(19) United States
(12) Patent Application Publication
(10) Pub. No.: US 2025/0385187 A1
(43) Pub. Date: Dec. 18, 2025

(54) FERROMAGNETIC THROUGH SILICON VIAS IN THREE-DIMENSIONAL INTEGRATED CIRCUITS

(71) Applicant: PI Invent Inc., Parker, TX (US)

(72) Inventors: Muhammad Rashad Ramzan, Islamabad (PK); Ibrahim Bin Shahid, Islamabad (PK); Haziq Rohail, Faisalabad (PK); Ali Raza Mustafa, Hyderabad (PK); Muddassar Farooq, Islamabad (PK)

(73) Assignee: PI Invent Inc., Parker, TX (US)

(21) Appl. No.: 18/772,014

(22) Filed: Jul. 12, 2024

(30) Foreign Application Priority Data
Jun. 14, 2024 (PK) 441/2024

(51) Int. Cl. H01L 23/538; H01L 23/367; H01L 23/498; H01L 27/06

(52) U.S. Cl. CPC H01L 23/5384; H01L 23/367; H01L 23/49866; H01L 23/5386; H10D 1/20; H10D 88/00

(57) ABSTRACT

An apparatus of a ferromagnetic transformer in a 3D integrated circuit is described, which comprises a plurality of semiconductor chips stacked within the 3D integrated circuit. An individual semiconductor chip of the plurality of semiconductor chips comprises a substrate, a plurality of dielectric layers, and a plurality of metal layers in the plurality of dielectric layers. In at least one example, the apparatus comprises one or more ferromagnetic through silicon vias vertically positioned through the individual semiconductor chip.

### CLAIM FOR PRIORITY

This application claims priority to Pakistan Patent Application No. 441/2024, filed on Jun. 14, 2024, titled “Ferromagnetic Through Silicon Vias in Three-Dimensional Integrated Circuits,” which is incorporated by reference in its entirety for all purposes.

### TECHNICAL FIELD

At least one example generally relates to three-dimensional integrated circuit (3D IC) devices and fabrication methods, and more particularly to wireless communication, wireless power transfer and heat dissipation in three-dimensional integrated circuit (3D IC) devices.

### BACKGROUND

Modern digital systems comprise interconnected processors, memories, and peripherals. Among different interfaces, processor to memory interface uses the highest bandwidth and data transfer rate. However, it is challenging to physically fabricate larger size memories and multiple processors on a single silicon die. Typically, a primary processor die merely comprises a small sized high-speed cache memory while large sized memory of a processor system is implemented on separate chips as static random-access memory (SRAM) or dynamic random-access memory (DRAM). This design choice results in long printed circuit board (PCB) tracks between a memory as separate chips and a processor, which results in interconnect parasitics, impedance mismatches, and voltage spikes in the power supply. Consequently, this limits the operation of a processor system.

Three-dimensional (3D) integration of dies may reduce length of tracks by vertically stacking multiple processor and memory dies namely chips, thereby, increasing the bandwidth and operating speed of a multi-processor system. Inter-chip communication may be realized by through silicon vias (TSVs). However, using TSVs alone for power distribution between dies is challenging because of heat generated by resistive loses in the TSVs. Heat management of stacked ICs remains a challenge due to resistive losses in the power distribution network (PDN). Due to high chip density, heat is trapped inside the IC, which further exacerbates the heat dissipation issues.

The background description provided here is for the purpose of generally presenting the context of the disclosure. Unless otherwise indicated here, the material described in this section is not prior art to the claims in this application and are not admitted to be prior art by inclusion in this section.

### BRIEF DESCRIPTION OF THE DRAWINGS

At least one example may be understood more fully from detailed description given below and from accompanying drawings, which, however, should not be taken to be limiting, but are for explanation and understanding.

FIG. 1 is a schematic that illustrates a layout of three-dimensional integrated circuit with multiple chips communicating through a proposed apparatus of ferromagnetic transformer, in accordance with at least one example.

FIG. 2 is a schematic that illustrates a three-dimensional integrated circuit comprising multiple chips with multiple ferromagnetic transformers, in accordance with at least one example.

FIG. 3 is a schematic that illustrates an inductive link comprising two inductive coils of one turn each, implemented on two different chips for communication, in accordance with at least one example.

FIG. 4 is a schematic that illustrates the dimensions of the inductive link of FIG. 3, in accordance with at least one example.

FIG. 5 is a schematic that illustrates a test circuit that compares transient performance of various inductive links or ferromagnetic transformers, in accordance with at least one example.

FIG. 6 is a plot that illustrates transient results of the inductive link of FIG. 3 at a signal frequency of 100 megahertz, in accordance with at least one example.

FIG. 7 is a schematic that illustrates a ferromagnetic transformer with a ferromagnetic through silicon via interposed in the inductive link of FIG. 3, in accordance with at least one example.

FIG. 8 is a plot that illustrates transient results of the ferromagnetic transformer of FIG. 7 at a signal frequency of 100 megahertz, in accordance with at least one example.

FIG. 9 is a schematic that illustrates dimensions of two different sets of inductive links, used for inter-chip communication in a three-dimensional integrated circuit, in accordance with at least one example.

FIG. 10 is a schematic that illustrates a test circuit to examine transient performance of two inductive links or ferromagnetic transformers, in accordance with at least one example.

FIG. 11 is a plot that illustrates transient results of the two inductive links of FIG. 9 operating at two different signal frequencies of 100 megahertz and 166 megahertz, respectively, in accordance with at least one example.

FIG. 12 is a schematic that illustrates two ferromagnetic transformers with ferromagnetic through silicon vias interposed in each of the two inductive links of FIG. 9, in accordance with at least one example.

FIG. 13 is a plot that illustrates transient results of the ferromagnetic transformers of FIG. 12 operating at two different signal frequencies of 100 megahertz and 166 megahertz, respectively, in accordance with at least one example.

FIG. 14 is a plot that illustrates a dependence of inductances and coupling coefficient on the radius of a ferromagnetic through silicon via, keeping the inductive coil's dimensions fixed, in accordance with at least one example.

FIG. 15 is a plot that illustrates a dependence of inductances and coupling coefficient on the radius of a ferromagnetic through silicon via as well as the inner radius of an inductive coil, in accordance with at least one example.

FIG. 16 is a plot that illustrates a dependence of inductances and the coupling coefficient on the chip-to-chip distance, in accordance with at least one example.

FIG. 17 is a schematic that illustrates an example structure of a ferromagnetic transformer, wherein two ferromagnetic through silicon vias are connected by ferromagnetic lines, in accordance with at least one example.

FIG. 18 is a plot that illustrates transient results of the inductive link of FIG. 17 operating at a signal frequency of 100 megahertz, in accordance with at least one example.

FIG. 19 is a plot that illustrates a dependence of inductances and coupling coefficient on the radii of ferromagnetic through silicon vias of FIG. 17 keeping the inductive coil dimensions fixed, in accordance with at least one example.

FIG. 20 is a plot that illustrates a dependence of inductances and coupling coefficient on the radii of ferromagnetic through silicon vias and the inner radii of inductive coils of FIG. 17, in accordance with at least one example.

FIG. 21 is a plot that illustrates a dependence of inductances and coupling coefficient on the chip-to-chip distance between the inductive coils of FIG. 17, in accordance with at least one example.

FIG. 22 is a schematic that illustrates an example structure of a ferromagnetic transformer, wherein the ferromagnetic lines of FIG. 17 are replaced with ferromagnetic sheets, in accordance with at least one example.

FIG. 23A is a schematic that illustrates low reluctance paths through which magnetic fields travel in the ferromagnetic sheets of FIG. 22, in accordance with at least one example.

FIG. 23B is a schematic that illustrates magnetic flux density lines in the structure of FIG. 22, in accordance with at least one example.

FIG. 24 is a schematic that illustrates a magnetic circuit model of the structure of FIG. 22, in accordance with at least one example.

FIG. 25 is a set of plots that illustrates simulation results of the model of FIG. 24, in accordance with at least one example.

FIG. 26 is a schematic that illustrates an example structure of four ferromagnetic transformers placed close together in a three-dimensional integrated circuit, in accordance with at least one example.

FIG. 27 is a schematic that illustrates a layout mask of a ferromagnetic layer of the structure of FIG. 26, in accordance with at least one example.

FIG. 28 is a plot that illustrates a voltage gain as a function of different loads, to compare different example structures of the ferromagnetic transformer with a simple inductive link, in accordance with at least one example.

FIG. 29 is a plot that illustrates the power gain as a function of different loads, for different example structures of the ferromagnetic transformer, in accordance with at least one example.

FIG. 30 is a schematic that illustrates an example structure of the ferromagnetic transformer including two guard rings, in accordance with at least one example.

FIG. 31 is a plot that illustrates modelling of inductance as a function of frequency for the inductive coils of FIG. 30, in accordance with at least one example.

FIG. 32 is a plot that illustrates modelling of inductance as a function of frequency for the inductive coils of FIG. 30 without guard rings, in accordance with at least one example.

FIG. 33A is a schematic that illustrates a three-dimensional integrated circuit comprising different dies connected through ferromagnetic through silicon vias inside a chip package, in accordance with at least one example.

FIG. 33B is a schematic that illustrates a three-dimensional integrated circuit comprising heat lines on different dies connected through ferromagnetic through silicon vias, in accordance with at least one example.

FIG. 34 is a schematic that illustrates a heat dissipation model of the three-dimensional integrated circuit of FIG. 33A to model the heat transfer behavior of the ferromagnetic through silicon vias, in accordance with at least one example.

FIG. 35 is a schematic that illustrates a thermal model of the three-dimensional integrated circuit of FIG. 33A, in accordance with at least one example.

FIG. 36 is a schematic that illustrates an example structure of a ferromagnetic transformer with two ring oscillators around a ferromagnetic through silicon via, in accordance with at least one example.

FIG. 37 is a schematic that illustrates current paths through inverter transistors in a circuit diagram of the structure of FIG. 36, in accordance with at least one example.

FIG. 38 is a schematic that illustrates a layout of an example structure of ferromagnetic transformer with a ring oscillator around a ferromagnetic through silicon via, in accordance with at least one example.

FIG. 39 is a schematic that illustrates a state of active devices and current paths during the first half cycle of the ring oscillator of FIG. 38, in accordance with at least one example.

FIG. 40 is a schematic that illustrates a state of active devices and current paths during the second half cycle of the ring oscillator of FIG. 38, in accordance with at least one example.

FIG. 41 is a schematic that illustrates a ferromagnetic transformer that achieves frequency interlocking with a single transistor, in accordance with at least one example.

FIG. 42 is a schematic that illustrates a three-dimensional integrated circuit comprising a multitude of chips connected through ferromagnetic transformers, in accordance with at least one example.

FIG. 43 is a schematic that illustrates a ferromagnetic transformer with multiple inductive coils around a ferromagnetic through silicon via for resonant link communication in a three-dimensional integrated circuit, in accordance with at least one example.

FIG. 44 is a schematic that illustrates a test circuit for the ferromagnetic transformer of FIG. 43, in accordance with at least one example.

FIG. 45 is a schematic that illustrates a ferromagnetic transformer comprising four on-chip inductive coils around a ferromagnetic through silicon via, in accordance with at least one example.

FIG. 46 is a schematic that illustrates dimensions of the four on-chip inductive coils of FIG. 45, in accordance with at least one example.

FIG. 47 is a plot that illustrates transient results using the test circuit of FIG. 43 for the structure of FIG. 45, in accordance with at least one example.

FIG. 48 is a schematic that illustrates a test circuit for enhancement of resonant links of FIG. 44, in accordance with at least one example.

FIG. 49 is a plot that illustrates improved transient results of the ferromagnetic transformer of FIG. 48, in accordance with at least one example.

FIG. 50 is a schematic that illustrates a modified circuit diagram of FIG. 44, wherein a band pass LNA is added in a receiving end, in accordance with at least one example.

FIG. 51 is a schematic that illustrates a magnified view of an on-chip resonating tank including an inductive coil and a capacitor implemented in different metal layers of a chip, in accordance with at least one example.

FIG. 52 is a schematic that illustrates a ferromagnetic transformer with four resonating tanks for two resonant links around a ferromagnetic through silicon via (FTSV), in accordance with at least one example.

FIG. 53 is a plot that illustrates a high frequency S parameter result of the resonant links of FIG. 52, in accordance with at least one example.

FIG. 54 is a schematic that illustrates an example structure of a ferromagnetic transformer with the two resonant links of FIG. 52, wherein two ferromagnetic through silicon vias are connected by ferromagnetic lines, in accordance with at least one example.

FIG. 55 is a plot that illustrates a high frequency S parameter result of the resonant links of FIG. 54, in accordance with at least one example.

FIG. 56 is a schematic that illustrates an example structure of a ferromagnetic transformer, such that the resonant links operating at a same resonant frequency have slightly different physical dimensions, in accordance with at least one example.

FIG. 57 is a plot that illustrates a high frequency S parameter result of the resonant links of FIG. 56, in accordance with at least one example.

FIG. 58 is a schematic that illustrates an example structure of a ferromagnetic transformer, such that the resonant links of FIG. 54 operating at the same resonant frequency have slightly different physical dimensions, in accordance with at least one example.

FIG. 59 is a plot that illustrates an improved high frequency S parameter result of the resonant links of FIG. 58, in accordance with at least one example.

FIG. 60 is a schematic that illustrates an example structure of a resonating tank circuit, wherein a capacitor is implemented in smaller segments, in accordance with at least one example.

FIG. 61 is a plot that illustrates an eye diagram of a resonant link of FIG. 58, in accordance with at least one example.

FIG. 62 is a schematic that shows a block diagram of a serializer-deserializer (SERDES) communication using an enhanced resonant link, in accordance with at least one example.

FIG. 63 is a schematic that illustrates a ferromagnetic power transformer based power distribution network in a three-dimensional integrated circuit comprising a multitude of chips, in accordance with at least one example.

FIG. 64 is a schematic that illustrates a block diagram of a power distribution network with a ferromagnetic power transformer, in accordance with at least one example.

FIG. 65 is a schematic that illustrates a block diagram of a state of the art power distribution network of a three-dimensional integrated circuit, in accordance with at least one example.

FIG. 66 is a schematic that illustrates a resonant link of a ferromagnetic power transformer, wherein two ferromagnetic through silicon vias (FTSVs) are connected by ferromagnetic lines, in accordance with at least one example.

FIG. 67A is a schematic that illustrates an exploded view of an on-chip resonating tank including an inductive coil and a capacitor implemented in different metal layers of a chip, in accordance with at least one example.

FIG. 67B is a schematic that illustrates methods of implementing on-chip capacitors for a resonating tank, in accordance with at least one example.

FIG. 68 is a plot that illustrates a high frequency S-parameter result of a resonant link with resonating tanks of FIG. 67A, in accordance with at least one example.

FIG. 69 is a schematic that illustrates a test circuit of a state of the art power distribution network with high frequency on-chip decoupling capacitors, in accordance with at least one example.

FIG. 70A is a schematic that illustrates a layout of a backside power delivery network using buried power rails and micro TSVs, in accordance with at least one example.

FIG. 70B is a schematic that illustrates a layout of a mesh type on-chip PDN and a unit cell for modelling the PDN characteristics, in accordance with at least one example.

FIG. 71 is a schematic that illustrates an equivalent model of the PDN unit cell of FIG. 70B, in accordance with at least one example.

FIG. 72 is a schematic that illustrates a complete model of the PDN unit cell of FIG. 70B, in accordance with at least one example.

FIG. 73 is a plot that illustrates impedance changes seen at a source of the test circuit of FIG. 69, in accordance with at least one example.

FIG. 74 is a plot that illustrates voltage at a load of the test circuit of FIG. 69 when it drives different current transients, in accordance with at least one example.

FIG. 75 is a schematic that illustrates a circuit of a ferromagnetic power transformer based power distribution network that eliminates on-board parasitic elements, in accordance with at least one example.

FIG. 76 is a plot that illustrates impedance changes seen at a source of the circuit of FIG. 75, in accordance with at least one example.

FIG. 77 is a plot that illustrates voltage at the load of the circuit of FIG. 75 when it drives different current transients, in accordance with at least one example.

FIG. 78 is a schematic that illustrates two ferromagnetic power transformers to power up different circuit areas on a chip, in accordance with at least one example.

FIG. 79 is a schematic that illustrates two ferromagnetic power transformers to power up different chips in a three-dimensional integrated circuit, in accordance with at least one example.

FIG. 80 is a schematic that illustrates an electro-migration effect in a DC powered circuit, in accordance with at least one example.

FIG. 81 is a schematic that illustrates an electro-migration effect in the ferromagnetic power transformer based PDN, in accordance with at least one example.

GLOSSARY OF SYMBOLS

| | |
|---|---|
| 3D | Three-dimensional. |
| IC | Integrated circuit. |
| 3D IC | Three-dimensional integrated circuit. |
| FTSV | Ferromagnetic through silicon via. |
| FMPT | Ferromagnetic power transformer. |
| FMHT | Ferromagnetic heat transformer. |
| FMT | Ferromagnetic transformer. |
| PDN | Power distribution network. |
| SRAM | Static random-access memory. |
| DRAM | Dynamic random-access memory. |
| RF | Radio frequency. |
| TSV | Through silicon via. |
| PCB | Printed circuit board. |
| AC | Alternating current. |
| DC | Direct current. |
| IoT | Internet of things. |
| LED | Light emitting diode. |
| k | Coupling coefficient. |
| M | Mutual inductance. |
| L | Inductance. |
| C | Capacitance. |
| R | Resistance. |
| [symbol] | Reluctance. |
| Tx | Transmitter. |
| Rx | Receiver. |
| V_{TX} | Transmitted voltage. |
| V_{RX} | Received voltage. |
| SER-DES | Serializer-deserializer. |
| PMIC | Power management integrated circuit. |
| PTE | Power transfer efficiency. |
| ESR | Equivalent series resistance. |
| ESL | Equivalent series inductance. |
| FEOL | Front end of the line. |
| BEOL | Back end of the line. |
| MIM | Metal-insulator-metal. |
| MOM | Metal-oxide-metal. |

### DETAILED DESCRIPTION

At least one example discloses an apparatus that enhances coupling of one or more inductive links to achieve higher efficiency for inter-chip single-channel and multiple-channel communication, and wireless alternating current (AC) power transfer by applying ferromagnetic materials. The disclosed apparatus is also suited for low bandwidth and low power applications including but not limited to IoT sensor chips and smart dust motes.

At least one example illustrates an apparatus that can enable lossless wireless communication between multitudes of chips, which are stacked on top of each other. At least one example applies ferromagnetic through silicon vias (FTSVs) to provide a low reluctance path for the magnetic field, from the transmitter coil to the receiver coil that ensures improved quality factor of inductive link, and improved coupling and signal strengths. The FTSVs can also be used as a heat pipe to conduct heat from inside the 3D chip to a heat sink, solving one of the major bottlenecks in three-dimensional integrated circuits (3D ICs). Some examples illustrate a multitude of structures that exhibit a trade-off between performance and manufacturing cost. An optimized structure is also identified that gives a reasonable performance and has simple construction easing out the manufacturing cost. At least one example illustrates an architecture to optimize the area used by metal inductive coils. The architecture lays out a transistor around an FTSV and applies a ring oscillator to generate flux in the FTSV to perform inter-chip communication. At least one example applies multiple resonant links for chip-to-chip communication. Each of the multitude of on-chip resonant links comprises at least two on-chip resonating circuits, wherein each on-chip resonating circuit is implemented on a different chip in the 3D IC stack. The multitude of on-chip resonant links may operate using any modulation scheme. When combined with a multitude of on-chip resonating circuits operating at a certain frequency, AC power is transmitted wirelessly between multitudes of vertically stacked ICs. The on-chip DC to AC converter converts the DC power from a printed circuit board (PCB) at a power management integrated circuit (PMIC) to AC, wherein this AC power is channeled to multitude of vertically stacked ICs. In at least one example, each IC receiving AC power contains an on-chip rectifier and a regulator to convert the said AC power to DC power to power up one or more loads.

Some examples provide high bandwidth resonant links for communication in 3D integration of cores of processor systems. In at least one example, the FTSVs enhance the heat dissipation and improve reliability and average lifetime of the chips since FTSV do not suffer from resistive losses because no electric current passes through them. Hence, the examples enable efficient inductive links in a 3D IC for several types of applications.

In the following description, numerous details are discussed to provide a more thorough explanation of examples of the present disclosure. It will be apparent, however, to one skilled in the art, that examples of the present disclosure may be practiced without these specific details. In other instances, well-known structures and devices are shown in block diagram formats, rather than in detail, to avoid obscuring examples of the present disclosure.

Note that in the corresponding drawings of the examples, signals and/or dimensions are represented with lines. Some lines may be thicker, to indicate more constituent signal paths, and/or have arrows at one or more ends, to indicate primary information flow direction. Such indications are not intended to be limiting. Rather, the lines are used in connection with one or more exemplary examples to facilitate easier understanding of a circuit or a logical unit. Any represented signal, as dictated by design needs or preferences, may actually comprise one or more signals that may travel in either direction, and may be implemented with any suitable type of signal scheme.

It is pointed out that those elements of the figures having the same reference numbers (or names) as the elements of any other figure can operate or function in any manner like that described but are not limited to such.

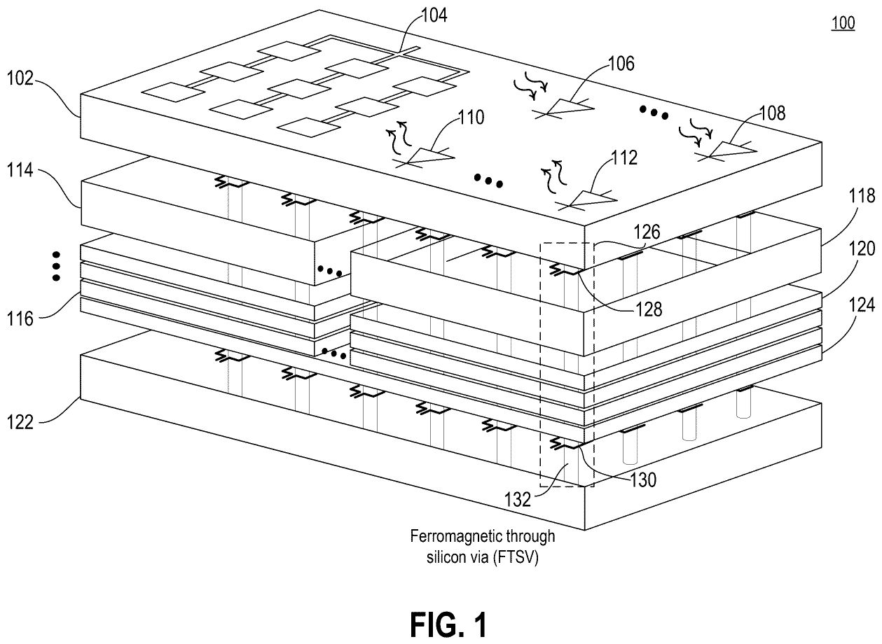

FIG. 1 is a schematic that illustrates a 3D IC 100 comprising multiple chips: chip 102 to chip 122, wherein each chip serves a different purpose in a stack and may be manufactured using different chip manufacturing technologies, in accordance with at least one example. In at least one example, the inductive coupling is enhanced by an FTSV passing through vertically stacked chips of a 3D IC. In at least one example, on-chip inductive coils surround the FTSV on each chip for inter-chip communication. The FTSVs provide a low reluctance path for magnetic fields to flow, ensuring better linkage between the inductive coils. In at least one example, different examples of the FTSV, like a vertical transformer or ferromagnetic sheet based vertical transformer, may be used to improve the permeability and flux linkage. In at least one example, different examples of FTSV may be used to decrease manufacturing complexity of the FTSVs.

In at least one example, 3D ICs having FTSVs may be used in low power internet-of-things (IoT) sensor chips, smart dust mote applications, or high-speed cores of processors. In at least one example, a high-performance inductive link can be established between the stacked chips by using the FTSVs as a low reluctance medium. Due to the small on-chip area of the inductive link, an array comprising a plurality of inductive links can be created to support several connections in a 3D IC. As the chips are reconfigurable, they are swapped out or stacked on to add new sensors or processors in IoT nodes. In this way, multiple chip stacks are conceived for requirements of an application, in accordance with at least one example.

In at least one example, chip 102 includes a radio frequency (RF) mm-wave front end comprising an antenna array 104, a photonics front end comprising photo diodes 106 and 108, light-emitting diodes (LEDs) 110 and 112, and other circuits or components used for a photonics front end. In at least one example, a chip 114 is a central processing unit (CPU) core with a memory chip 116. More processor cores and memories may be included in the stack such as a CPU core 118 and a memory N 120.

In at least one example, chip 122 is an artificial intelligence (AI) accelerator. In at least one example, 3D IC 100 includes chip 124 which is a power management IC (PMIC). In at least one example, sensors are integrated into 3D IC 100. The number and order of these chips are not a limiting factor and other configurations may be possible. In at least one example, PMIC 124 core is manufactured separately for each chip within the 3D IC.

In at least one example, inter-chip communication within the 3D IC 100 is enabled using a set of ferromagnetic transformers, such as ferromagnetic transformer 126 that includes on-chip inductive coils 128 and 130, and ferromagnetic through silicon via 132. Since ferromagnetic through silicon via 132 is made from a ferromagnetic material with a high permeability, magnetic fields of on-chip inductive coils 128 and 130 are confined within the FTSV 132 that results in enhanced coupling, in accordance with at least one example. This results in a bandwidth efficiency for intra-chip communication, even when inductive coils are relatively small and have few turns. Furthermore, magnetic fields traverse primarily through FTSV 132 which allows designers to densely pack a multitude of inductive links for communication, in accordance with at least one example.

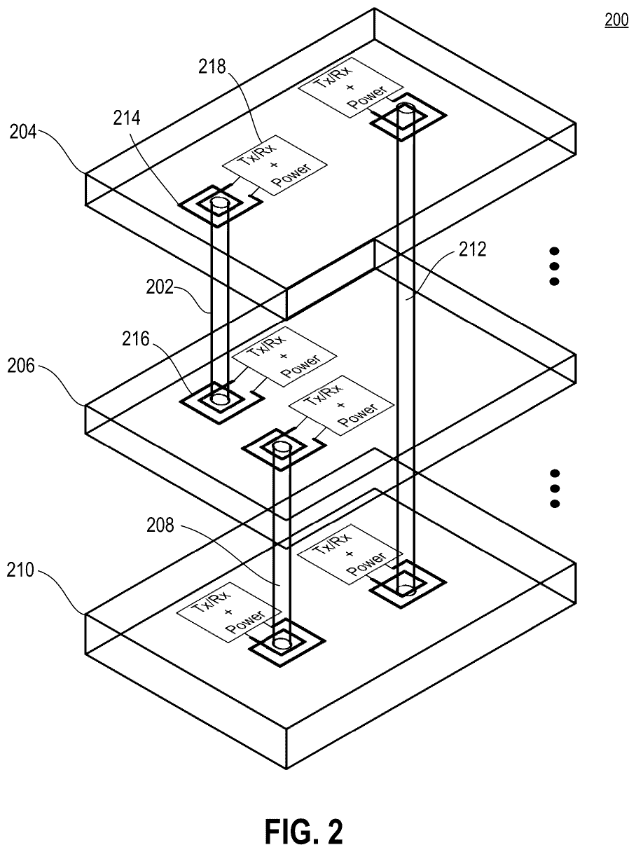

FIG. 2 is a schematic that illustrates a 3D IC 200 of multiple chips with multiple ferromagnetic transformers, in accordance with at least one example. Each chip may be a processor or a memory depending on applications. In at least one example, FTSV 202 extends from chip 204 to chip 206, FTSV 208 extends from chip 206 to chip 210, commonly known in PCB technology as one sided vias or semi blind vias, and FTSV 212 extends all the way from chip 204 to chip 210, commonly known in PCB technology as a through via. In at least one example, each FTSV has at least two inductive coils around it with some space for insulation, making a ferromagnetic transformer. For instance, FTSV 202 has inductive coils 214 and 216 around it, and each inductive coil has its associated transmitting (Tx) and receiving (Rx) circuits, and power circuit 218 for an inductive coil 214.

The similar naming convention for TSV exists which is based on the manufacturing processes. Via-first TSVs are fabricated before individual components like transistors, resistors etc. Via-middle TSVs are fabricated after each individual component is patterned but before metal layers, and via-last TSVs are fabricated during a backend of line (BEOL) process, as known to the ones skilled in the art. Via-middle TSVs may be preferred for advanced 3D ICs, in accordance with at least one example.

Despite using the naming convention of TSVs, FTSVs may not be configured for use as conducting vias, in accordance with at least one example. In at least one example, each FTSV acts as a high permeability channel/medium for magnetic fields of the inductive coils that surround its ends. The high permeability of the FTSV allows the fields to pass through it; as a result, it forms a vertical ferromagnetic transformer core that enhances the coupling and power transfer efficiency of an inductive link. Inductive link supported by the FTSV for communication, is beneficial over a conducting TSV link because of its power dissipation characteristics. The conducting TSV has a resistance and capacitance, requires input-output driving circuits, and dissipates heat which is a major concern in 3D ICs. While an inductive link with a higher coupling, the FTSV does not conduct current which minimizes the power losses. This coupling and power transfer efficiency from an FTSV may not be possible for a planar coil because of high losses that are associated with the silicon permeability, resistivity, and low directivity of the magnetic fields of a planar coil. These problems are overcome by forming a multi-chip vertical ferromagnetic transformer. The FTSV of various examples drastically improves the coupling coefficient and efficiency. The FTSV also establishes a one-to-one link between two inductive coils by confining their fields within themselves, which prevents spurious coupling with other inductive coils.

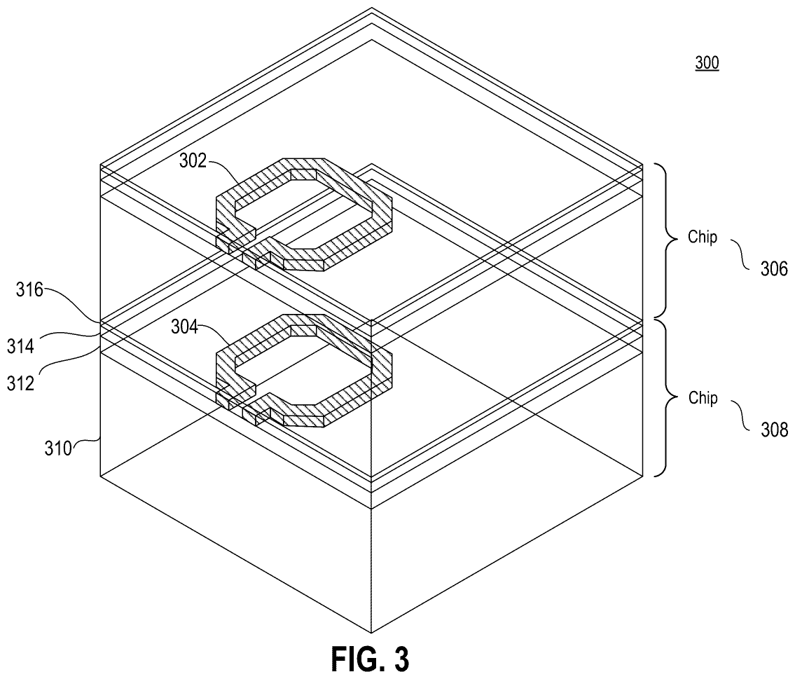

FIG. 3 is a schematic that illustrates a layout of a 3D IC 300, with two inductive coils: inductive coils 302 and 304 with one turn each, in accordance with at least one example. In at least one example, inductive coil 302 is implemented in the top metal layer of chip 306 and inductive coil 304 is implemented in the top metal layer of chip 308 in the same 3D IC 300. FIG. 3 also illustrates other layers of chip 308 including active silicon 310, dielectric layers 312 and 314, and passivation layer 316, in accordance with at least one example. These layers are also illustrated for chip 306 as well.

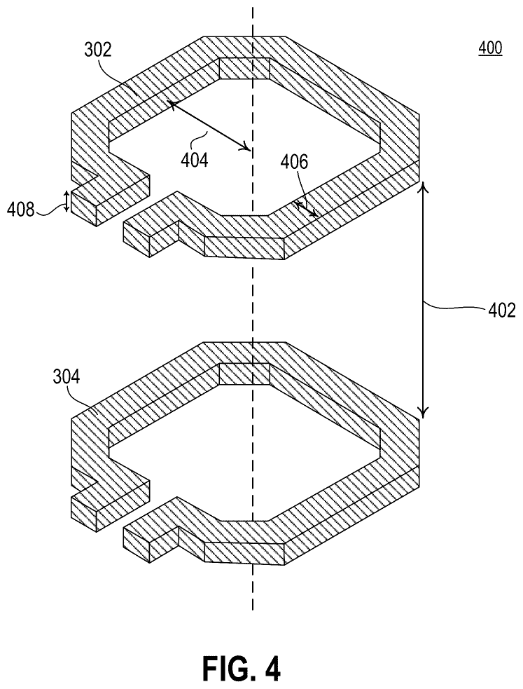

FIG. 4 is a schematic that illustrates a dimensional view 400 of inductive coils 302 and 304, in accordance with at least one example. The distance between inductive coil 302 and inductive coil 304, namely chip-to-chip distance 402, is typically 350 micrometers. The chip-to-chip distance 402 can be reduced up to 50 micrometers by using advance manufacturing processes, in accordance with at least one example. In at least one example, chip-to-chip distance 402 is 50 micrometers, inner radius 404 of both inductive coils is 15 micrometers, width 406 is 5 micrometers, and metal thickness 408 is 3.4 micrometers. In at least one example, self inductances of these inductive coils are approximately 57.06 picohenry, mutual inductance is 1.91 picohenry, and inductive coupling coefficient is 0.033. The numbers for various dimensions are provided as examples and other numbers may be used in accordance with at least one example.

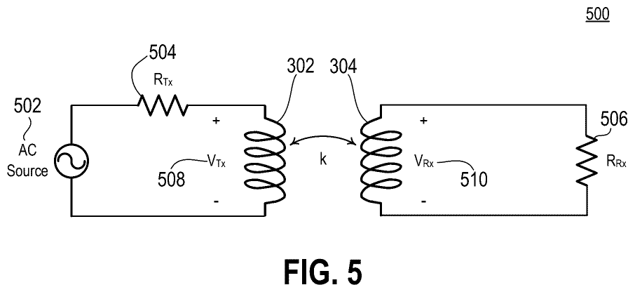

FIG. 5 is a schematic that illustrates a test circuit 500 comprising transmitting inductive coil 302 and receiving inductive coil 304 in accordance with at least one example. An alternating current (AC) source 502 and small series resistance R_{Tx} 504 are constituents of transmitting circuit, and load resistor R_{Rx} 506 is a part of the receiver circuit. V_{TX} 508 is a transmitted voltage at transmitting inductive coil 302, and V_{RX} 510 is the received voltage at receiving inductive coil 304. In this example, default values of source resistance R_{Tx} 504 and load resistance R_{Rx} 506 are 1 ohm and 10 kohm, respectively, unless stated otherwise.

The circuit 500 of FIG. 5 is an equivalent circuit of two coils with or without FTSV. This circuit serves as a test bench to compare different coupling methods of an inductive link with and without FTSV and with or without external closed low reluctance magnetic flux path. The use of FTSV improves the coupling coefficient k between the inductive coils.

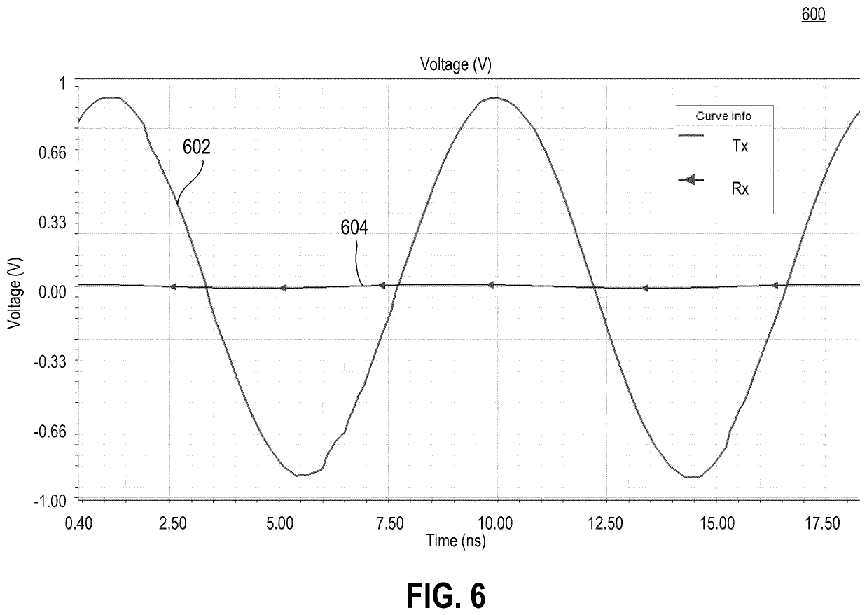

FIG. 6 is a plot 600 that illustrates coupling results of the inductive link established between inductive coils 302 and 304 of FIG. 3 by using the test circuit 500 of FIG. 5, in accordance with at least one example. Here, AC source 502 has a frequency of 100 megahertz, but other frequencies may be used too. Signals 602 and 604 are the normalized voltage waveforms of V_{TX} 508 and V_{RX} 510, respectively. The voltage gain of the inductive link in this case is −40.6 decibels and the power gain is −88.5 decibels. Moreover, the received signal strength is significantly lower than the transmitted signal strength because of poor coupling and losses of the inductive link.

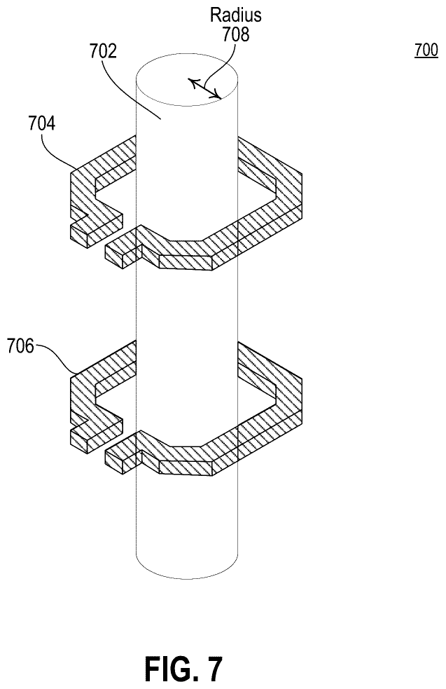

FIG. 7 is a schematic that illustrates a ferromagnetic transformer (FMT) 700 with an FTSV 702 interposed between an inductive coil 704 and an inductive coil 706 having the same dimensions as of the inductive coils in FIG. 3, in accordance with at least one example. In at least one example, inductive coils 704 and 706 lie in metal layers of two different chips in a 3D IC. In at least one example, the ferromagnetic through silicon via 702 has a radius 708 of 10 micrometers, and is made of a ferromagnetic material such as iron or other ferrite based materials that are suited by the manufacturing process. The self inductances in the case of iron lies between 84.7 picohenry and 144.8 picohenry, the mutual inductance is 27.85 picohenry, and the inductive coupling coefficient is 0.251. The material of FTSV may be chosen based on an application, in accordance with at least one example.

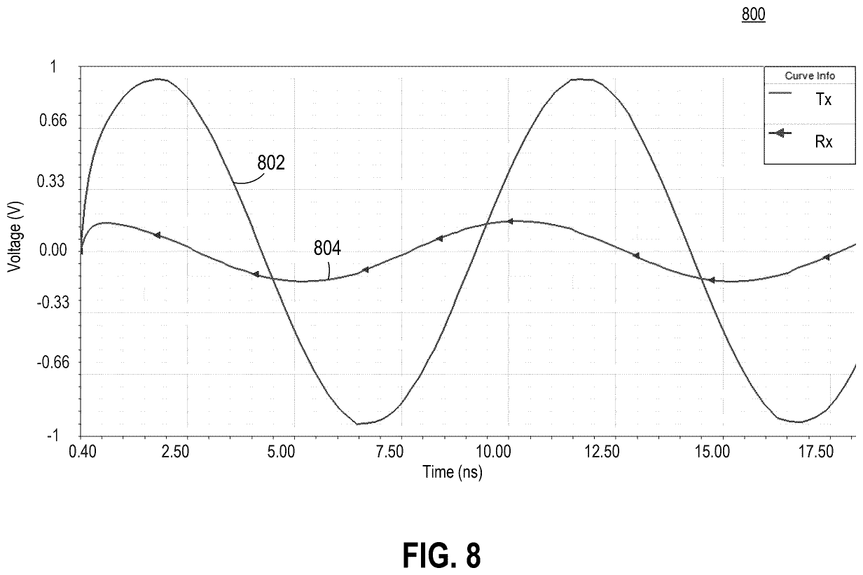

FIG. 8 is a plot 800 that illustrates a transient coupling result of ferromagnetic transformer of FIG. 7 by using test circuit 500 of FIG. 5 at a signal frequency of 100 megahertz, in accordance with at least one example. Signals 802 and 804 are voltage waveforms of V_{TX} 508 and V_{RX} 510, respectively. The voltage gain of this configuration is −15.5 decibels, and the power gain is −62.6 decibels in accordance with at least one example. Consequently, ferromagnetic transformer 700 ensures improved coupling and received signal strength.

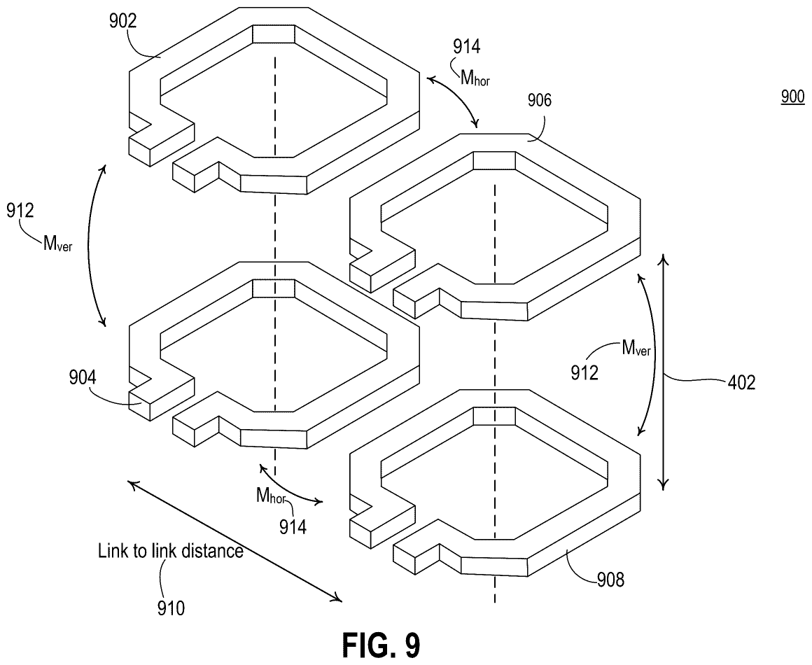

FIG. 9 is a schematic that illustrates an example structure 900 of two different sets of inductive links, wherein the first link includes inductive coils 902 and 904, and the second link includes inductive coils 906 and 908, respectively, in accordance with at least one example. In at least one example, chip-to-chip distance 402 between the inductive coils of both inductive links is the same, and the horizontal distance between the two links namely link-to-link distance 910 is 50 micrometers. The self inductances of inductive coils are approximately 57.1 picohenry, and the the desired mutual inductance M_{Ver} 912 between inductive coils 902 and 904 or between inductive coils 906 and 908 is 1.94 picohenry. Here, mutual inductance Mₕₒᵣ 914 between inductive coils 902 and 906 or between inductive coils 904 and 908 is 2.36 picohenry. The inductive coupling coefficient between inductive coils 902 and 904 is 0.034 and between inductive coils 904 and 908 it is 0.04. It is apparent that the mutual inductance and coupling coefficient of horizontal coupling Mₕₒᵣ 914 between inductive coils 904 and 908 is stronger compared with the vertical coupling M_{Ver} 912 between inductive coils 902 and 904. Structure 900 of FIG. 9 may not be used for making two vertical links or trasnsformers with a good performace because of an increase in the mutual interference. With structure 900 of FIG. 9, these issues can be resolved by increasing link-to-link distance 910 between the inductive coils, but that may increase the on-chip area.

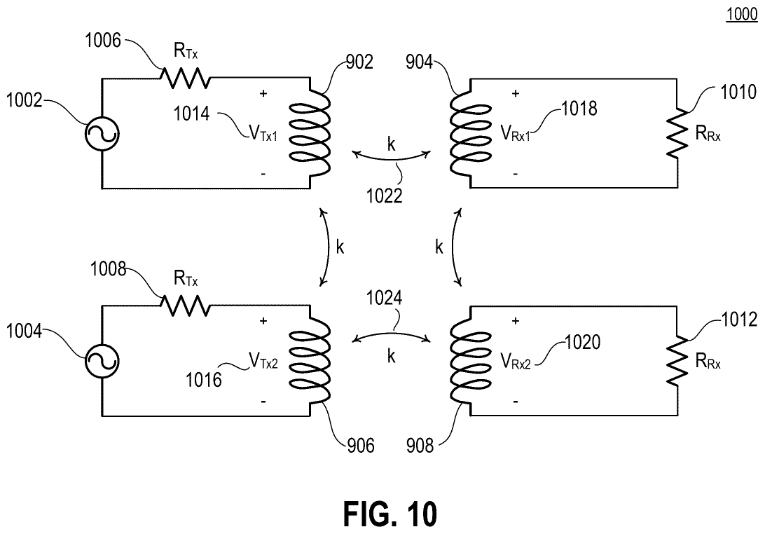

FIG. 10 is a schematic that illustrates a test circuit 1000, wherein the inductive coils 902 and 904 create a first transmission link 1022, and the inductive coils 906 and 908 create a second transmission link 1024, in accordance with at least one example. In at least one example, AC sources 1002 and 1004 and two small series resistances R_{Tx} 1006 and R_{Tx} 1008 are used at the transmitting side. Similarly, two load resistors R_{Rx} 1010 and R_{Rx} 1012 are used at the receiving end, respectively. V_{TX1} 1014 and V_{TX2} 1016 represent the voltages at the transmitting inductive coils 902 and 906 and V_{RX1} 1018 and V_{RX2} 1020 represent the voltages received at the receiving inductive coils 904 and 908. Test circuit 1000 compares the coupling between the inductive coils of the structure 900 of FIG. 9 with that of the disclosed structures herein. Source resistances R_{Tx} 1006 and R_{Tx} 1008 are 1 ohms and the load resistances R_{Rx} 1010 and R_{Rx} 1012 are 10 kilo ohms. FIG. 10 is an equivalent circuit of two inductive links, comprising four inductive coils, operating at different frequencies with or without ferromagnetic through silicon vias. Consequently, the equivalent circuit provides a test bench which can be used to compare the coupling behavior of two inductive links with or without FTSVs.

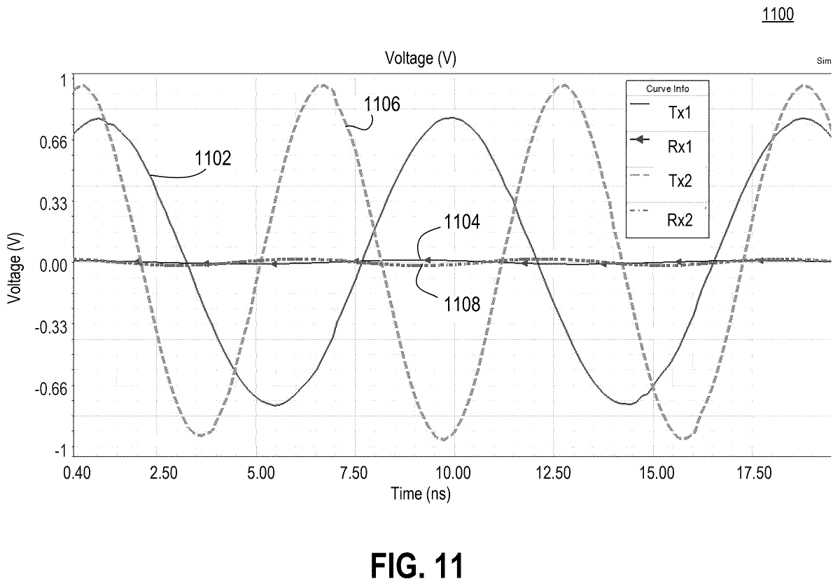

FIG. 11 shows a plot 1100 that illustrates coupling results of the first inductive link that is established between inductive coils 902 and 904 and the second inductive link that is established between inductive coils 906 and 908 of FIG. 9 by using test circuit 1000 of FIG. 10, in accordance with at least one example. Signals 1102 and 1104 are the voltage waveforms of Tx1 and Rx1 at a signal frequency of 100 megahertz, whereas signals 1106 and 1108 are voltage waveforms of Tx2 and Rx2 at a signal frequency of 166 megahertz. In at least one example, voltage gain of the first link established between inductive coils 902 and 904 is approximately-39.5 decibels, and the voltage gain of the second link established between inductive coils 906 and 908 is −37.5 decibels. The power gain of the first link is approximately-87.2 decibels and the power gain of the second link is approximately-85.04 decibels with 10 kilo ohms load.

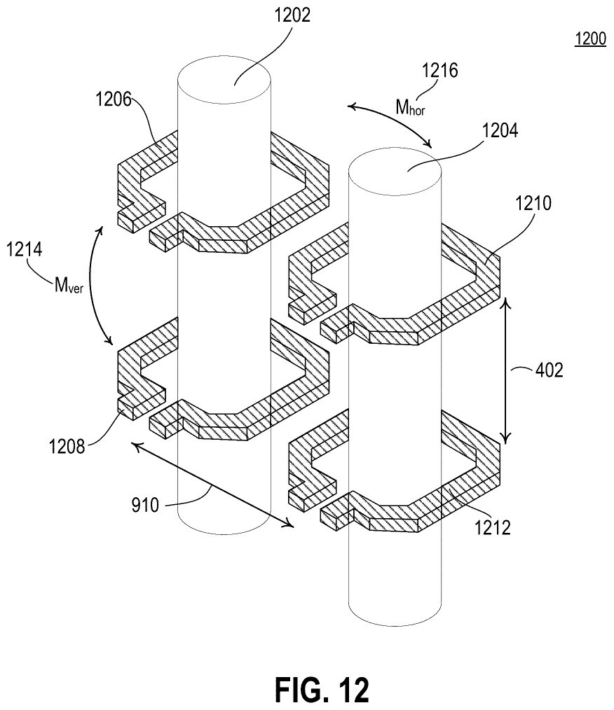

FIG. 12 is a schematic that illustrates a 3D view 1200 of two different sets of inductive links in two ferromagnetic transformers disclosed in FIG. 9, wherein FTSVs 1202 and 1204 are interposed between inductive coils 1206 and 1208 and inductive coils 1210 and 1212, respectively, in accordance with at least one example. In at least one example, FTSVs 1202 and 1204 provide a high permeability path for magnetic fields. In at least one example, chip-to-chip distance 402 and link-to-link distance 910 are the same as in the previous examples, and the radii of the FTSVs is 10 micrometers. In at least one example, self inductances of inductive coils 1206 and 1210 are 33.06 picohenry, and the self inductances of inductive coils 1208 and 1212 are 123.5 picohenry. The difference is due to the small low permeability path provided by FTSVs for inductive coils 1206 and 1210. The desired mutual inductance M_{Ver} 1214 between the inductive coils 1206 and 1208 or between inductive coils 1210 and 1212 is 5.74 picohenry. The undesired mutual inductance Mₕₒᵣ 1216 between inductive coils 1206 and 1210 is 0.79 picohenry. The inductive coupling coefficient is 0.09 between inductive coils 1206 and 1208, and the inductive coupling coefficient is 0.02 between inductive coils 1206 and 1210.

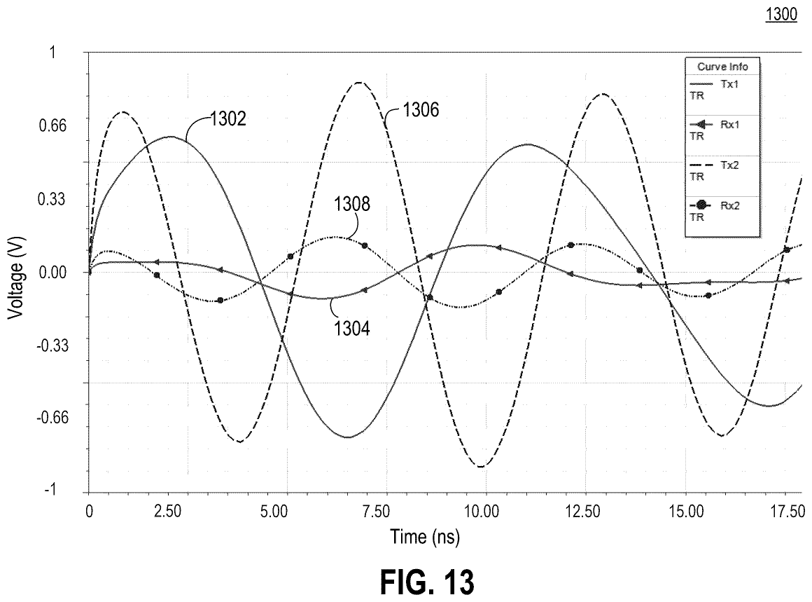

FIG. 13 is a plot 1300 that illustrates a coupling result established between the inductive coils 1206, 1208, 1210, and 1212 of FIG. 12 at signal frequencies of 100 megahertz and 166 megahertz, respectively, in accordance with at least one example. Consequently, two signals with different frequencies are distinguishable from one another. In at least one example, signals 1302 and 1304 are the voltage waveforms Tx1 and Rx1 at a signal frequency of 100 megahertz, whereas signals 1306 and 1308 are the voltage waveforms Tx2 and Rx2 at a signal frequency of 166 megahertz. The received signal strength illustrated by the signals Rx1 1304 and Rx2 1308 has significantly improved, and the interlink coupling, e.g., between inductive coils 1206 and 1210 or between inductive coils 1208 and 1212 has reduced. In at least one example, the voltage gain of the first inductive link between inductive coils 1206 and 1208 is −13.39 decibels, and the voltage gain of the second inductive link between inductive coils 1210 and 1212 is −14.64 decibels. Moreover, the power gain of the first inductive link is −61.86 decibels and the power gain of the second inductive link is −59.6 decibels with a resistive load of 10 kilo ohms.

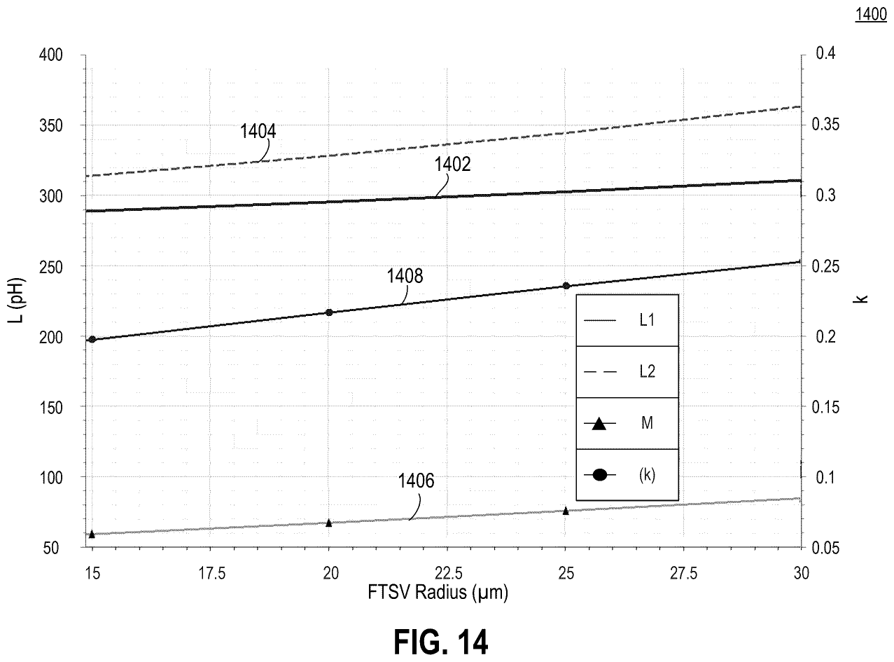

FIG. 14 is a plot 1400 that shows the dependence of inductances and coupling coefficients on the radius 708 of the ferromagnetic through silicon via 702, keeping inductive coil dimensions fixed, in accordance with at least one example. In at least one example, inner radius 404 of the inductive coils is set to 50 micrometers, width 406 is set to 5 micrometers, and thickness 408 is set to 3.4 micrometers. In at least one example, radius 708 of the FTSV 702 is varied from 15 micrometers to 30 micrometers. The self inductances are L1 1402 and L2 1404, mutual inductance is M 1406 and the inductive coupling coefficient k is 1408. The increase in the radius of FTSV 702 results in a consequent increase in self inductances L1 1402 and L2 1404, and increasing mutual inductance M 1406 and increasing coupling coefficient k 1408 which is due to the higher permeabillity of the FTSV 702 with a larger radius in comparison to the FTSV 702 with a smaller radius.

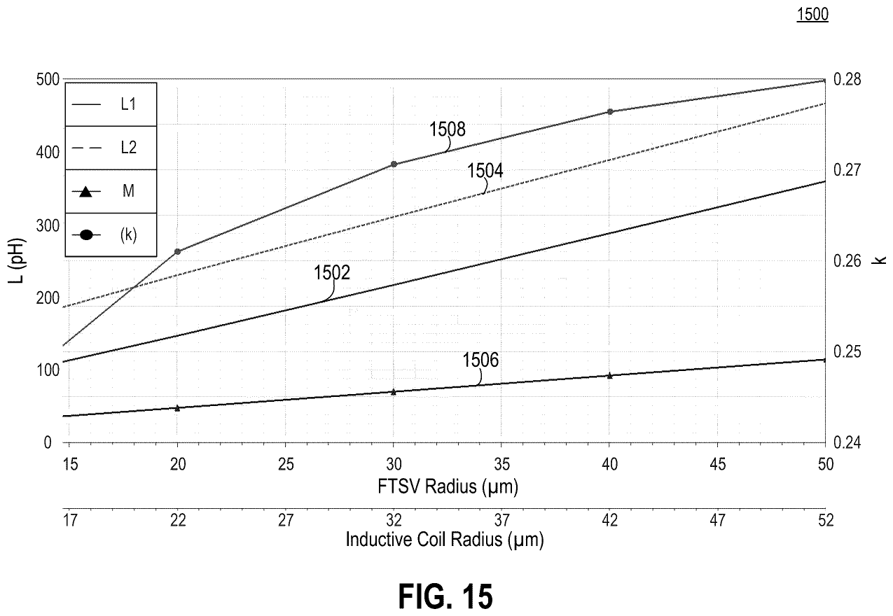

FIG. 15 is a plot 1500 that illustrates the dependence of inductances and coupling coefficients associated with radius 708 of FTSV 702, and inner radius 404 of inductive coils 704 and 706, in accordance with at least one example. Here, width 406 is 5 micrometers and thickness 408 is set to 3.4 micrometers. In at least one example, radius 708 of FTSV 702 is varied from 15 micrometers to 50 micrometers, while also scaling inner radius 404 of inductive coils 704 and 706 from 17 to 52 micrometers with a 2 micrometers clearance between them. The self inductances are are L1 1502 and L2 1504, the mutual inductance is M 1506 and the inductive coupling coefficient is k 1508. The increase in radius 708 of FTSV 702 and inductive coils 704 and 706 consequently results in an increase in self inductances L1 1502 and L2 1504, inductance M 1506 and coupling coefficient k 1508, which is due to the higher permeabillity of an FTSV with a larger radius in comparison to an FTSV of a smaller radius. The increase in radius of FTSV 702 and inductive coils 704 and 706 can ensure an improved inductive link performance but at the cost of a larger on-chip area.

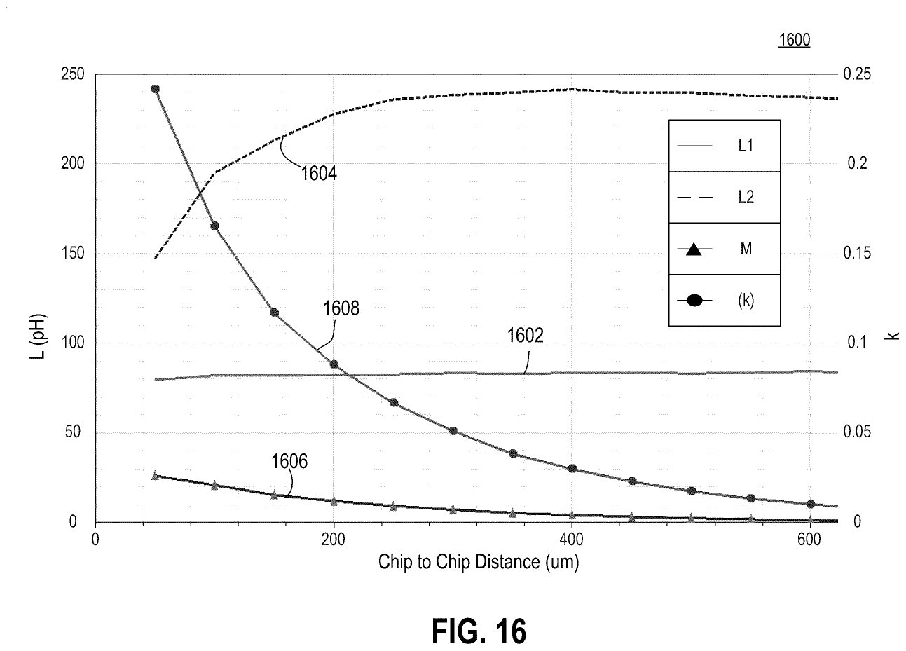

FIG. 16 is a plot 1600 that illustrates the dependence of the inductances and the coupling coefficients on chip-to-chip distance 402 as illustrated in FIG. 4, in accordance with at least one example. In this example, radius 708 is 50 micrometers, the inner radius 404 is 52 micrometers, the width 406 is 5 micrometers, and the thickness 408 is 3.4 micrometers, while the chip-to-chip distance 402 is varied from 50 micrometers to 600 micrometers. Plot 1600 shows self inductances L1 1602 and L2 1604, mutual inductance M 1606 and inductive coupling coefficient k 1608. Plot 1600 shows that mutual inductance 1606 of inductive coils 704 and 706 decreases with an increase in chip-to-chip distance 402 between inductive coils 704 and 706. Consequently, coupling coefficient k 1608 expoentially decreases and approaches to zero as chip-to-chip distance 402 increases beyond 600 micrometers.

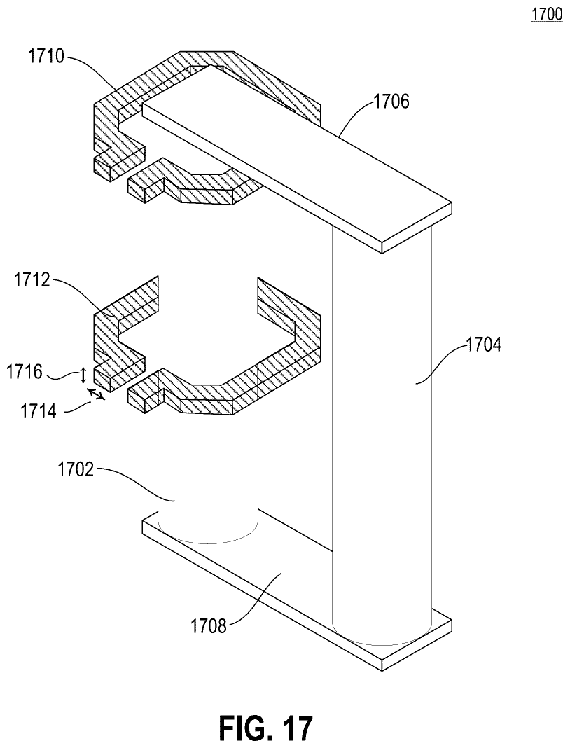

FIG. 17 is a schematic that illustrates a vertical transformer 1700 of a ferromagnetic transformer, wherein FTSVs 1702 and 1704 are connected at the top and bottom by ferromagnetic lines 1706 and 1708, forming vertical transformer 1700, in accordance with at least one example. Width 1714 and thickness 1716 are the width and thickness of the trace of inductive coils 1710 and 1712. In at least one example, vertical transformer 1700 provides approximately near unity coupling between inductive coils 1710 and 1712, as it completes the reluctance path for magnetic fields at the expense of a large chip area. In at least one example, self inductances are 2.95 nanohenry, mutual inductance is 2.83 nanohenry, and inductive coupling coefficient is 0.96.

In at least one example, ferromagnetic lines 1706 and 1708, as illustrated in FIG. 17, are deposited in a 3D IC using one of via-first, via-middle, or via-last methods depending on an application. In at least one example, ferromagnetic line 1706 is made at the top of the second chip, and ferromagnetic line 1708 is made at the bottom of the first chip underneath a substrate. A separate mask and process deposits the desired ferromagnetic material and can be used to make ferromagnetic lines 1706 and 1708. Both thin film and thick film deposition process can be used based on the desired thickness and smoothness of the deposited ferromagnetic layer.

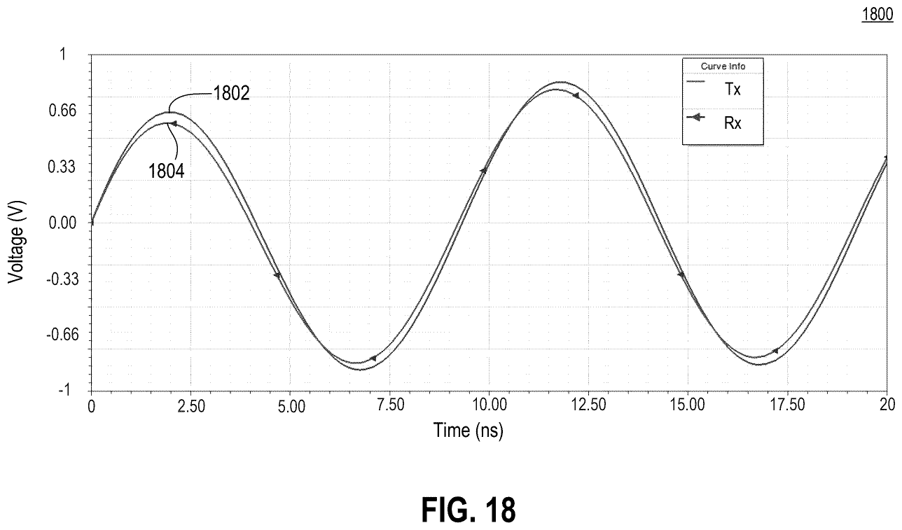

FIG. 18 is a plot 1800 that illustrates a coupling result of the inductive link established between inductive coils 1710 and 1712 of FIG. 17 by using test circuit 500 of FIG. 5 with a signal frequency of 100 megahertz, in accordance with at least one example. Signals 1802 and 1804 are the normalized voltage waveforms of V_{TX} 508 and V_{RX} 510, respectively. It is evident that the coupling efficiency of the inductive link, between inductive coils 1710 and 1712, has significantly improved to a near unity and the received signal 1804 strength is comparable to that of transmitted signal 1802 strength. In this example, voltage gain of the structure of FIG. 17 is −0.42 decibels, and the power gain is −34.6 decibels with a 10 kiloohm load. Vertical transformer 1700 ensures that the inductive coils may achieve a near unity coupling, as illustrated in plot 1800, which is a significant improvement than coupling of inductive coils 704 and 706 as illustrated in plot 800.

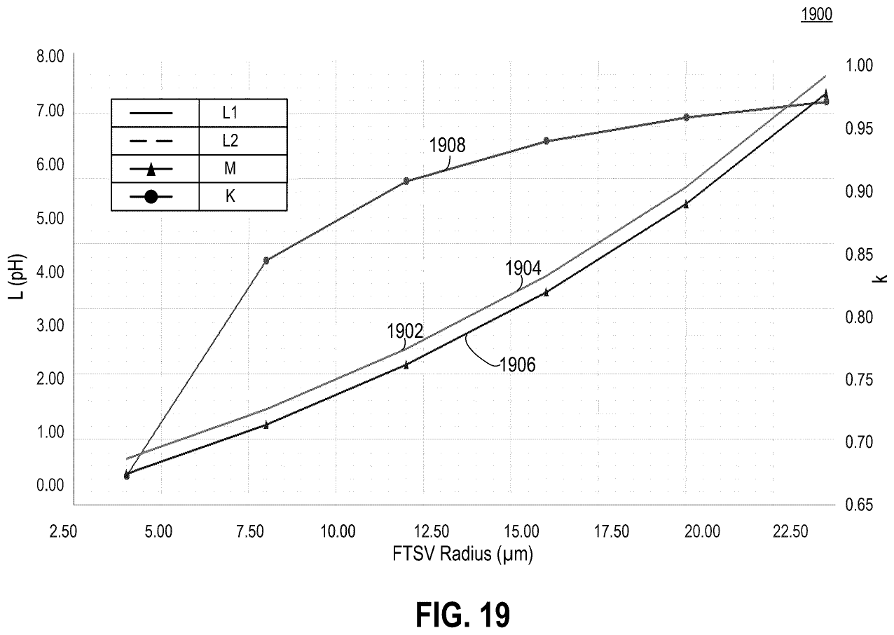

FIG. 19 shows a plot 1900 that illustrates the dependence of inductances and the coupling coefficients on the radii of FTSVs 1702 and 1704, provided the inductive coil dimensions remain fixed, in accordance with at least one example. Here, inner radius 404 is set to 50 micrometers, width 406 is 5 micrometers, and thickness 408 is 3.4 micrometers. In at least one example, radius 708 of FTSV is varied from 15 micrometers up to 30 micrometers. In at least one example, self inductances are L1 1902 and L2 1904, mutual inductance is M 1906, and inductive coupling coefficient is k 1908. The increase in the radii of FTSVs 1702 and 1704 consequently results in an increase in self inductances L1 1902 and L2 1904, mutual inductance M 1906 and coupling coefficient k 1908, which is due to the higher permeabillity of FTSVs 1702 and 1704 with larger radiii in comparison to FTSVs 1702 and 1704 with smaller radii.

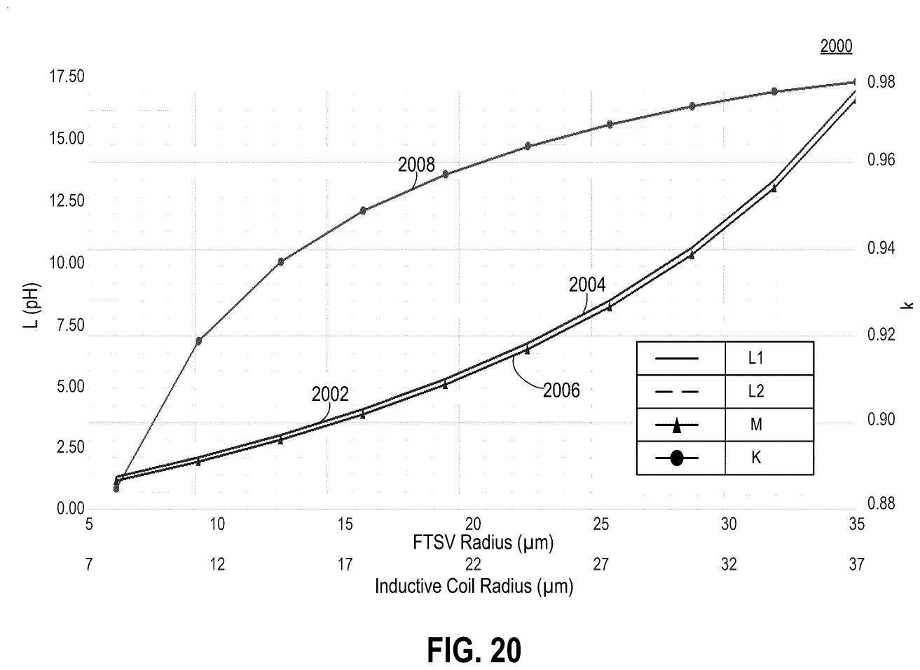

FIG. 20 is a plot 2000 that illustrates the dependence of the inductances and the coupling coefficients on the radii of FTSVs 1702 and 1704 as well as on inner radius 404 of inductive coils 1710 and 1712, in accordance with at least one example. Here, width 1714 and thickness 1716 of inductive coils 1710 and 1712 is 5 micrometers and 3.4 micrometers, respectively. The radii of FTSVs 1702 and 1704 are varied from 10 micrometers to 30 micrometers, while inner radius 404 of inductive coils 1710 and 1712 increases from 12 to 32 micrometers with a 2 micrometers clearance between them and FTSV 1702. The increase in radii of FTSVs 1702 and 1704 consequently results in an increase in self inductances L1 2002 and L2 2004, mutual inductance M 2006 and coupling coefficient k 2008, which is due to the higher permeabillity of FTSVs 1702 and 1704 with larger radiii in comparison to FTSVs 1702 and 1704 with smaller radii.

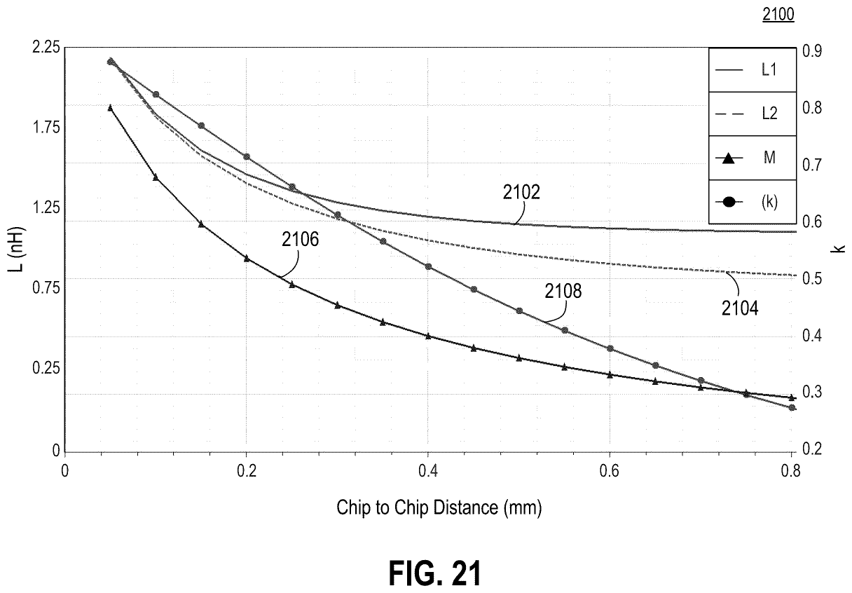

FIG. 21 is a plot 2100 that shows the dependence of the inductances and the coupling coefficient on the chip-to-chip distance 402, in accordance with at least one example. In at least one example, radius 708 of each of FTSVs 1702 and 1704 is set to 50 micrometers, inner radius 404 is 52 micrometers, width 406 is 5 micrometers, and thickness 408 is 3.4 micrometers. In accordance with at least one example, chip-to-chip distance 402 is varied from 50 micrometers to 800 micrometers. Self inductances L1 2102 and L2 2104, mutual inductance M 2106, and inductive coupling coefficient k 2108 change with a change in the chip-to-chip distance 402. Plot 1200 illustrates the deteriorating coupling performance with an increase in chip-to-chip distance 402 between inductive coils 1710 and 1712.

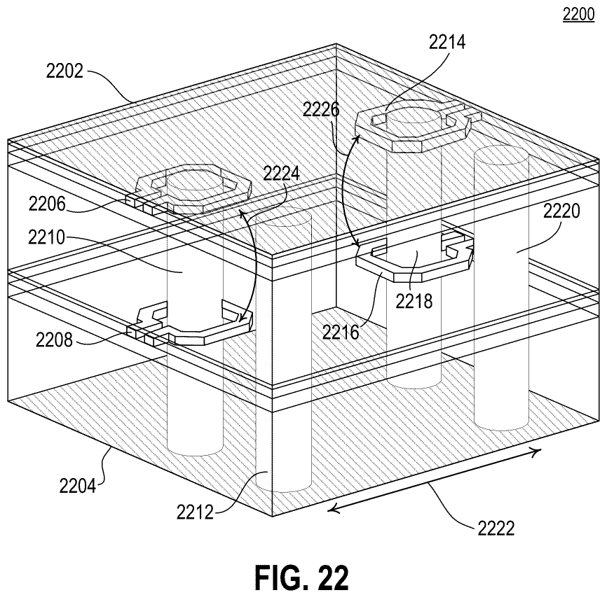

FIG. 22 is a schematic that illustrates an example structure 2200, wherein ferromagnetic lines 1706 and 1708 of FIG. 17 are replaced by continuous sheets 2202 and 2204, in accordance with at least one example. Two different ferromagnetic transformer structures with four ferromagnetic through silicon vias 2210, 2212, 2218, and 2220, and four inductive coils 2206, 2208, 2214, and 2216 illustrate the behavior of the ferromagnetic transformer using the continuous sheets 2202 and 2204. A first inductive link 2224 is established between inductive coils 2206 and 2208 using FTSVs 2210 and 2212, and a second inductive link 2226 is established between inductive coils 2214 and 2216 using FTSVs vias 2218 and 2220, in accordance with at least one example. In at least one example, the links are at a link-to-link distance 2222 to minimize the interference between them.

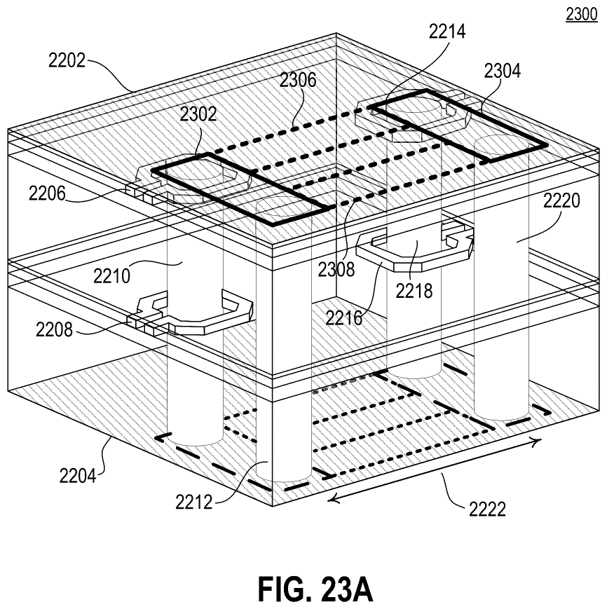

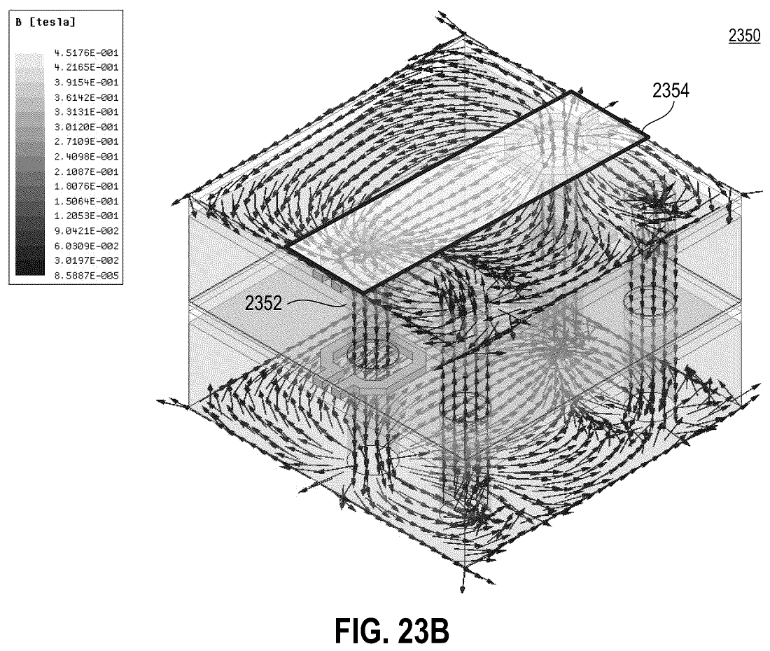

FIG. 23A is a schematic 2300 that illustrates the low reluctance paths of ferromagnetic sheets 2202 and 2204 through which the magnetic fields travel in structure 2200, in accordance with at least one example. Although magnetic fields travel through the entire sheets, the field intensity of the magnetic fields drops as a function of the distance from the center of an FTSV, such as FTSVs 2210 and 2218. A bounded region around FTSVs is used to approximate the path reluctance. In at least one example, the path reluctance of sheet 2202 from FTSV 2210 to FTSV 2212 is modeled as a function of the area of region 2302. Similarly, the path reluctance of sheet 2202 from FTSV 2218 to FTSV 2220 is modeled as a function of the area of region 2304. Also the reluctance from FTSV 2210 to t FTSV 2218 is modeled as a function of the area of region 2306, and that from FTSV 2212 to FTSV 2220 is modeled as a function of the area of region 2308, in accordance with at least one example. Similar paths are also illustrated for ferromagnetic sheet 2204.

FIG. 23B is a schematic 2350 that illustrates the field plots of structure 2200 of FIG. 22, in accordance with at least one example. The magnetic field traverses primarily through the low reluctance paths provided by ferromagnetic sheets 2202 and 2204 and FTSVs 2210, 2212, 2218, and 2220. In at least one example, the vertical paths of the magnetic fields (such as path 2352) go straight down through FTSVs 2210 and 2218, which avoids the lossy silicon region. These paths are modeled as reluctances using the dimensions of FTSVs. The horizontal paths traverse through an entire sheet, but with a decreasing field strength, in accordance with at least one example. Consequently, a portion of sheet 2202 with strong fields, for instance magnetic field region 2354 in sheet 2202, is used for modelling the behavior of a ferromagnetic transformer.

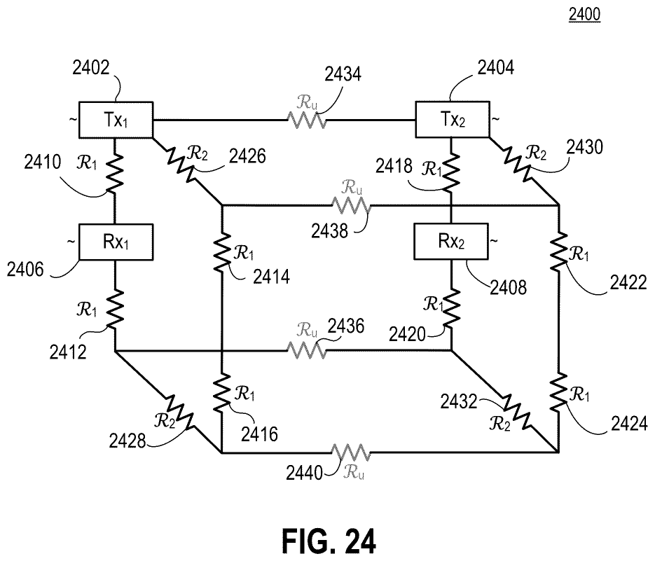

FIG. 24 is a schematic that illustrates a magnetic circuit model 2400 of structure 2200 of FIG. 22, in accordance with at least one example. In at least one example, magnetic circuit model 2400 simulates the behavior of FTSVs 2210 and 2218 by creating an equivalent electrical circuit for faster simulations. Tx₁ 2402 and Tx₂ 2404 are two transmitters, while Rx₁ 2406 and Rx₂ 2408 are two receivers. In at least one example, each ferromagnetic path is represented by a reluctance [symbol] , and the reluctances with the same values are labeled with the same subscript. For instance, [symbol] ₁ 2410 and [symbol] ₁ 2412 are two different circuit equivalent reluctances of different anatomical parts of the ferromagnetic through silicon via 2210 but have the same reluctance value because of the same physical dimensions and hence are labelled as [symbol] R₁. Similarly, reluctances [symbol] ₁ 2414 and 2416 model FTSV 2212, and reluctances [symbol] ₁ 2418 and 2420 model FTSV 2218, and reluctances [symbol] ₁ 2422 and 2424 model FTSV 2220. Reluctance [symbol] ₂ 2426 models the path length of ferromagnetic sheet 2202 from FTSV 2210 to ferromagnetic through silicon via 2212. Similarly, reluctance [symbol] ₂ 2428 models the path length of ferromagnetic sheet 2204 from FTSV 2210 to FTSV 2212. Reluctances [symbol] ₂ 2430 and [symbol] ₂ 2432 model the path lengths between FTSV 2218 and FTSV 2220 for ferromagnetic sheets 2202 and 2204, respectively. Thus, the path including reluctances [symbol] ₁ 2410, [symbol] ₁ 2412, [symbol] ₂ 2428, [symbol] ₁ 2416, [symbol] ₁ 2414, and [symbol] ₂ 2426 comprise a first inductive link 2224, and the path including reluctances [symbol] ₁ 2418, [symbol] ₁ 2420, [symbol] ₂ 2432, [symbol] ₁ 2424, [symbol] ₁ 2422, and [symbol] ₂ 2430 comprise a second inductive link 2226. On other hand, reluctances [symbol] ᵤ 2434 and 2436 model the path lengths of ferromagnetic sheets 2202 and 2204 between FTSVs 2210 and 2218, respectively. In a similar manner, the reluctances [symbol] ᵤ 2438 and [symbol] ᵤ 2440 model the path lengths of ferromagnetic sheets 2202 and 2204 between FTSVs 2212 and 2220, respectively.

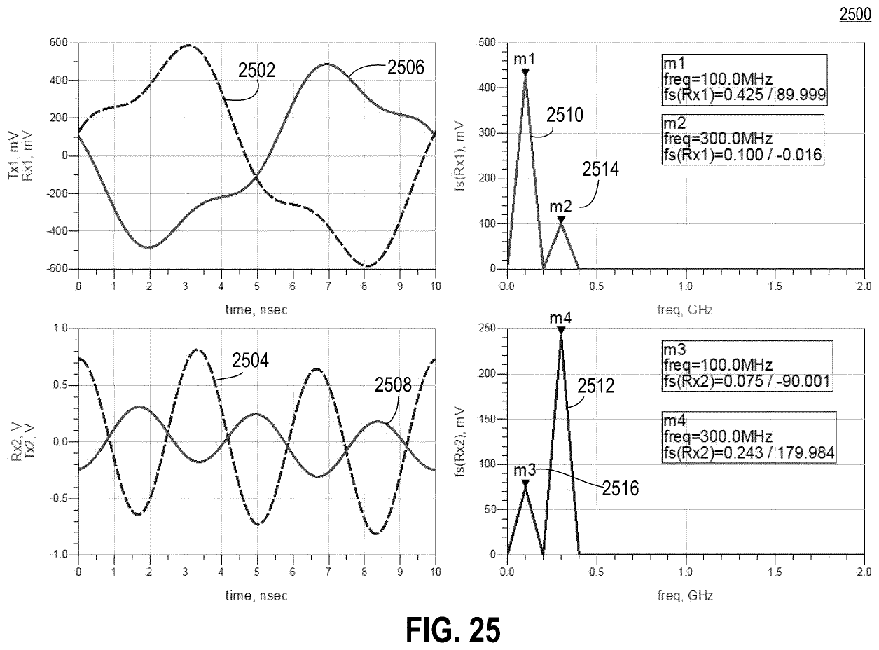

FIG. 25 is a set of plots 2500 that illustrates the behavioral simulation results of magnetic circuit model 2400 of FIG. 24, wherein transmitter Tx₁ 2402 is excited with a 100 megahertz signal 2502, and transmitter Tx₂ 2404 with a 300 megahertz signal 2504, in accordance with at least one example. Here, 100 megahertz signal 2502 of Tx₁ 2402 is received at Rx₁ 2406 as signal 2506. Similarly, 300 megahertz signal of Tx₂ 2404 is received at Rx₂ 2408 as signal 2508. However, inter signal interference due to the undesired path reluctances [symbol] ᵤ 2434, [symbol] ᵤ 2436, [symbol] ᵤ 2438, and [symbol] ᵤ 2440 causes both signals to mix with each other, as is apparent from the frequency responses in FIG. 25. In at least one example, frequency response 2510 of signal 2506 received at Rx₁ 2406 has an undesired coupling element m2 2514 at 300 megahertz, and frequency response 2512 of signal 2508 received at Rx₂ 2408 has an undesired coupling element m3 2516 at 100 megahertz. This phenomenon may be equivalent to inter symbol interference in the receiver or in the side channel leakage in the transmitter.

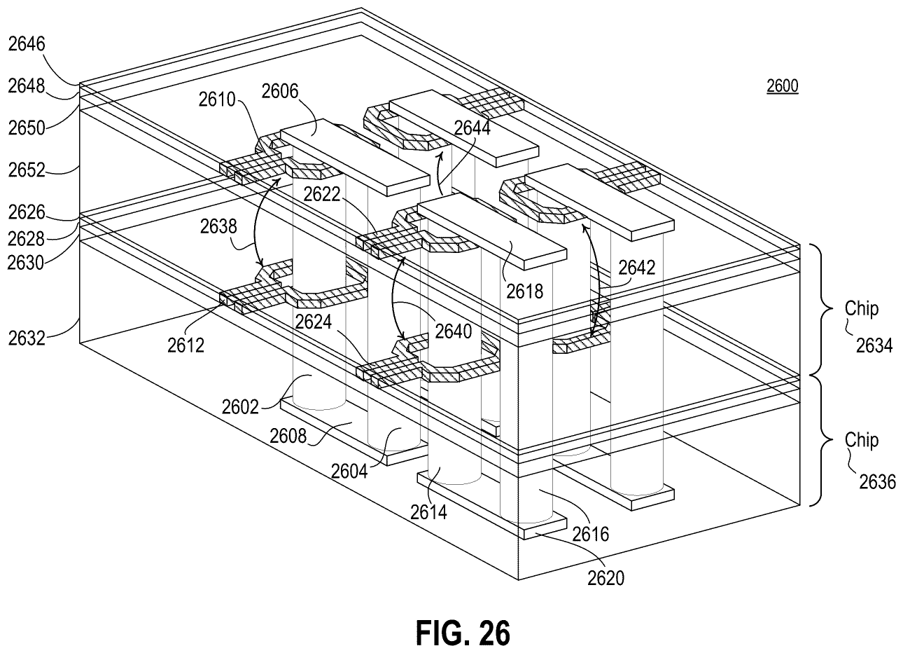

FIG. 26 is a schematic that illustrates an example structure 2600 of a 3D IC with multiple ferromagnetic transformers, with their inductive coils implemented on different chips, in accordance with at least one example. In at least one example, FTSVs 2602 and 2606 are connected to complete the flux path via ferromagnetic lines 2606 and 2608. In at least one example, first link 2638 comprises two FTSVs namely FTSVs 2602 and 2604, and inductive coils 2610 and 2612. Similarly, second link 2640 comprises FTSVs 2614 and 2616 that are connected through ferromagnetic lines 2618 and 2620, and it includes inductive coils 2622 and 2624. Two additional inductive links 2642 and 2644 are shown in FIG. 26. Furthermore, the schematic illustrates different layers of chip 2636 namely a passivation layer 2626, dielectric layers 2628 and 2630, and an active silicon layer 2632, in accordance with at least one example. These layers are also shown for chip 2634 namely passivation layer 2646, dielectric layers 2648 and 2650 and active silicon layer 2652. Example dimensions of structure are the same as that of the structure in FIG. 17.

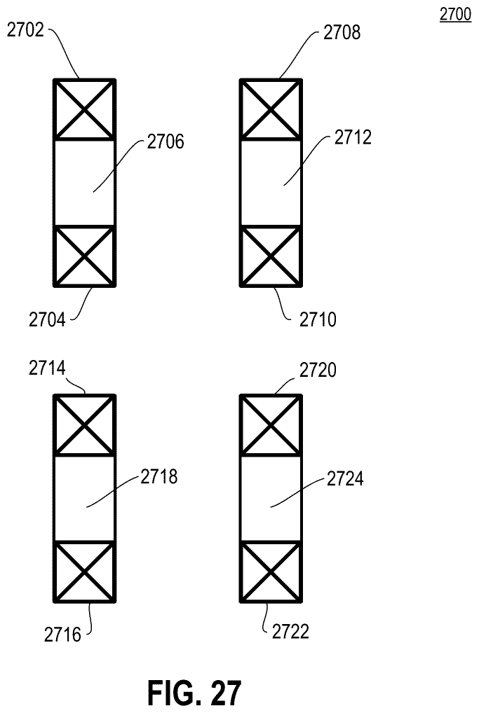

FIG. 27 is a schematic 2700 that illustrates different masks that may be used to create ferromagnetic tracks, ferromagnetic sheet segments, or lines of structure 2600 of FIG. 26, in accordance with at least one example. Here, ferromagnetic lines 2706, 2712, 2718, and 2724 represent ferromagnetic sheet segments at the top of chip 2634. Similarly, they can also be created at the bottom of chip 2636. Crosses 2702, 2704, 2708, 2710, 2714, 2716, 2720, and 2722 represent FTSVs that go through both chips, in accordance with at least one example. Other possible mask layouts may also be created according to the specifications of an FTSV.

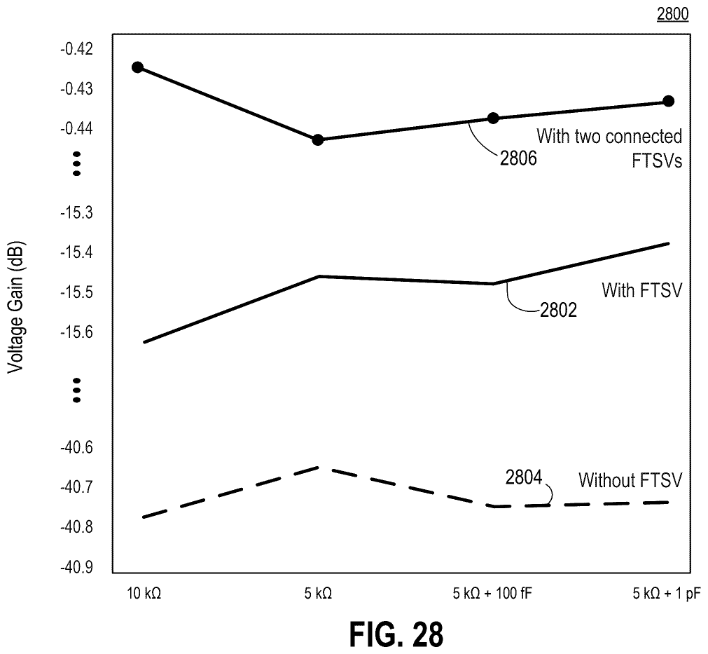

FIG. 28 is a plot 2800 that illustrates a comparison of the voltage gain as a function of the load impedance, in accordance with at least one example. A voltage gain signal 2802 for structure 700 of FIG. 7, voltage gain signal 2804 for structure 300 of FIG. 3, and voltage gain signal 2806 for structure 1700 of FIG. 17 are illustrated for a comparison. In at least one example, the change in voltage as a function of load changes is less than 1 decibels in all three cases. The voltage gain increases more than 10 decibels once FTSVs are added, and this is evident from voltage gain signals 2802 and 2806.

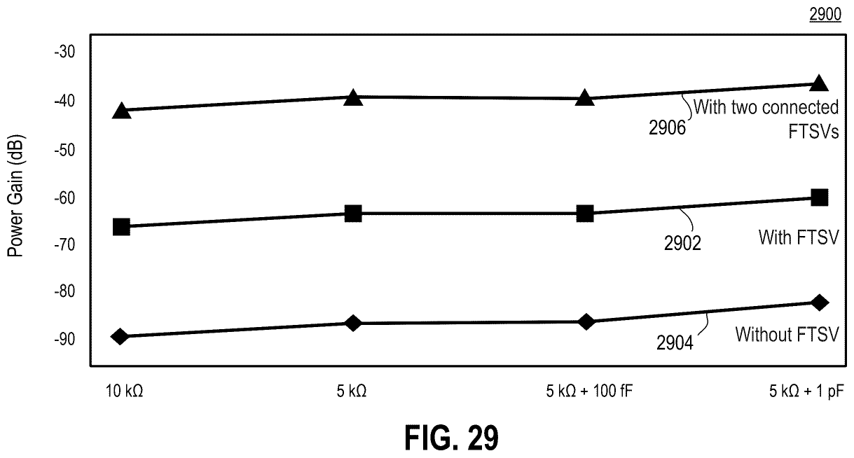

FIG. 29 is a plot 2900 that illustrates a comparison of the power gain as a function of the load impedance, in accordance with at least one example. Here, power gain signal 2902 with one FTSV for structure 700 of FIG. 7, and power gain signal 2904 without FTSV for structure 300 of FIG. 3, and power gain signal 2906 with the two connected FTSVs for structure 1700 of FIG. 17 are illustrated for a comparison. The power gain increases approximately 20 decibels once FTSVs are added, and this is evident from the behavior of power gain signals 2902 and 2906.

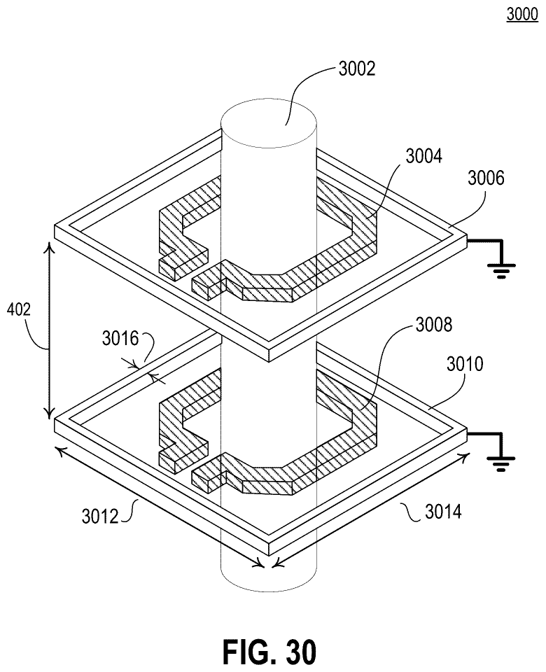

FIG. 30 is a schematic that illustrates an example structure 3000 of a ferromagnetic transformer comprising an inductive link that includes an FTSV 3002, an inductive coil 3004, and a guard ring 3006 in the top metal layer of a first chip, and an inductive coil 3008 and a guard ring 3010 in the top metal layer of a second chip in a 3D IC, in accordance with at least one example. The distance between the inductive coils, e.g., chip-to-chip distance 402, and the other dimensions of the inductive coils are the same as that of structure 700 of FIG. 7, in accordance with at least one example. Here, length 3012 of guard ring 3010 is 62 micrometers and width 3014 is 57 micrometers and trace width 3016 of guard ring 3010 is 2 micrometers.

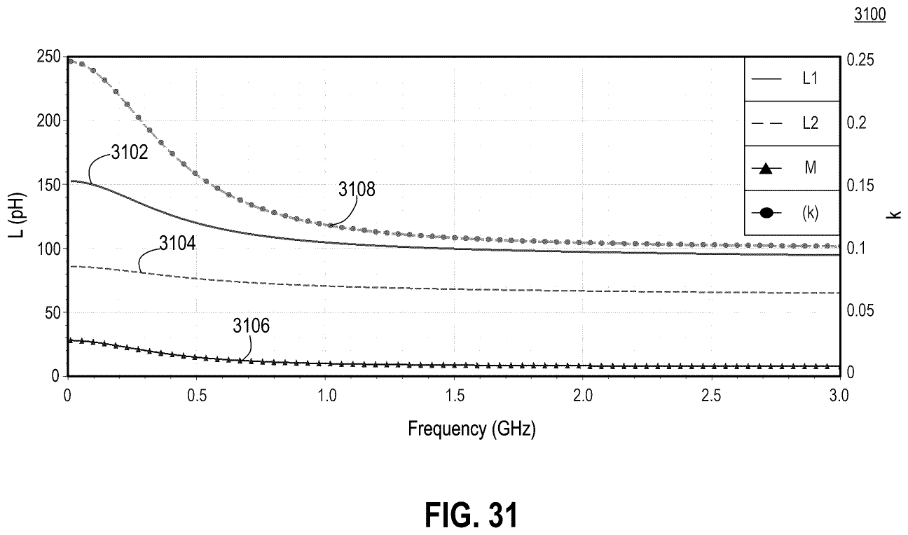

FIG. 31 is a plot 3100 that illustrates a behavior of the example structure 3000 with guard rings using [Co₉₀Fe₁₀/Ta]₁₅ material in a frequency range of 0 to 3 GHZ, in accordance with at least one example. In this example, self-inductances 3102 and 3104 drop from 155.5 picohenry and 145.7 picohenry to 99.6 picohenry and 96.7 picohenry, respectively, and mutual inductance 3106 drops from 50 picohenry to 13.8 picohenry. Similarly, coupling coefficient k 3108 drops from 0.25 to 0.1 in this frequency range.

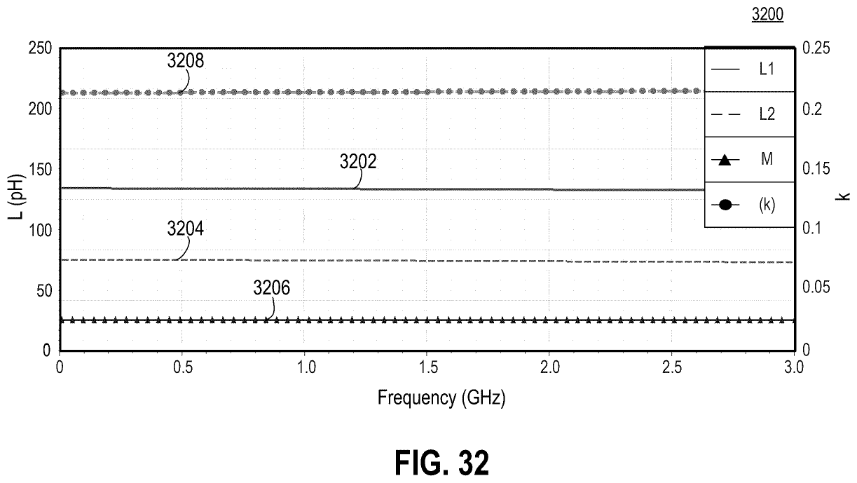

FIG. 32 is a plot 3200 that illustrates the behavior of an example structure 3000 of FIG. 30 without guard rings, using material [Co₉₀Fe₁₀/Ta]₁₅ in a frequency range from 0 to 3 GHz, in accordance with at least one example. In at least one example, self-inductances 3202, 3204, mutual inductance 3206, and coupling coefficient 3208 remain substantially constant with a change in the frequency.

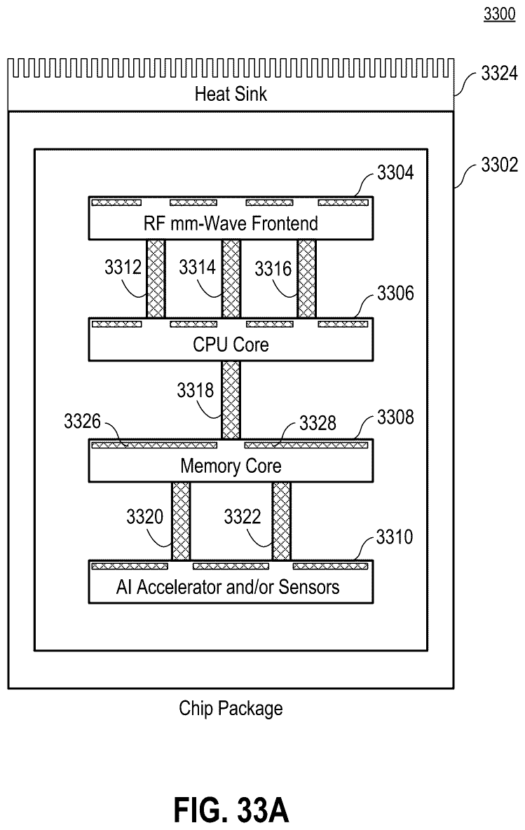

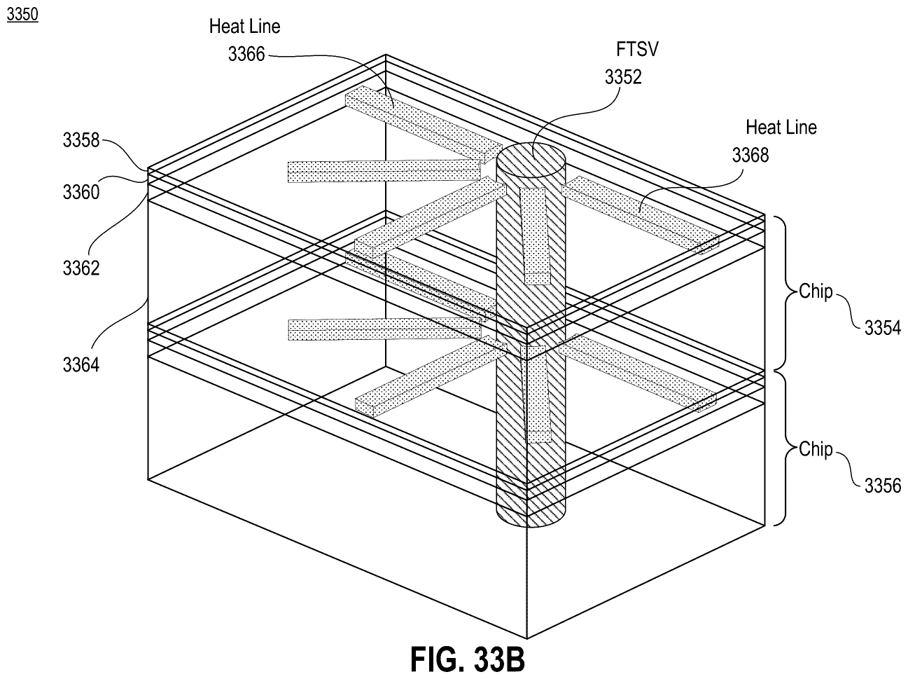

FIG. 33A is a schematic 3300 that illustrates a 3D IC comprising different dies with ferromagnetic through silicon vias and heat lines, in accordance with at least one example. The 3D IC comprises an RF mm-Wave Front end 3304, a CPU core 3306, a memory core 3308, and an AI accelerator and/or sensors 3310 inside a chip package 3302. In at least one example, a heat sink 3324 is also present with chip package 3302. In at least one example, dies inside package are connected through FTSVs. For example, RF mm-Wave Frontend 3304 and CPU core 3306 are connected through FTSVs 3312, 3314, and 3316. Similarly, CPU and memory cores 3306 and 3308 are connected through FTSV 3318, and memory core 3308 and AI accelerator and/or sensors 3310 are connected through FTSVs 3320 and 3322. Each chip also contains heat lines such as heat lines 3326 and 3328 on memory core 3308. These electrically insulated and non-magnetic heat lines collect heat from the hot spots in the ICs e.g., memory core 3308 and conduct the heat towards FTSVs (e.g., FTSV 3318). In at least one example FTSVs extending through dies act as a heat pipe and provide thermal pathways for the heat dissipation but with a low thermal resistance. FIG. 33A illustrates a few such examples, however, several other examples of these FTSVs are possible in 3D ICs.

FIG. 33B is a schematic 3350 that illustrates a 3D integrated circuit (3D IC) comprising heat lines on different dies, thermally connected through FTSV 3352, in accordance with at least one example. In at least one example, 3D IC comprises two chips, chips 3354 and 3356, wherein each chip on the 3D IC includes multiple layers such as passivation layer 3358, dielectric layers 3360 and 3362, and active silicon layer 3364 on chip 3354. An FTSV 3352 passes through two chips 3354 and 3356. Each chip also contains multiple heat lines, such as heat lines 3366 and 3368 on chip 3354. These heat lines, being electrical insulators, non-magnetic, and thermally conductive, form thermal pathways from hotspots on chips 3354 and 3356 towards FTSV 3352. In at least one example, FTSV 3352 carries this heat towards a heat sink or the ambient environment.

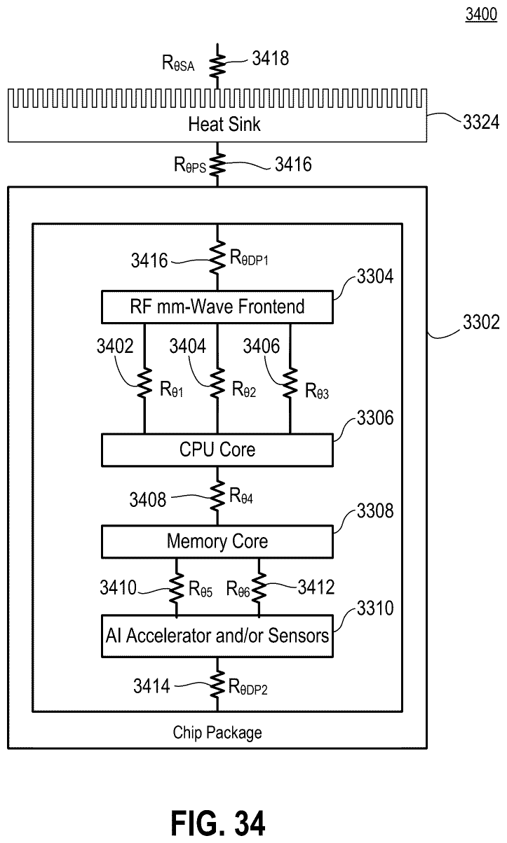

FIG. 34 is a schematic that illustrates a heat dissipation model 3400 of 3D integrated circuit shown in FIG. 33A to illustrate the benefits of using ferromagnetic through silicon vias, in accordance with at least one example. Each FTSV may provide a low thermal resistance Ren among the dies that it connects. FTSV 3318 between CPU core 3306 and memory core 3308 of FIG. 33A is modeled as a thermal resistance R_{θ4} 3408. Similarly, other FTSVs are modeled as well: R_{θ1} 3402, R_{θ2} 3404, and R_{θ3} 3406 from CPU core 3306 to RF mm-Wave Frontend 3304; and R_{θ5} 3410, and R_{θ6} 3412 from memory core 3308 to AI accelerator and/or sensors 3310. The thermal resistance from the top die in 3D IC e.g., RF mm-Wave Frontend 3304 to chip package 3302 is modeled as R_{θDP1} 3416. Similarly, the thermal resistance from bottom die, e.g., AI accelerator and/or sensors 3310 to chip package 3302 is modeled as R_{θDP2} 3414. The thermal resistance from chip package 3302 to heat sink 3324 is modeled as Reps 3416 and that from heat sink 3324 to the ambient environment is modeled as R_{θSA} 3418.

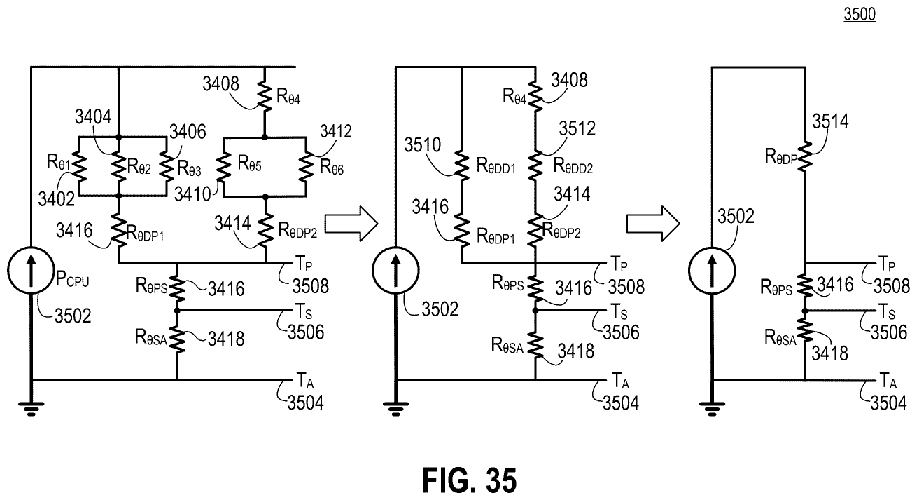

FIG. 35 is a schematic that illustrates a thermal model 3500 of a 3D integrated circuit of FIG. 32, in accordance with at least one example. An equivalent circuit model with one heat source P_{CPU} 3502 is used; however, other chips in the package can also dissipate heat in which case the equivalent circuit model may have additional heat sources. The heat generated by processor P_{CPU} 3502 radiates through the ferromagnetic vias to the adjacent dies and then eventually to the chip package. In at least one example, the thermal resistances of the ferromagnetic through silicon vias at a given layer are modeled as a parallel combination of resistances, and subsequently these parallel thermal resistances are combined into a series resistance to have an overall equivalent circuit of the thermal resistances of the complete package. This model is used to calculate the maximum power that can be dissipated for a given ambient temperature and the maximum tolerable CPU temperature. For the equivalent circuit model 3500, maximum power P_{Max} is:

$${P}_{Max} = \frac{{T}_{J} - {T}_{A}}{{R}_{θ T}} = \frac{{T}_{J} - {T}_{A}}{{R}_{θ DP} + {R}_{θ PS} + {R}_{θ SA}} \qquad ( 1 )$$

wherein P_{Max} is the maximum power that is dissipated, T_{J} is the maximum allowable junction temperature, T_{A} 3504 is the ambient temperature, and R_{θT} is the total thermal resistance.

$${R}_{θ DP} = ( {R}_{θ DD 1} + {R}_{θ DP 1} ) \vert \vert ( {R}_{θ 4} + {R}_{θ DD 3} + {R}_{θ DP 2} ) \qquad ( 2 )$$

$${R}_{θ DD 1} = {R}_{θ 1} ‖ {R}_{θ 2} ‖ {R}_{θ 3} \qquad ( 3 )$$

$$and$$

$${R}_{θ DD 2} = {R}_{θ 5} \vert \vert {R}_{θ 6} \qquad ( 4 )$$

In at least one example, the thermal resistances of FTSVs 3312, 3314, 3316, 3318, 3320 and 3322 are modelled as R_{θ1} 3402, R_{θ2} 3404, R_{θ3} 3406, R_{θ4} 3408, R_{θ5} 3410, and R_{θ6} 3412, respectively. The thermal resistance from die 3304 to package 3302 of model 3300 are modelled as R_{θDP1} 3416, and the thermal resistance from die 3310 to package 3302 is R_{θDP2} 3414. The thermal resistance from package 3302 to heat sink 3324 is R_{θPS} 3416 and from heat sink 3324 to the ambient environment is R_{θSA} 3418. T_{S} 3506 is the heat sink temperature, T_{P} 3508 is the package temperature, and R_{θT} is the total thermal resistance from the die to the ambient environment. The total thermal resistance is calculated by using parallel and series combinations. For instance, thermal resistances R_{θ1} 3402, R_{θ2} 3404, and R_{θ3} 3406 of FTSVs 3312, 3314 and 3316, respectively, are combined in parallel into die-to-die thermal resistance R_{θDD1} 3510, in accordance with at least one example. Similarly, thermal resistance R_{θ5} 3410, and thermal resistance R_{θ6} 3412 of FTSVs 3320 and 3322 are combined in parallel to get die-to-die thermal resistance R_{θDD2} 3512. Resulting thermal resistances are combined in a series combination of R_{θDP} 3514, R_{θPS} 3416, and R_{θsA} 3418. In at least one example, FTSVs make the heat management of chips in a 3D IC significantly easier and efficient. The ferromagnetic materials that have high permittivity and low thermal resistance can be used for FTSVs, in accordance with at least one example.

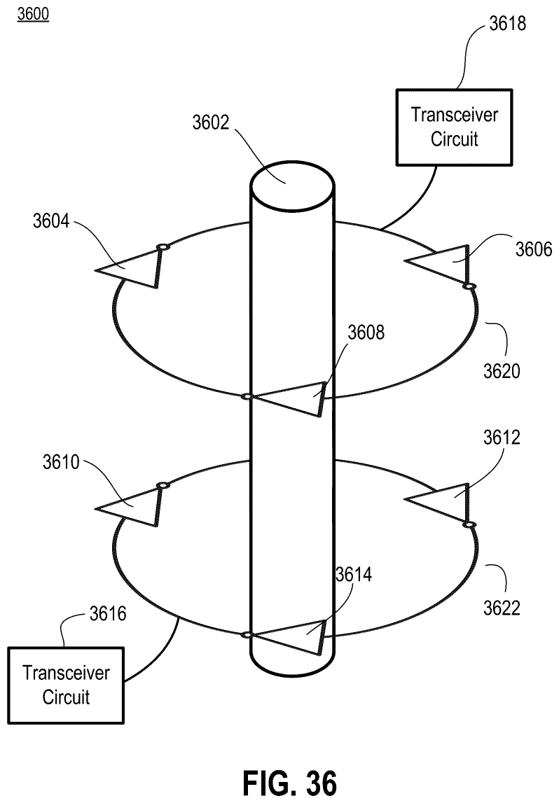

FIG. 36 is a schematic that illustrates an example structure 3600 of a ferromagnetic transformer in which ring oscillators are used instead of inductive coils around an FTSV 3602 for establishing a communication link between different chips in a 3D IC, in accordance with at least one example. A first ring oscillator 3620 comprises inverters 3604, 3606, and 3608, and second ring oscillator 3622 comprises inverters 3610, 3612, and 3614. In at least one example, either of the two ring oscillators generates desired currents that produce a magnetic flux in FTSV 3602 which makes the two ring oscillators to oscillate synchronously at the resonant frequency because of the frequency interlocking phenomenon. Consequently, in at least one example, both ring oscillators may also act as a transmitter-receiver pair. Data is transmitted and received using a transceiver circuit 3616 and transceiver circuit 3618, in accordance with at least one example.

In at least one example, if first oscillator 3620 is excited by its transceiver circuit and oscillates on frequency f1, and second oscillator 3622 oscillates at f1, then its transceiver receives data from first ring oscillator 3620. Similarly, if second oscillator 3622 oscillates at frequency f2, then first oscillator 3620 also synchronizes its oscillation frequency with the frequency f2, and subsequently its transceiver 3616 receives the data.

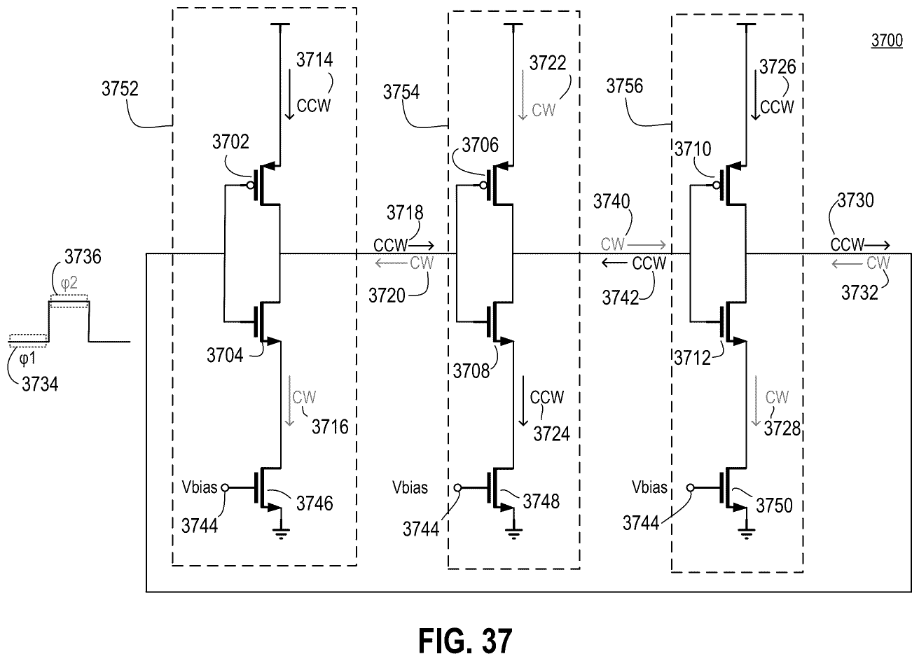

FIG. 37 is a schematic that illustrates different paths of the current passing through the invertors along with their directions around an FTSV, in a ring oscillator 3700, in accordance with at least one example. The alternate inverters in ring oscillator 3700 are activated with the opposite phases. For a first phase φ1 3734, the inputs of inverters 3752 and 3756 are low and that of inverter 3754 is high. For a second phase φ2 3736, the inputs of inverters 3752 and 3756 are high and that of second inverter 3754 is low. In at least one example, the inverters around FTSV 3602 may be configured such that the direction of all currents around the FTSV 3602 is same for one given phase, and their directions reverse when the phase is reversed.

During first phase φ1 3734, current 3714 flows through a transistor PMOS 3702 to an output of a first inverter in a counterclockwise (CCW) direction, and current 3718 from the output of first inverter 3752 flows through the gate of a second inverter in a CCW direction. During first phase φ1 3734, current 3724 at the output of a second inverter 3754 is discharged to ground through NMOS 3708 in the same CCW direction, and current 3742 from the gate capacitance of a third inverter 3756 discharges through the output of second inverter 3754 in a counterclockwise direction. Current 3726 flows through a PMOS 3710 to the output of third inverter 3756 in a counterclockwise direction, and current 3730 from the output of third inverter 3756 flows towards a gate of the first inverter 3752 in a counterclockwise direction. The remaining transistors 3704, 3706, and 3712 are in a cut off state during this phase, consequently, they may not conduct a significant amount of current in this time duration.

During a second phase φ2 3736, all other currents namely current 3716 through NMOS 3704, current 3720 from the gate of second inverter 3754 to the output of the first inverter 3752, current 3722 through PMOS 3706 flows in a clockwise direction from one inverter to the next and to the ground. Similarly, current 3740 from the output of second inverter 3754 to the gate of third inverter 3756, current 3728 through the NMOS 3712, and finally current 3732 from the gate capacitance of first inverter 3752 to the output of third inverter 3756, flows in a clockwise direction. In at least example, remaining transistors 3702, 3708, and 3710 are in a cutoff state during this phase, consequently, they do not conduct in this time duration.

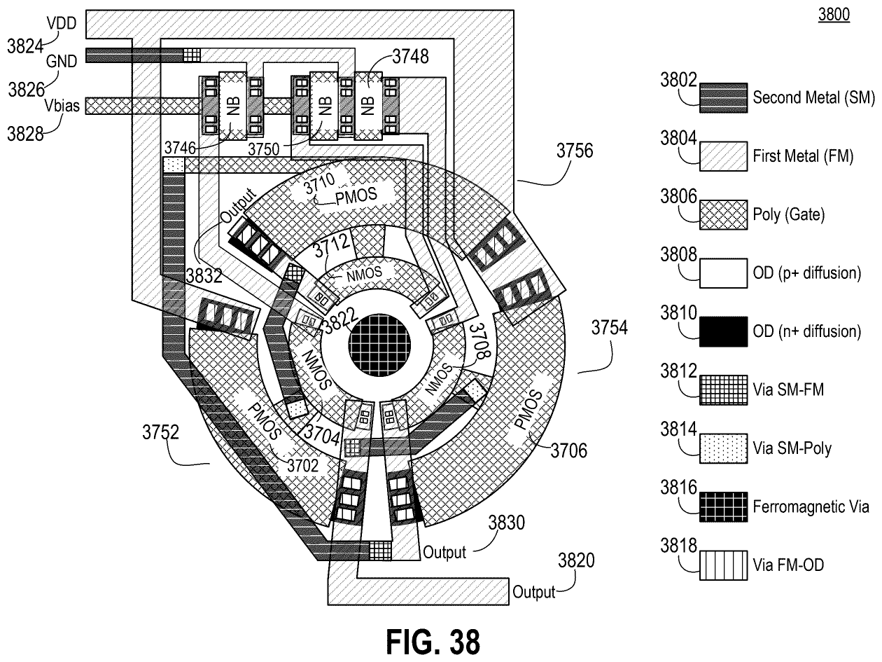

FIG. 38 is a schematic that illustrates a layout 3800 of an example structure of a ferromagnetic transformer with a ring oscillator that generates the desired currents to induce magnetic fields in a ferromagnetic through silicon via, in accordance with at least one example. In at least one example, the inverters include transistors 3702, 3704, 3706, 3708, 3710, and 3712, which are made in a way that their channels are long and curved around FTSV 3822. In at least one example, NMOS transistors 3704, 3708, and 3712 are of relatively smaller width and PMOS transistors 3702, 3706, and 3710 are of relatively larger width to allow for similar amounts of current to flow through them. In at least one example, first inverter 3752 comprises PMOS transistor 3702 and NMOS transistor 3704. In at least one example, second inverter 3754 comprises PMOS transistor 3706 and NMOS transistor 3708. In at least one example, third inverter 3756 comprises transistors PMOS 3710 and NMOS 3712. In at least one example, output 3820 of first inverter 3752 is fed into second inverter 3754, output 3830 of second inverter 3754 is fed into third inverter 3756, and finally output 3832 of third inverter 3756 is fed into first inverter 3752. The metal interconnects comprising a first metal 3804 (FM) and a second metal 3802 (SM) are used to make circuit connections, and to route the power supply VDD 3824 and GND 3826 rails. In at least one example, via SM-FM 3812 is used to interconnect first metal 3804 and second metal 3802 signals. Via FM-OD 3818 connects the p+ diffusion layer 3808 and the n+ diffusion layer 3810, and this comprises sources and drains of both types of devices to FM 3804. Via SM-poly 3814 connects the gate to SM 3802. In at least one example, the source of PMOS transistor 3702 is connected to VDD 3824 using the vias of FM-OD 3818 and a track of FM 3804, while the drain of PMOS transistor 3702 is connected to the drain of NMOS transistor 3704 using vias FM-OD 3818 and the track of FM 3804.

The source of NMOS transistor 3704 is connected to the drain of NB 3746 through the vias of FM-OD 3818 and the track of FM 3804; while the source of NB 3746 is connected to GND 3826 through the interconnects of FM-OD 3818 and track of FM 3804 that is followed by the interconnect of SM-FM 3812 and the track of SM 3802. In at least one example, the gate of NB 3746 is connected to Vbias 3828 through the track of poly 3806. This comprises the first inverter 3752 and its bias transistor 3746. The output 3820 of the first inverter 3752 from the drains of both PMOS 3702 and NMOS 3704 is taken through the FM 3804 track, and is also fed to the gates of the second inverter 3754 comprising NMOS 3708 and PMOS 3706 through via SM-FM 3812, the track of SM 3802 and via SM-poly 3814. In a similar fashion, the second and third inverters are laid out except that the sources of NMOS 3708 and NMOS 3712 go to the bias transistors NB 3748 and NB 3750, respectively. The gates of the bias transistor 3748 and bias transistor 3750 are connected to Vbias 3828 through the track of poly 3806, like NB 3746.

In at least one example, the sources of bias transistors are connected to GND 3826 through conductive via FM-OD 3818, the track of FM 3804, via SM-FM 3812 and the track of SM 3802; thereby completing layout 3800 of circuit 3700 of FIG. 37. The transistors and metal interconnects are routed around output 3820 of FTSV 3816 to keep the current in the circuit in the same direction in a given phase as described in circuit 3700 of FIG. 37. In at least one example, the bias controlling transistors namely transistors 3746, 3748, and 3750 are also laid out around FTSV 3822 to enhance the strength of flux significantly. In at least one example, the ring oscillators with a higher number of inverters may also be utilized.

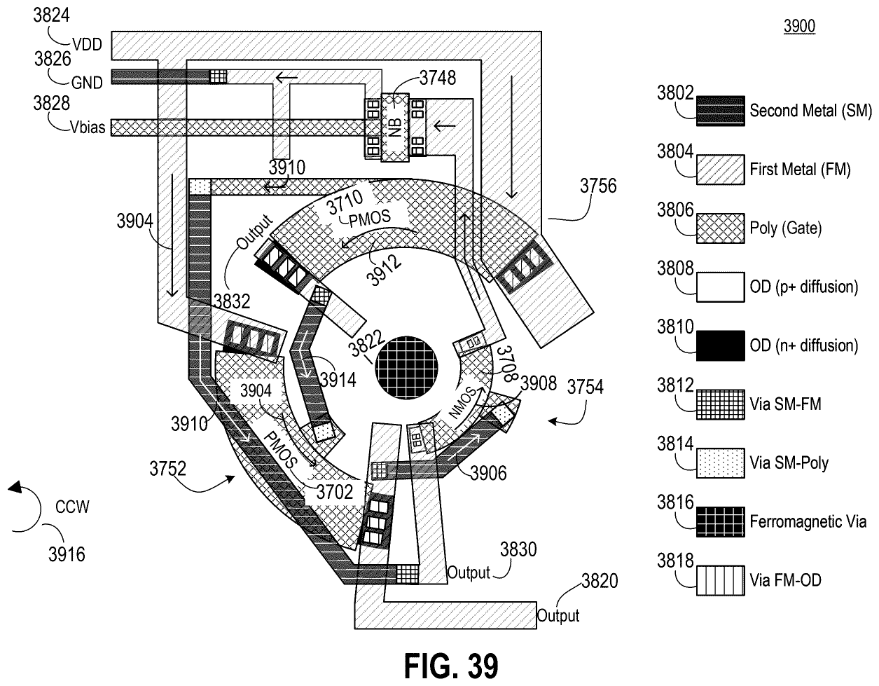

FIG. 39 is a schematic that illustrates a state 3900 of the active devices and the paths of currents passing through different devices in the layout 3800 of a ring oscillator circuit layout 3800 of FIG. 38 during first phase φ1 3734, in accordance with at least one example. A current from the VDD 3824 passes through PMOS transistor 3702 as a channel current 3904 in a counterclockwise (CCW) direction 3916 and reaches at output 3820. In at least one example, current 3906 from output 3820 of first inverter 3752 charges the gate capacitances of NMOS transistor 3708 of second inverter 3754 through the second metal interconnect in counterclockwise direction 3916. In at least one example, second inverter 3754 is discharged to GND 3826 through channel current 3908 of NMOS transistor 3708 in counterclockwise direction 3916. In at least one example, current 3910 from the gate capacitance of PMOS 3710 reaches output 3830 in counterclockwise direction 3916. The current supplied by VDD 3824 charges the capacitance at the output 3832 through channel current 3912 of PMOS transistor 3710 in a counterclockwise direction 3916. In at least one example, current 3914 from output 3832 charges the gate capacitance of PMOS transistor 3702 in counterclockwise direction 3916. Consequently, currents in first phase φ1 3734 flows in counterclockwise direction 3916 that reinforces the flux, which is generated by the net current flowing in a loop around FTSV 3822.

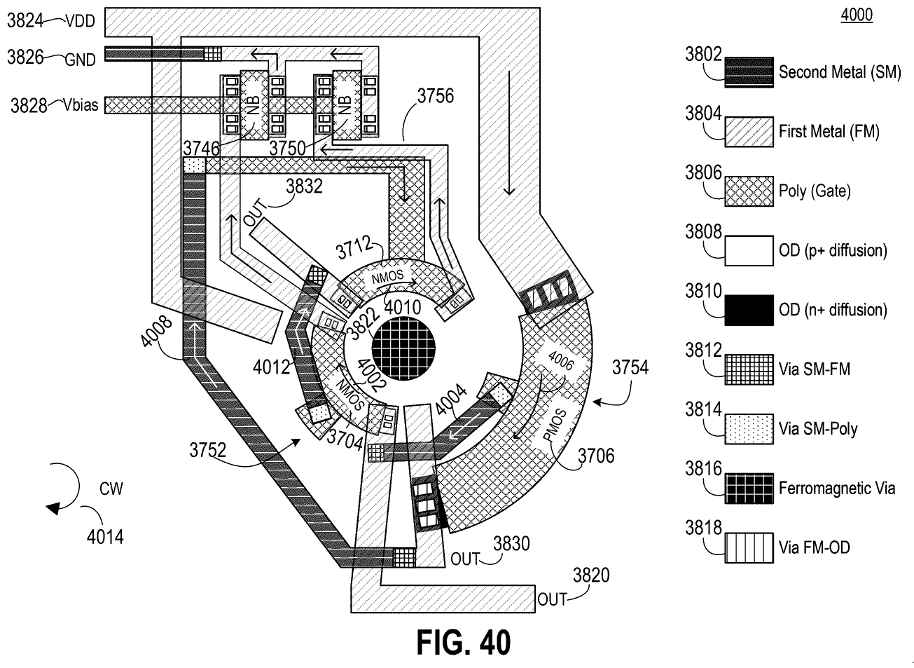

FIG. 40 is a schematic that illustrates a state 4000 of the active devices and paths of currents passing through different active devices in the state 4000 of a ring oscillator layout 3800 of FIG. 38 during second phase φ2 3736, in accordance with at least one example. An output 3820 of first inverter 3752 is discharged to GND 3826 through channel current 4002 of NMOS transistor 3704 flowing in a clockwise direction 4014. In at least one example, the gate capacitance of second inverter 3754 is discharged through current 4004 to output 3830 via second metal interconnect 3802 in a clockwise direction 4014. The current from VDD 3824 charges the gate capacitances at output 3830 through channel current 4006 of PMOS transistor 3706 in a clockwise direction 4014. Current 4008 from output 3830 of second inverter 3754 charges the gate capacitances of NMOS 3712 of the third inverter through a second metal interconnect in a clockwise direction, in accordance with at least one example. In at least one example, third inverter 3756 is discharged to GND 3826 through channel current 4010 of NMOS transistor 3712 flowing in a clockwise direction 4014. The gate capacitance of first inverter 3752 is discharged through current 4012 to output 3832 in clockwise direction 4014, in accordance with at least one example. Consequently, currents in second phase φ2 3736 flow in clockwise direction 4014, which reinforces the flux generated by the net current flowing in a loop around FTSV 3822.

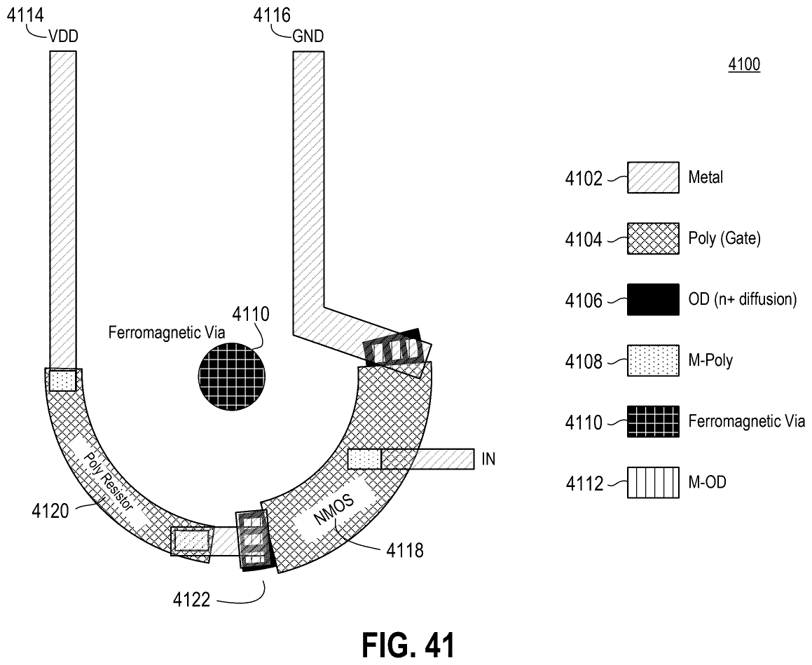

FIG. 41 is a schematic that illustrates a ferromagnetic transformer 4100 with a resistive circuit instead of the inductive coils, laid around FTSV 4110, in accordance with at least one example. A poly resistor 4120 is connected to a power line VDD 4114, and an NMOS transistor 4118 is connected to poly resistor 4120 at a drain 4122 and to GND 4116 line at its source via metal 4102 lines. In at least one example, poly resistor 4120 is made using silicide poly layer 4104, and is connected to powerline VDD 4114 using metal 4102 through via M-poly 4108. Similarly, the source of an NMOS transistor 4118 that is made in OD 4106 diffusion layer is connected to metal 4102 to GND 4116 through vias M-OD 4112, in accordance with at least one example.

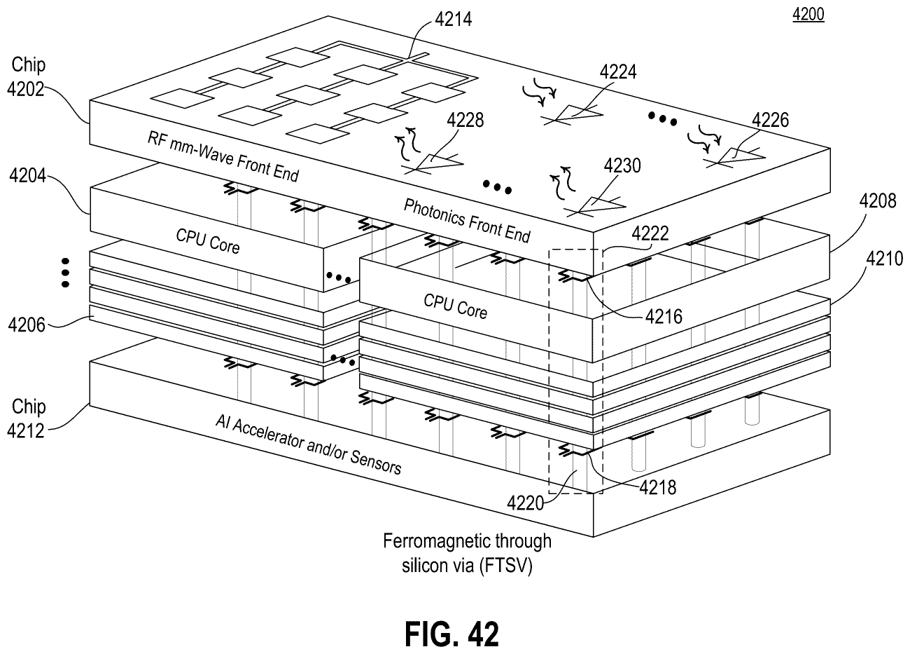

FIG. 42 is a schematic that illustrates a 3D integrated circuit 4200 with multiple ferromagnetic transformers, in accordance with at least one example. In at least one example, 3D IC 4200 includes a set of chips comprising chips from chip 4202 to chip 4212, wherein each chip serves a different function in the 3D IC stack and can be manufactured using a different technology. In at least one example, chip 4202 comprises a radio frequency (RF) mm-wave front end that includes antenna array 4214, a photonics front end comprising photo diodes 4224 and 4226, and light emitting diodes (LEDs) 4228 and 4230, and other auxiliary circuits for the photonics front end. In at least one example, chip 4204 is a CPU core, and memory 4206 is its corresponding memory. More CPU cores and memories can also be added in 3D IC 4200, such as CPU core 4208 and memory 4210, in accordance with at least one example.

In at least one example, chip 4212 is an AI accelerator integrated into 3D IC 4200. The number of chips and their placement in 3D IC 4200 depends on the applications' requirements, in accordance with one example. The inter-chip communication within 3D IC 4200 is enabled using a set of ferromagnetic transformers, such as ferromagnetic transformer 4222 which comprises on-chip resonating tanks 4216 and 4218, and FTSV 4220.

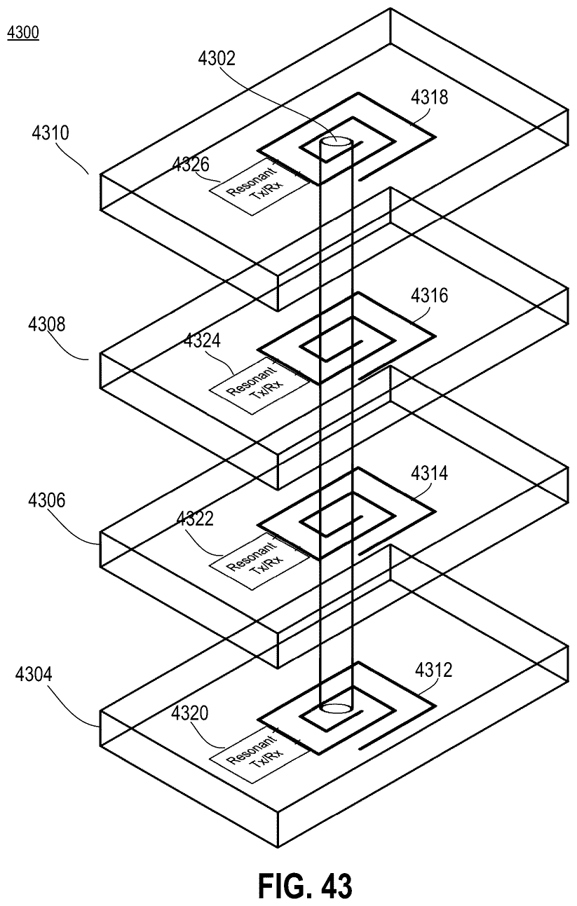

FIG. 43 is a schematic that illustrates a 3D IC 4300 with an FTSV 4302 going through four chips: chips 4304, 4306, 4308, and 4310, in accordance with at least one example. Each chip may have its own inductive coil and a resonant transmitting/receiving (Tx/Rx) circuit. For instance, chip 4304 includes inductive coil 4312 and resonant Tx/Rx circuit 4320, chip 4306 includes inductive coil 4314 and resonant Tx/Rx 4322, chip 4308 includes inductive coil 4316 and resonant Tx/Rx 4324, and chip 4310 includes inductive coil 4318, and resonant Tx/Rx 4326. The resonant Tx/Rx circuits can be implemented in a chip using an inductive coil and one or more on-chip capacitors to make a resonating tank circuit and a transceiver circuit to control the inter-chip communication, in accordance with at least one example.

In at least one example, the on-chip capacitor can be implemented as MIM (Metal Insulator Metal) capacitor, or MOM (Metal Oxide Metal) capacitor, or a combination thereof, or any other type of on-chip capacitor known to the ones skilled in the art. It may be implemented in the same area as that of the inductive coil on different metal layers, or it may also be implemented on a different area of a chip. In at least one example, the resonance frequency of a resonating tank can be set by controlling inductance and capacitance as known to the ones skilled in the art. Consequently, different resonating tank pairs in 3D IC 4300 may be operated at different resonant frequencies, and hence, data may be transmitted at multiple frequencies on the same channel. For instance, the resonant Tx/Rx circuit 4320 can communicate with resonant Tx/Rx circuit 4324 at a first frequency f₁, and resonant Tx/Rx circuit 4322 can communicate with resonant Tx/Rx circuit 4326 at a second frequency f₂. Both circuits use the same FTSV 4302 to gain higher inductances and coupling coefficients. In at least one example, the inter-link-interference between two frequency channels can be minimized by selecting a suitable design for the resonating tanks or by using additional frequency selective circuits.

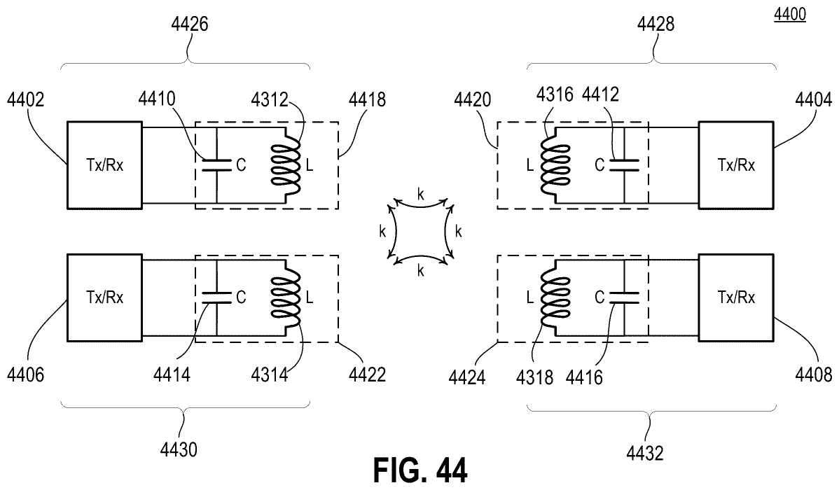

FIG. 44 is a schematic that illustrates a circuit 4400 for ferromagnetic transformer of FIG. 43, in accordance with at least one example. In at least one example, first circuit 4426 comprises a Tx/Rx circuit 4402, and a resonating tank 4418, wherein the resonating tank 4418 includes an on-chip capacitor C 4410 and an on-chip inductive coil L 4312. In at least one example, the second circuit 4428 comprises a Tx/Rx circuit 4404, and a resonating tank 4420, wherein the resonating tank 4420 includes an on-chip capacitor C 4412 and an on-chip inductive coil L 4316. In at least one example, two circuits may operate at a first resonance frequency f₁ to communicate data. Similarly, a third circuit 4430 comprises a Tx/Rx circuit 4406 and a resonating tank 4422, wherein resonating tank 4422 includes an on-chip capacitor C 4414 and an on-chip inductive coil L 4314. In at least one example, a fourth circuit 4432 comprises a Tx/Rx circuit 4408, and a resonating tank 4424, wherein resonating tank 4424 includes an on-chip capacitor C 4416 and an on-chip inductive coil L 4318. In at least one example, these two resonating tanks 4422 and 4424 communicate at a second resonant frequency f₂ for data communication.

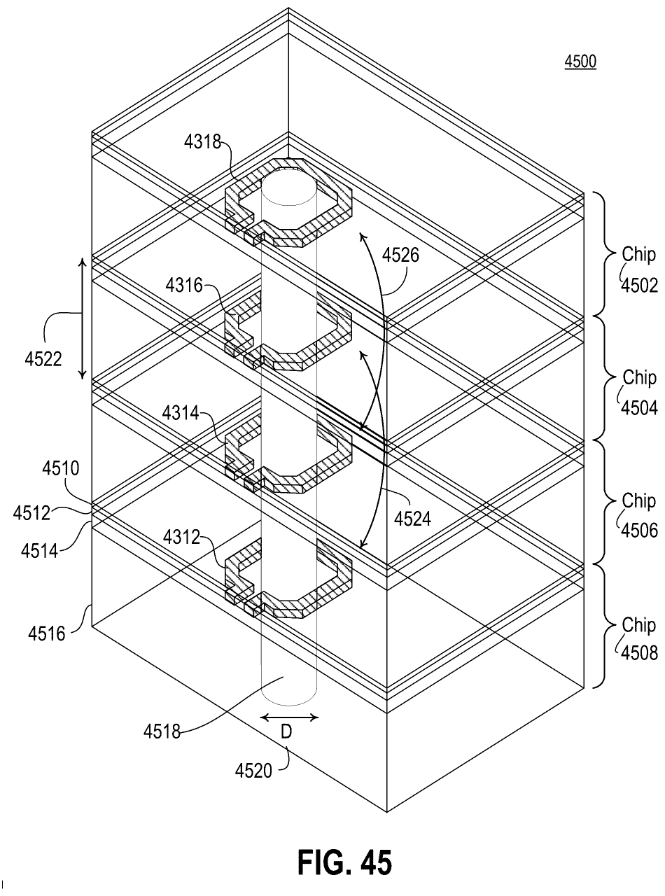

FIG. 45 illustrates a 3D integrated circuit 4500 comprising chips 4502, 4504, 4506, and 4508, in accordance with at least one example. Each chip can have different layers of materials. In at least one example, chip 4508 contains a passivation layer 4510, two dielectric layers 4512 and 4514, and an active silicon layer 4516. In at least one example, FTSV 4518 may pass through all four chips in 3D IC 4500 stack. In at least one example, inductive coils 4318, 4316, 4314, and 4312 on chips 4502, 4504, 4506, and 4508, respectively, can be placed around the ferromagnetic through silicon via 4518. FTSV 4518 has a diameter D 4520, and the distance between two consecutive chips is chip-to-chip distance 4522. In at least one example, diameter D 4520 of FTSV 4518 is 20 micrometers and chip-to-chip distance 4522 is 50 micrometers. However, this example is for explanation and illustration purposes, and may not be taken to be limiting as other configurations may also be possible.

In at least one example, FIG. 45 shows all inductive coils have a single turn and the same dimensions, but other configurations with different dimensions and number of turns are also possible. In at least one example, FTSV 4518 has two resonant links 4524 and 4526 e.g., a first resonant link 4524 operating at a first resonance frequency f₁, and a second resonant link 4526 operating at a second resonance frequency f₂. In at least one example, on-chip capacitors 4410, 4414, 4412 and 4416 are placed in a parallel configuration with their the respective inductive coils 4312, 4314, 4316, and 4318 to complete the resonating tank as shown in FIG. 44.

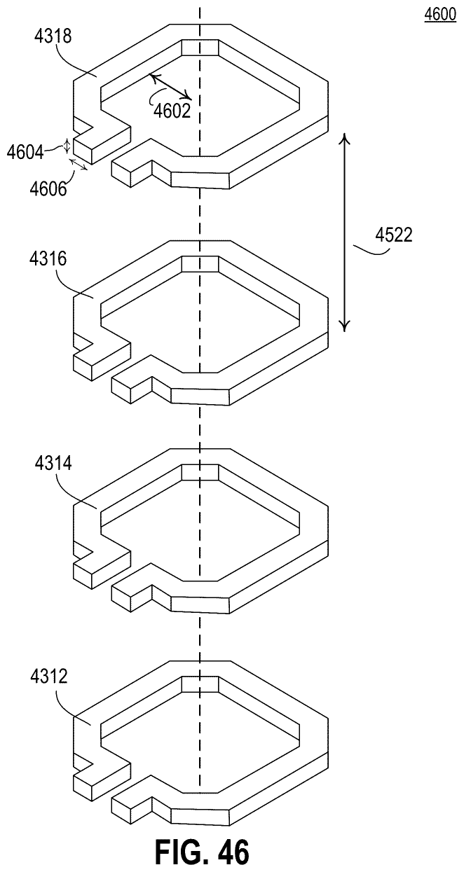

FIG. 46 is a schematic 4600 that illustrates inductive coils 4312, 4314, 4316 and 4318 to show their physical dimensions. For example, the inductive coil 4318 has an inner radius 4602, a coil width 4606, and a thickness 4604. In at least one example, other inductive coils 4312, 4314, and 4316 also have the same physical dimensions. These physical dimensions are inner radius 4602 of 15 micrometers, width 4606 of 5 micrometers, and thickness 4604 of 3.4 micrometers. In this example, the inductances of inductive coils 4312, 4314, 4316, and 4318 are 0.174 nanohenry, 0.1995 nanohenry, 0.1807 nanohenry, and 0.0887 nanohenry, respectively, assuming FTSV 4518 of FIG. 45 is passing through them.

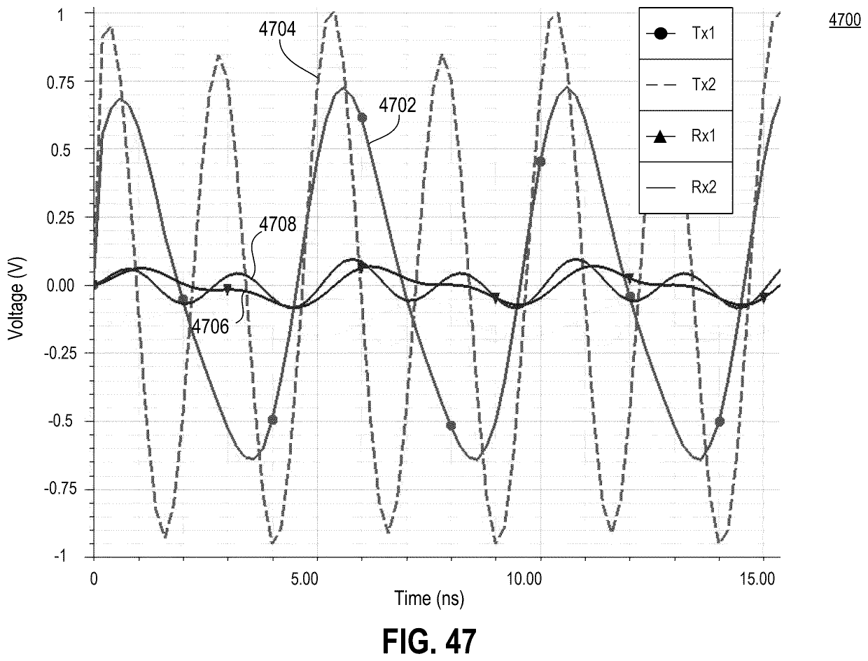

FIG. 47 is a plot 4700 that illustrates the transient results of circuit 4400 of FIG. 44 while using the inductive coils of FIG. 45. In at least one example, inductive coils 4312 and 4314 can be part of two transmitting circuits. Similarly, inductive coils 4316 and 4318 can be part of two receiving circuits. In this example, first resonance frequency f₁ for first resonant link 4524 is set at 200 megahertz, and second frequency f₂ for second resonant link 4526 is set at 400 megahertz. Consequently, the capacitance values for C4410 and C 4412 are 3.63 nanofarad and 3.5 nanofarad, respectively, for first resonant link 4524 resonating at the first resonance frequency f₁ of 200 MHz. Similarly, the capacitance values for C4414 and C 4416 are 793.5 picofarad and 1.78 nanofarad, respectively, for second resonant link 4526 resonating at the second resonance frequency f₂ of 200 MHz. This example is for illustration and may not be taken as limiting. Plot 4700 illustrates the poor linking between the inductive coils of resonant links 4524 and 4526. In plot 4700, the transmitted signals are shown as Tx1 4702 and Tx2 4704, and the received signals are shown as Rx1 4706 and Rx2 4708. Due to the coupling of the inductive coils, a single order resonating tank is not sufficient, as both received signals contains two frequency contents: f₁ and f₂. This issue can be resolved by using frequency selective components in the receiver circuits, such as higher order circuits, or inductive coils with different sizes, or band pass LNAs etc.

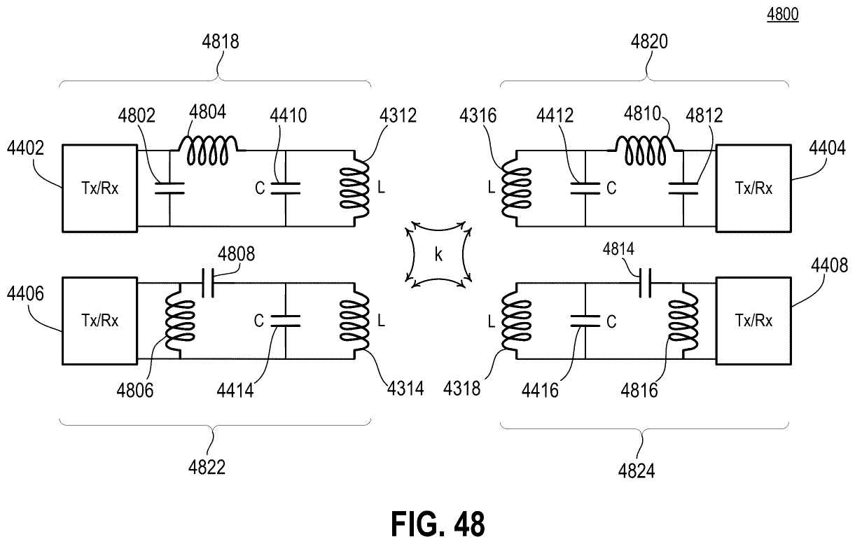

FIG. 48 is a schematic that illustrates a circuit 4800 that enhances the performance of circuit 4400 of FIG. 44, in accordance with at least one example. In at least one example, an additional inductive coil and a capacitor is added in each receiving and transmitting circuit to improve its frequency selectivity. In at least one example, a capacitor 4802 and an inductive coil 4804 are added in a first transmitter circuit 4818, and a capacitor 4812 and an inductive coil 4810 are added in a first receiving circuit 4820 to form high order filters. In at least one example, an inductive coil 4806 and a capacitor 4808 are added in second transmitter circuit 4822, and an inductive coil 4816 and a capacitor 4814 are added in second receiver circuit 4824 to form high order filters. The rest of the inductors, capacitors, and the Tx/Rx circuits are the same as shown in FIG. 44.

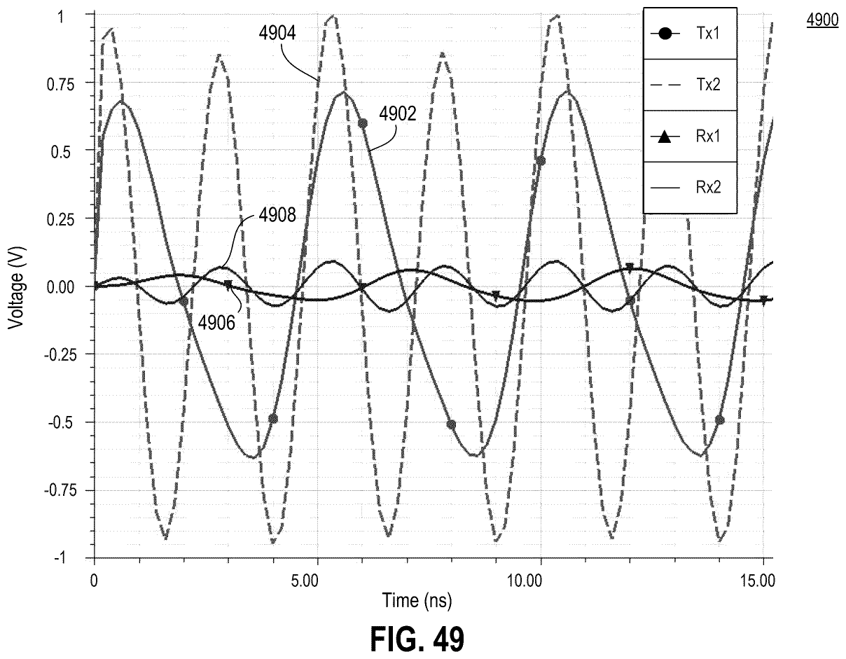

FIG. 49 is a plot 4900 that illustrates the improved transient waveforms of circuit 4800 of FIG. 48, in accordance with at least one example. In at least one example, transmitted signals Tx1 4902 and Tx2 4904 have frequencies 200 megahertz and 400 megahertz, respectively. In at least one example, signals Rx1 4906 and Rx2 4908 are received at frequencies 200 megahertz and 400 megahertz, and this shows that any interlink coupling is negligible.

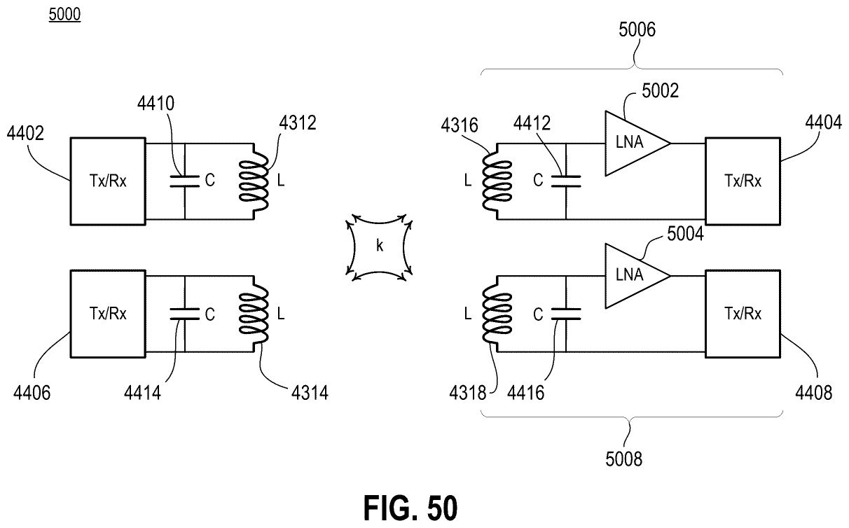

FIG. 50 is a schematic that illustrates another circuit 5000 that can further improve the performance of the circuit 4400 of FIG. 44, by adding two band pass low noise amplifiers (LNAs) 5002 and 5004 in receiving circuits 5006 and 5008, respectively, in accordance with at least one example. In at least one example, LNA 5002 in first receiving circuit 5006 can be tuned at the first resonance frequency f₁, of 200 megahertz, and the second LNA 5004 in the second receiving circuit 5008 can be tuned at the second resonance frequency f₂, of 400 megahertz. Other examples can also use the frequency selective filters, transmission line structures, or similar methods known to the ones skilled in the art.

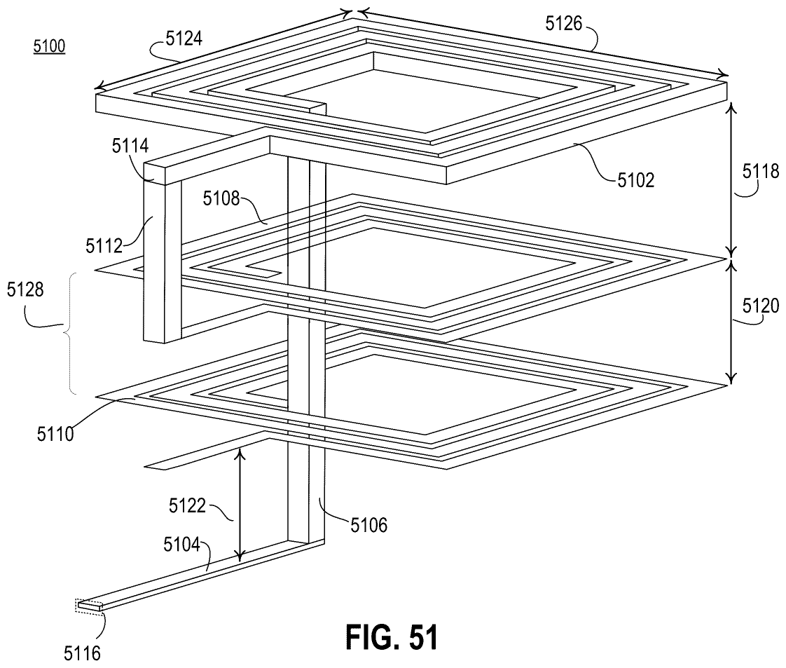

FIG. 51 is a schematic that illustrates an expanded view of an on-chip resonating tank 5100 including an inductive coil 5102 and a line 5104 connected through via 5106, in accordance with at least one example. In at least one example, inductive coil 5102 has two terminals 5114 and 5116, respectively. In at least one example, resonating tank 5100 includes a capacitor 5128 comprising a metal plate 5108 and a metal plate 5110, which are implemented underneath inductive coil 5102. In at least one example, plate 5108 of a capacitor 5128 is connected to first terminal 5114 of inductive coil 5102 through conductive via 5112, and plate 5110 is connected to terminal 5116 through via 5106 and line 5104. In at least one example, inductive coil 5102 and the capacitor 5128 are connected to form a parallel inductor-capacitor resonating tank 5100. In at least one example, the distances between inductive coil 5102 and metal plates 5108 and 5110 of capacitor 5128, and distance 5118 between inductive coil 5102 and capacitor plate 5108, and distance 5120 between capacitor plates 5108 and 5110 of capacitor 5128, and distance 5122 between the plate 5110 of capacitor 5128 and line 5104, can be determined by the manufacturing technology used to manufacture resonating tank 5100. The number of turns and the dimensions of inductive coil 5102 such as lengths 5124 and 5126, and the dimensions of capacitor 5128 are selected based on the value of the desired resonance frequency.

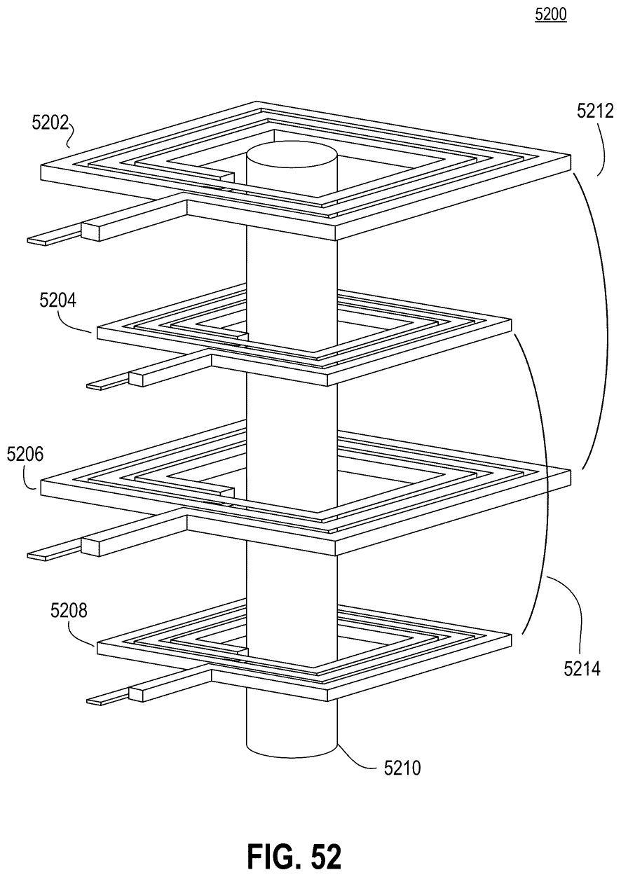

FIG. 52 is a schematic that shows a ferromagnetic transformer 5200 comprising ferromagnetic through the silicon via 5210 with two resonant links: 5212 and 5214, in accordance with at least one example. In at least one example, resonant link 5212, operating at a resonant frequency f₁, comprises resonating tanks 5202 and 5206. Similarly, the resonant link 5214, operating at a resonant frequency f₂, comprises resonating tanks 5204 and 5208. In at least one example, each of resonating tanks 5202, 5204, 5206, and 5208 can be implemented as resonating tank 5100 shown in FIG. 51. In at least one example, resonating tanks 5202 and 5206 have an inner radius of 20 micrometers, a width of 5 micrometers, a spacing of 2.5 micrometers, and 5 turns. In comparison, resonating tanks 5204 and 5208 can have the same dimensions for inner radius, width, and spacing as that of resonating tanks 5202 and 5206 with the exception of the number of turns that are 3. In at least one example, FTSV 5210 has a radius of 17 micrometers, the area occupied by resonating tanks 5202 and 5206 is 117.5×117.5 micrometers², and the area occupied by resonating tanks 5204 and 5208 is 87.5×87.5 micrometers².

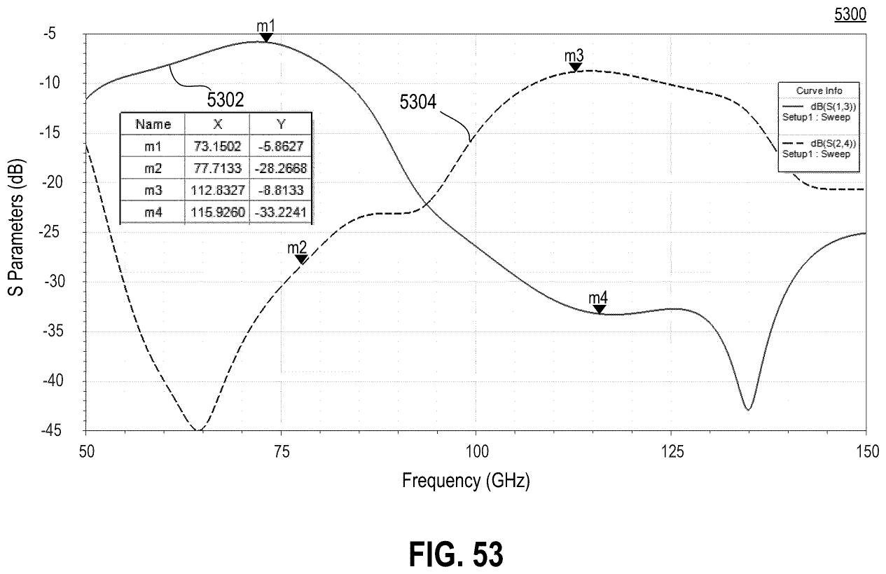

FIG. 53 is a plot 5300 that shows a high frequency S parameter result of resonant links 5212 and 5214 of ferromagnetic transformer 5200 of FIG. 52, in accordance with at least one example. Transmission coefficient S₁₃ 5302 represents the transmission response of resonant link 5212, e.g., from resonating tank 5202 to resonating tank 5206. Additionally, transmission coefficient S₂₄ 5304 represents the transmission response of resonant link 5214 from resonating tank 5204 to resonating tank 5208. With the dimensions indicated in ferromagnetic transformer 5200 of FIG. 52, resonant link 5212 operates at approximately 73 GHZ, and resonant link 5214 at 113 GHz. Moreover, the inter-link isolation is greater than 20 decibels in both cases, and this demonstrates that both resonant links are transmitting data efficiently.

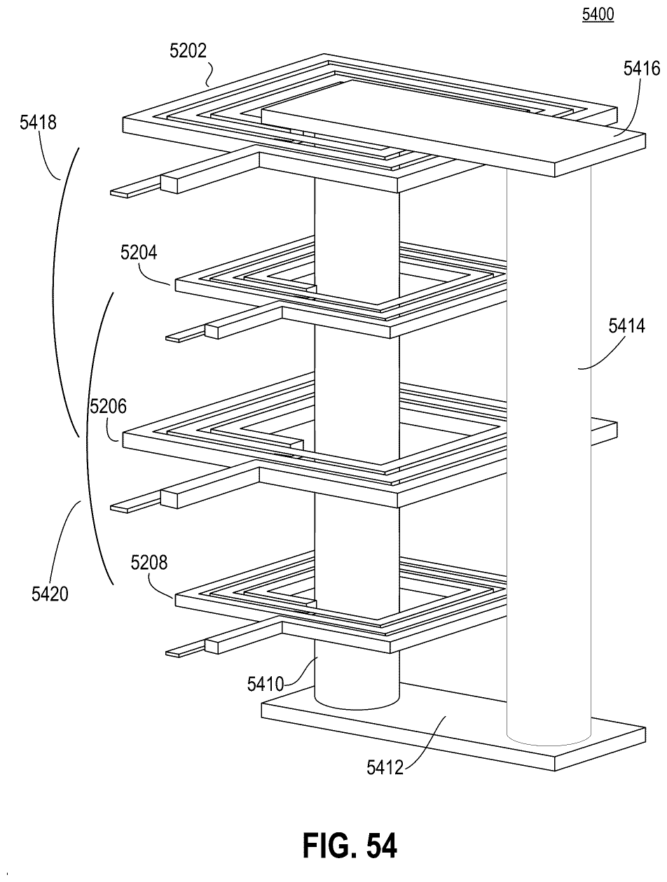

FIG. 54 is a schematic that illustrates an example structure of a ferromagnetic transformer 5400 including two ferromagnetic through silicon vias 5410 and 5414 connected at the bottom and top layers by two ferromagnetic lines 5412 and 5416, in accordance with at least one example. In at least one example, ferromagnetic lines 5412 and 5416 can be implemented as separate layers in a 3D IC stack by using known methods. In at least one example, ferromagnetic transformer 5400 of FIG. 54 improves the reluctance path for magnetic fields, which results in an efficient coupling. By using the inductive coils and capacitors of different dimensions, their resonant frequencies can be changed. As a result, two different resonant links operate at two different resonant frequencies. In at least one example, resonant link 5418 is formed between resonating tanks 5202 and 5206, and resonant link 5420 is formed between resonating tanks 5204 and 5208.

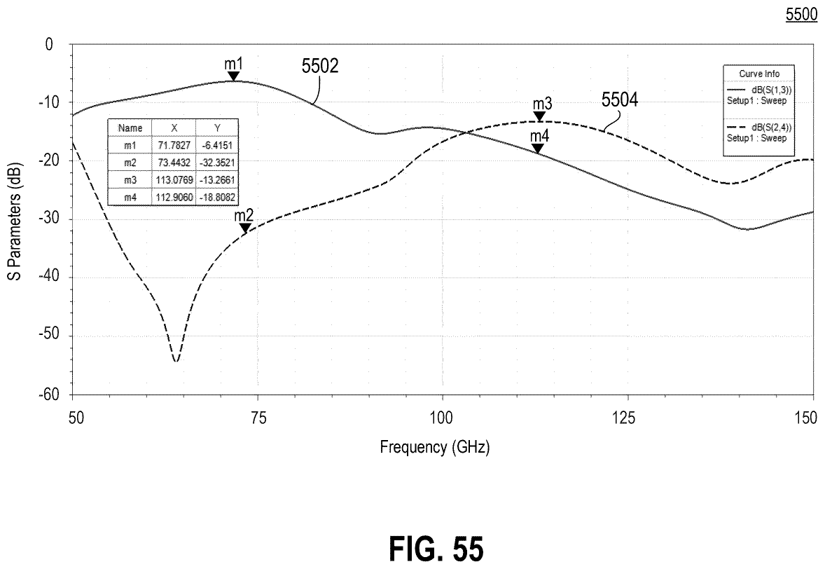

FIG. 55 is a plot 5500 that illustrates a high frequency S parameter result of the resonant links of ferromagnetic transformer 5400 of FIG. 54, in accordance with at least one example. Here, transmission coefficient S₁₃ 5502 represents the transmission response of the resonant link 5418 formed between resonating tank 5202 and resonating tank 5206. Similarly, transmission coefficient S₂₄ 5504 represents the transmission response of resonant link 5420 formed between resonating tank 5204 and resonating tank 5208. The inter-link isolation is greater than 20 decibels at low frequencies, and this demonstrates that both resonant links are transmitting data efficiently.

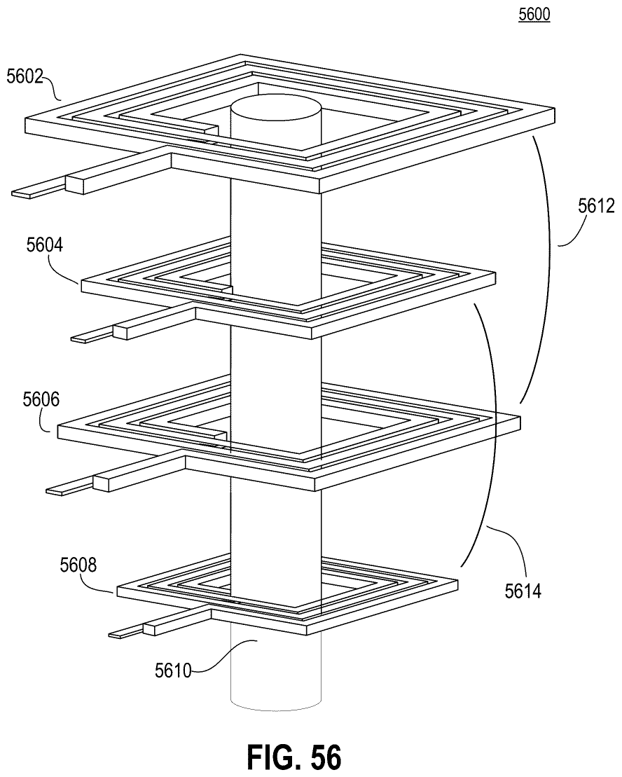

FIG. 56 is a schematic that illustrates an example structure of a ferromagnetic transformer 5600, in accordance with at least one example. In this example, the two resonating tanks of a resonating link can have different dimensions. For example, the inner radius of resonating tank 5602 is greater than resonating tank 5606 that form resonant link 5612 between them. Similarly, the inner radius of resonating tank 5604 is greater than resonating tank 5608 that form resonant link 5614 between them. In at least one example, resonating tank 5606 has a radius of 70 micrometers and resonating tank 5602 has radius of 80 micrometers, even though both tanks are configured to communicate using the same resonant link 5612. Similarly, resonating tank 5608 has a radius of 50 micrometers and resonating tank 5604 has a radius of 60 micrometers, even though both resonating tanks are configured to communicate using the same resonant link 5614. The dimensions of ferromagnetic through silicon via 5610 are the same as in the previous structures.

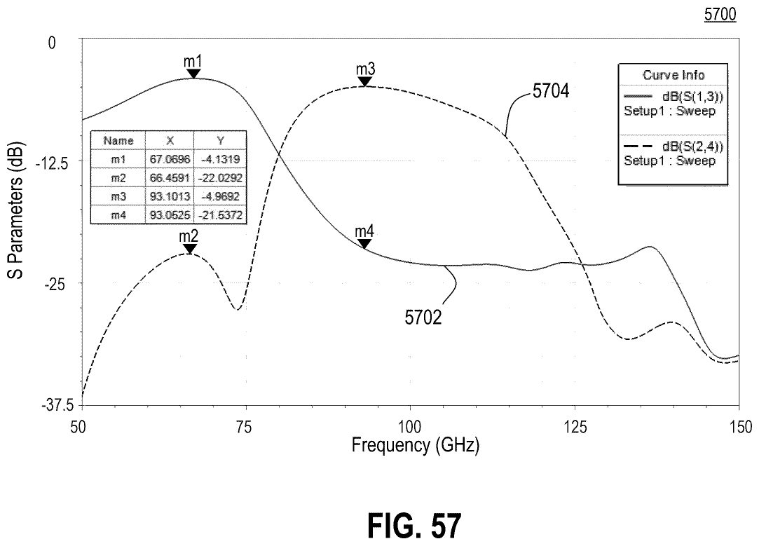

FIG. 57 is a plot 5700 that illustrates a high frequency S parameter result of resonant links of structure 5600 of FIG. 56, in accordance with at least one example. Here, transmission coefficient S₁₃ 5702 represents the transmission response of the resonant link 5614, from resonating tank 5604 to resonating tank 5608. Similarly, transmission coefficient S₂₄ 5704 represents the transmission response of resonant link 5612 from resonating tank 5602 to resonating tank 5606. In at least one example, resonant link 5612 operates at approximately 67 GHz, and resonant link 5614 at 93 GHz. The inter-link isolation is greater than 15 decibels in both cases, hence both links can communicate data efficiently.

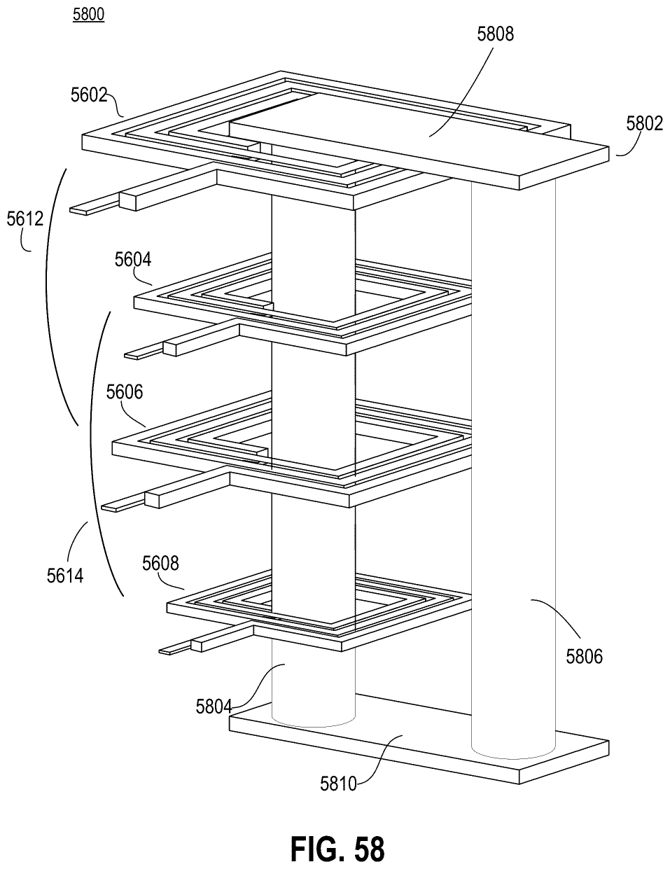

FIG. 58 is a schematic that illustrates an example structure of a ferromagnetic transformer 5800, wherein resonant links 5612 and 5614 of ferromagnetic transformer 5600 of FIG. 56 can be coupled using a vertical transformer core 5802. The vertical transformer core comprises two ferromagnetic through silicon vias 5804 and 5806, and both are connected using ferromagnetic lines 5808 and 5810, respectively. In at least one example, the dimensions of ferromagnetic through silicon vias 5804 and 5806 are the same as that of the dimensions of ferromagnetic through silicon via 5610 of FIG. 56.

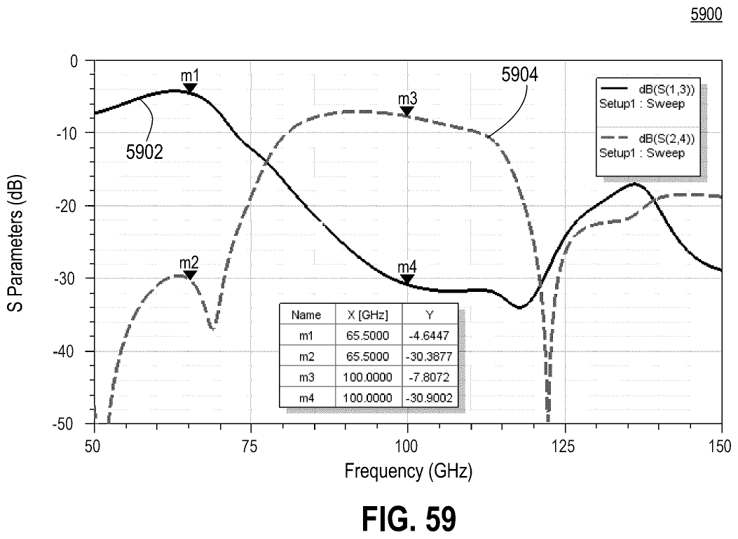

FIG. 59 is a plot 5900 that illustrates a high frequency S parameter result of resonant links 5612 and 5614 of the ferromagnetic transformer 5800 of FIG. 58, in accordance with at least one example. Here, transmission coefficient S₁₃ 5902 represents the transmission response of resonant link 5614 from resonating tank 5604 to resonating tank 5608. Similarly, transmission coefficient S₂₄ 5904 represents the transmission response of resonant link 5612 from resonating tank 5602 to resonating tank 5606. In at least one example, resonant link 5612 operates at approximately 65 GHz, and resonant link 5614 at 100 GHz. Plot 5900 shows that the inter-link isolation in ferromagnetic transformer 5800 is greater than 22 decibels at both frequencies i.e. 65 GHz and 100 GHz. In at least one example, ferromagnetic transformer 5800 of FIG. 58 may be a significant improvement from ferromagnetic transformers 5400 and 5600 of FIG. 54 and of FIG. 56, respectively. Consequently, it can transmit data reliably and efficiently on the resonant links compared with the previous structures.

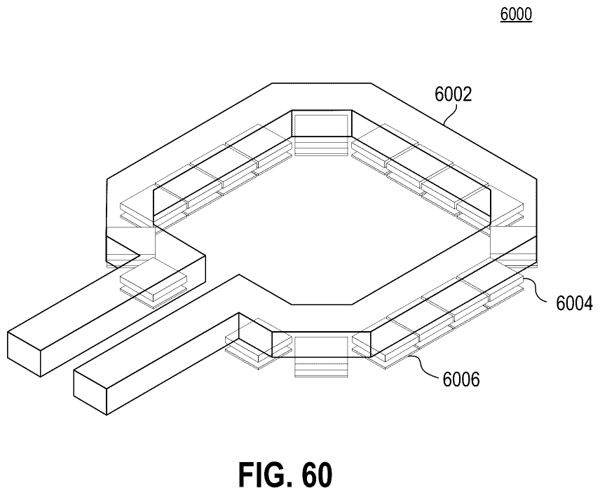

FIG. 60 is a schematic that illustrates an example structure 6000 of a resonating tank in which a capacitor is implemented using one or more smaller segments, in accordance with at least one example. In at least one example, inductive coil 6002 has a single continuous turn and capacitor's plates 6004 and 6006 are implemented using two or more smaller square plates. In at least one example, inductive coil 6002 and capacitor's plates can be implemented with multiple turns as well.

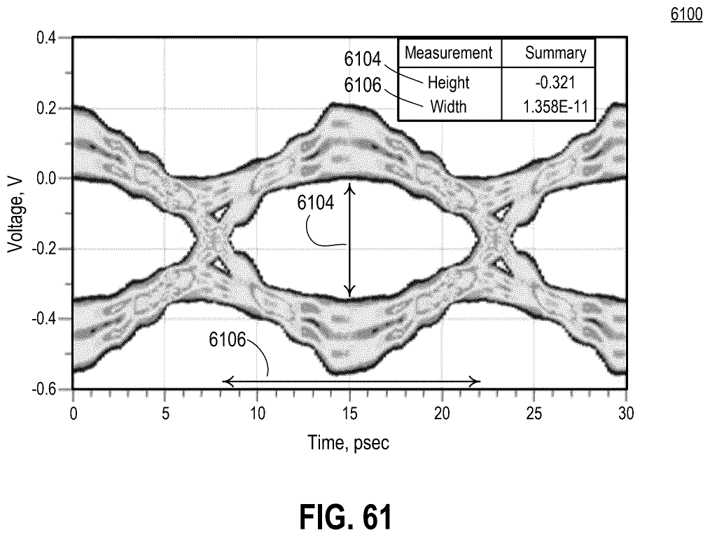

FIG. 61 is a plot that illustrates an eye diagram 6100 of second resonant link 5614 of ferromagnetic transformer 5800 of FIG. 58, in accordance with at least one example. The resonant link operates at 65.5 GHZ, wherein eye height 6104 is −0.321 volts and eye width 6106 is 1.358E-11 seconds, in accordance to with least one example. In at least one example, eye width 6106 and eye height 6104 of eye diagram 6100 signify the signal integrity and the margin for error in detecting the transmitted data.

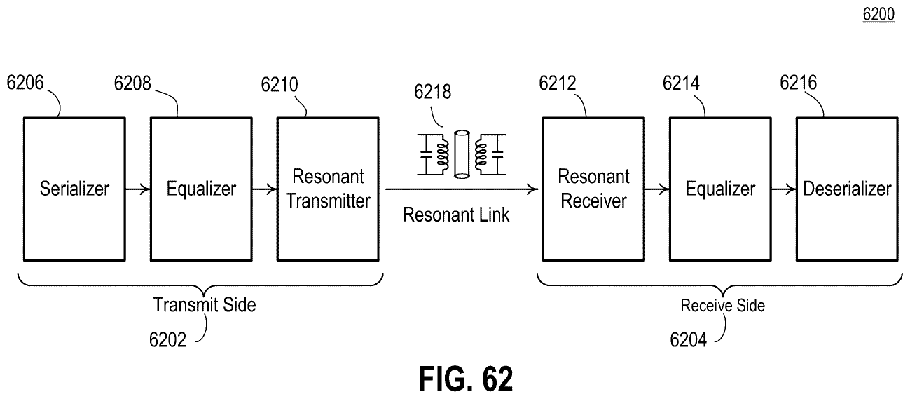

FIG. 62 is a schematic that illustrates a serializer-deserializer (SERDES) architecture 6200, in accordance with at least one example. In at least one example, transmitter side 6202 can include a serializer 6206, an equalizer 6208, and a resonant transmitter 6210; whereas the receive side 6204 can include a resonant receiver 6212, an equalizer 6214, and a de-serializer 6216, connected by resonant link 6218 of any of the examples of ferromagnetic transformers such as 5200, 5400, 5600, and 5800. On transmit side 6202, digital data is processed through a serializer 6206 to convert it into a serial data stream, which is then passed through equalizer 6208 to compensate for the channel impairments. The data is further transmitted through resonant transmitter 6210, where it is modulated using the quadrature amplitude modulation technique. On receive side 6204, resonant receiver 6212 captures the modulated signal from resonant link 6218. The received signal undergoes equalization by equalizer 6214 to mitigate any distortion introduced during the transmission. Subsequently, the equalized signal is passed through de-serializer 6216 to reconstruct the original digital data stream. Throughout the communication process, the resonant link facilitates efficient wireless energy transfer between the transmitter and receiver, ensuring reliable data transmission. In at least one example, equalizers 6208 and 6214 can be eliminated. In at least one example, resonant transmitter 6210 and resonant receiver 6212 can use one or modulation techniques, including but not limited to quadrature amplitude modulation. The selection of a modulation technique is done based on the requirements of an application.

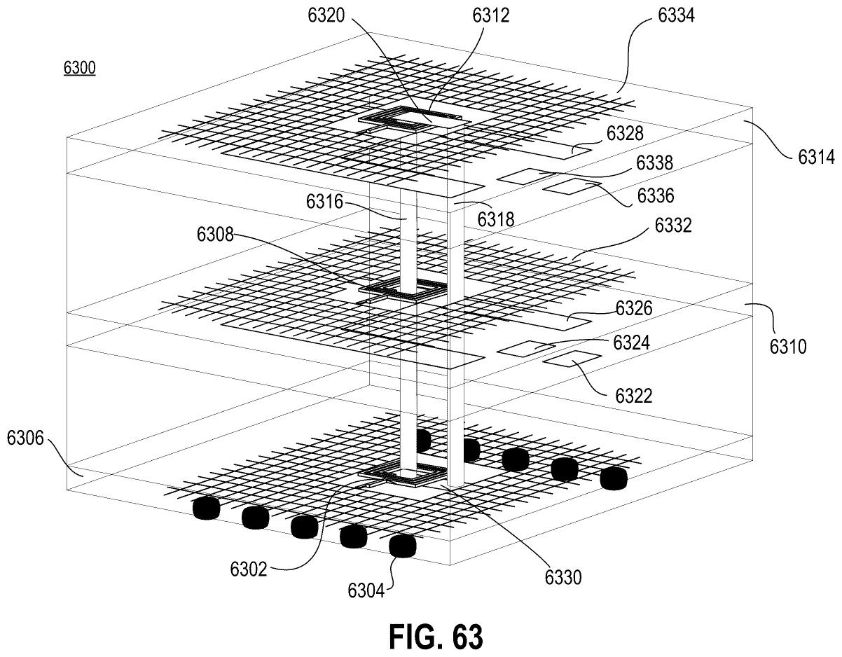

FIG. 63 is a schematic that illustrates a power distribution network 6300 of a 3D integrated circuit with a ferromagnetic power transformer, in accordance with at least one example. In at least one example, power distribution network 6300 comprises ball grid array (BGA) 6304, which provides an interface between a PCB and the 3D IC. The DC power from the PCB reaches a PMIC 6306 through BGA 6304. In at least one example, the DC power is converted to an AC power in PMIC 6306 and applied to inductive coil 6302 of PMIC 6306. This AC power is transferred to inductive coils 6308 and 6312 of chips 6310 and 6314 via inductive coupling, in accordance with at least one example. The FTSVs 6316 and 6318, along with ferromagnetic lines 6320 and 6330 form a transformer core that is configured to enhance the inductive coupling by concentrating the flux passing through inductive coils 6302, 6308 and 6312. Moreover, this arrangement increases the power transfer efficiency (PTE) by completing a flux path and decreasing the flux leakage, in accordance with at least one example. The AC power received at inductive coils 6308 and 6312 is rectified and regulated using the circuitry laid on the on-chip areas 6322 and 6324 of chip 6310 and on the on-chip areas 6336 and 6338 of chip 6314, respectively. In at least one example, the regulated DC power is transferred to on-chip circuits 6326 and 6328 using a mesh type PDNs 6332 and 6334 of chips 6310 and 6314. PDN 6300 is not drawn with the scale following a correct aspect ratio, BGA pad frame 6304 and horizontal dimensions of the chips can be relatively larger than the one illustrated in FIG. 63. Furthermore, chip 6306 is placed inverted in the flip chip way so that its pads can be easily connected to BGA 6304.

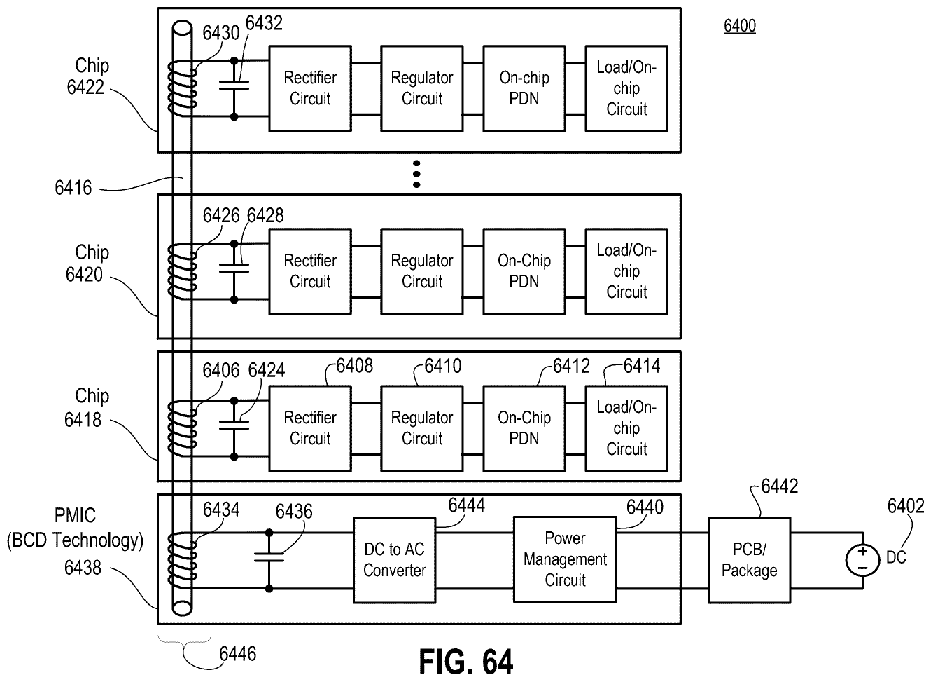

FIG. 64 is a schematic that illustrates the block diagram 6400 of a power distribution network for 3D ICs with a ferromagnetic power transformer 6446, in accordance with at least one example. In least one example, ferromagnetic core 6416 goes through a 3D IC of N chips. In at least one example, PMIC 6438, chip 6418, and chip 6420 up to chip 6422 are stacked on the top of each other and are connected by a single ferromagnetic core 6416, which can be a single FTSV of FIG. 52 or a double FTSV structure of FIG. 54. In at least one example, DC source 6402 is connected to PMIC 6438 using a PCB/package interface 6442. In at least one example, DC to AC converter 6444 converts the DC power to the AC using an oscillator, converter, or any other suitable module. In at least one example, the magnetic flux is generated when DC to AC converter 6444 supplies the AC power to inductive coil 6434 and capacitor 6436 of PMIC 6438. The magnetic flux induces voltage at inductors 6406, 6426, and 6430 of chip 6418, 6420, and 6422, respectively, as is stated by Faraday's law. Consequently, all vertically stacked chips from chip 6418 to chip 6422 are powered using an AC signal. In at least one example, power management circuit 6440 regulates the incoming DC power to match the power requirements of the vertically stacked ICs. In at least one example, PMIC 6438 has an on-chip resonating tank comprising inductive coil 6434 and capacitor 6432.

In at least one example, chip 6418 has an inductive coil 6406, a capacitor 6424, an on-chip rectifier block 6408, an on-chip regulator block 6410, and an on-chip power distribution network (PDN) 6412, and a load circuit 6414. These blocks are shown for chips 6420 and 6422 as well. In at least one example, inductive coil 6406 and capacitor 6424 form a resonating tank for wireless power transfer. In at least one example, on-chip rectifier block 6408 converts the alternating current from the resonating tank to the direct current suitable for powering up the chip. After doing rectification, on-chip regulator block 6410 regulates the voltage to ensure a stable and continuous power supply is provided internal circuits of to the chip. In at least one example, on-chip power distribution network (PDN) 6412 manages the distribution of power throughout the chip, optimizing power efficiency and minimizing power losses. Finally, load circuit 6414 utilizes the harvested energy to power the chip's functional blocks. In at least one example, inductive coils 6406, 6426, 6430, or 6434 on each chip are connected to the parallel capacitors to form a resonating tank. For instance, inductive coil 6434 is connected to the capacitor 6436, inductive coil 6406 is connected to capacitor 6424, inductive coil 6426 is connected to capacitor 6428, and inductive coil 6430 is connected to capacitor 6432. In at least one example, ferromagnetic power transformer 6446 is configured to transfer power wirelessly and as such it eliminates the heat generation problem, which is associated with conventional 3D ICs when the power is transmitted through conducting vias (TSVs).

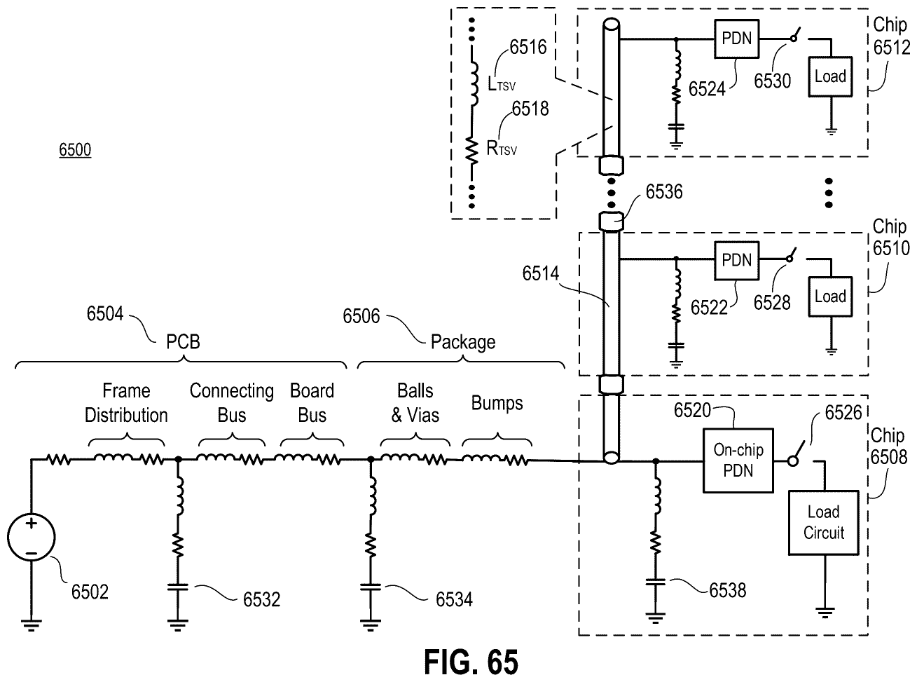

FIG. 65 is a schematic that illustrates a classical implementation of a power distribution network 6500 in a 3D IC, in accordance with at least one example. The DC power is supplied to the 3D IC from DC source 6502. As the current reaches PCB 6504, the power losses occur due to parasitic effects, such as the resistive and inductive losses, which are inherent in the PCB structure. These losses may stem from factors like frame distribution, board connecting buses, or other PCB components. Similarly, in package 6506, resistances and inductances are modeled from elements like balls from the ball grid, vias, bumps, or other circuit components. This power is supplied to chip 6508.

The power from chip 6508 reaches vertically stacked chips e.g., from chip 6510 up to chip 6512 through conducting via 6514 and bumps 6536, in accordance with at least one example. In at least one example, conducting via 6514 connects two vertically stacked chips 6510 and 6512, using bumps 6536. When the current passes through conducting via 6514, the power loss occurs because of inductance L_{TSV} 6516 and resistance R_{TSV} 6518 of conducting via 6514. In at least one example, each of the chips has its own on-chip PDN, such as PDN 6520 for chip 6508, PDN 6522 for chip 6510, and PDN 6524 for chip 6512. Moreover, the PDN circuits can also introduce resistive and inductive losses to the power when the load circuit draws the current from DC source 6502. The load can also be a switching circuit, and its switching behavior is modelled by switches, such as switch 6526 of chip 6508, switch 6528 of chip 6510, and switch 6530 of chip 6512. Moreover, the resistances along the current path also dissipate power, and inductances resist current changes during transients, leading to voltage peaks. To mitigate these effects, the decoupling capacitors are placed on each circuit level. For example, a decoupling capacitor 6532 is placed on PCB 6504, a decoupling capacitor 6534 is placed on package 6506, and a decoupling capacitor 6538 is placed on chip 6508.

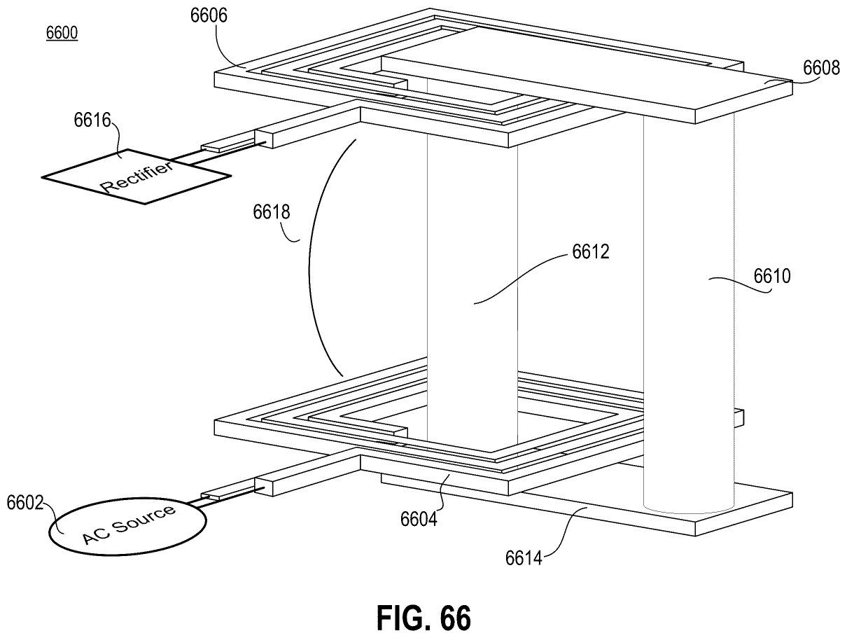

FIG. 66 is a schematic that illustrates a ferromagnetic power transformer (FMPT) 6600 that comprises ferromagnetic through silicon vias 6610 and 6612 connected by ferromagnetic lines 6608 and 6614, in accordance with at least one example. In at least one example, FTSV 6612 passes through the center of two inductors 6604 and 6606, which form inductive link 6618. In at least one example, AC source 6602 is connected to the inductive coil 6604, whereas inductive coil 6606 is connected to an on-chip rectifier 6616. In at least one example, the AC power induces the magnetic flux in inductive coil 6604. This magnetic flux can be channeled to inductive coil 6606 through the ferromagnetic core of the ferromagnetic through silicon vias 6610 and 6612, which are connected by ferromagnetic lines 6608 and 6614, and can induce the voltage in inductive coil 6606. In at least one example, inductive coils 6604 and 6606 may be connected to capacitors to form a resonating tank. Due to the resonance phenomenon, the power is transferred at a specific frequency, which enhances the frequency selectivity and the power transfer efficiency (PTE). In at least one example, on-chip rectifier 6616 converts the AC power to the DC which powers for one or more on-chip circuitries.

In at least one example, inductive coils 6604 and 6606 of FIG. 66 are of the same size. But the inductive coils with different turns and sizes can also be used to step up or step down the received voltage depending on the manufacturing process technology of the chips in the 3D IC and/or their intended application. Furthermore, FIG. 66 merely shows the inductive coils 6604 and 6606, and merely one AC source 6602 and one rectifier 6616. In a 3D IC with multiple chips, the number of inductive coils and rectifiers can increase with the increasing number of chips in the 3D IC.

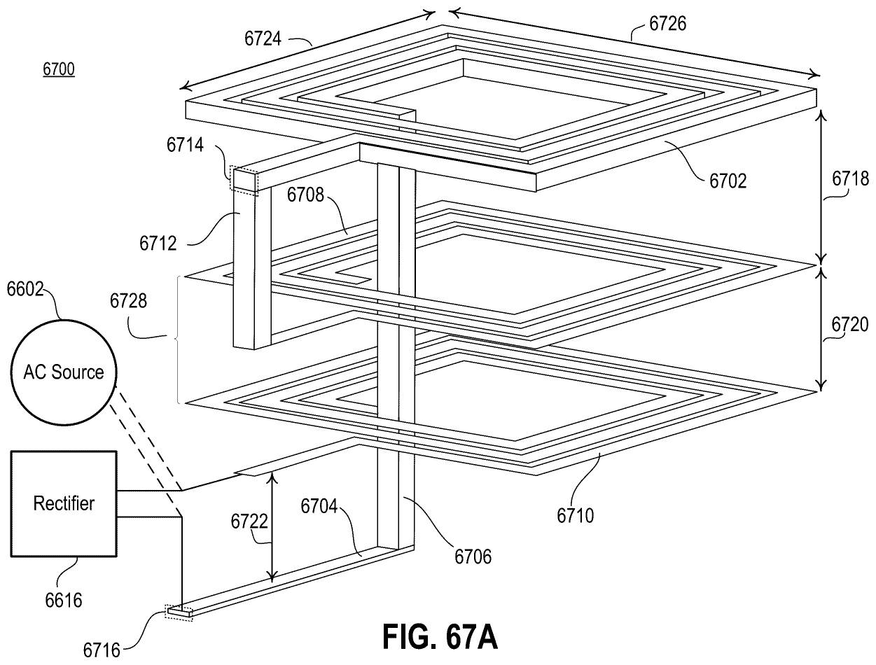

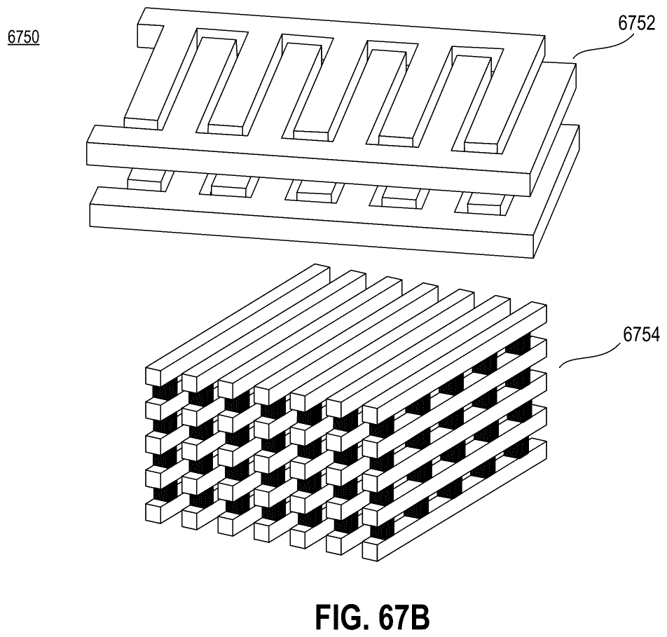

FIG. 67A is a schematic that illustrates an expanded view of an on-chip resonating tank 6700 including an inductive coil 6702 implemented with a line 6704, connecting one end of inductive coil 6702 through a conducting via 6706, in accordance with at least one example. In at least one example, inductive coil 6702 has two terminals; terminal 6714 and 6716. In at least one example, resonating tank 6700 also includes a capacitor 6728 comprising metal plates 6708 and 6710, which are fabricated underneath inductive coil 6702. In at least one example, capacitor's plate 6708 is connected, using conducting via 6712, to terminal 6714 of inductive coil 6702, and metal plate 6710 is connected to terminal 6716 through via 6706. In at least one example, inductive coil 6702 and capacitor 6728 are connected to form a parallel inductor-capacitor resonating tank 6700. The resonating tank may be connected to an AC source 6602 or a rectifier 6616 as shown in FIG. 66. In at least one example, distance 6718 between an inductive coil 6702 and a capacitor plate 6708, and distance 6720 between capacitor plates 6708 and 6710, and distance 6722 between capacitor plate 6710 and inductive coil's line 6704 depend on the manufacturing process technology used. In at least one example, lengths 6724 and 6726, and dimensions of capacitor 6728, and the dimensions of inductive coil 6702 such as the number of turns of inductive coil 6702 or capacitor 6728, and thicknesses of inductive coil 6702 or capacitor 6728 can be determined once the value of the desired resonant frequency gets known.

FIG. 67B is a schematic 6750 that illustrates different types of capacitors that can be used for resonating tank 6700, in accordance with at least one example. In at least one example, on-chip capacitor 6728 for resonating tank 6700 can be a metal-oxide-metal (MOM) capacitor 6752 having interdigitated parallel wires, or a MOM capacitor comprising parallel stacked wires 6754. In at least one example, capacitor 6728 may also be implemented as a metal-insulator-metal (MIM) capacitor or any other technology suitable for the application, and is known well to the ones skilled in the art.

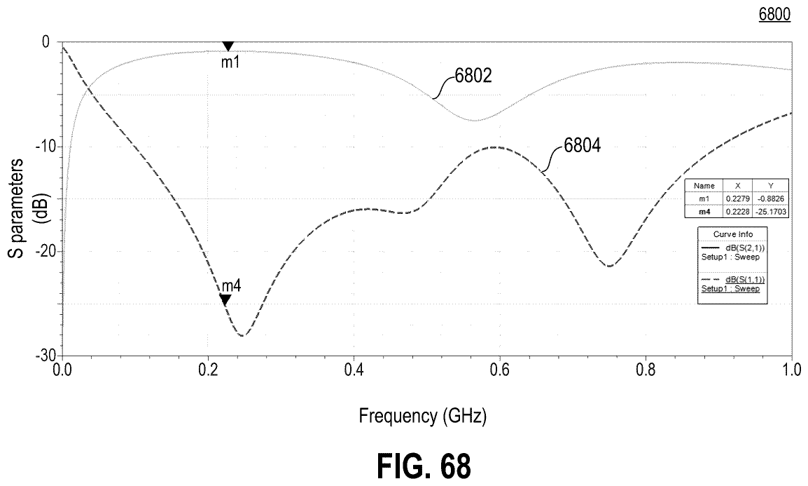

FIG. 68 is a plot 6800 that illustrates S-parameters result of a resonant link 6618, in accordance with at least one example. Here, transmission coefficient S₂₁ 6802 represents the transmission response of resonant link 6618 from inductive coil 6604 to inductive coil 6606. Similarly, reflection coefficient S₁₁ 6804 shows the reflections (of what) as seen at source 6602. Plot 6800 illustrates that the reflections at source 6602 are approximately-28 decibels and transmission to inductive coil 6606 is greater than-1 decibels. These results indicate that inductive coils 6604 and 6606 of resonant link 6618 transmit and receive power efficiently.

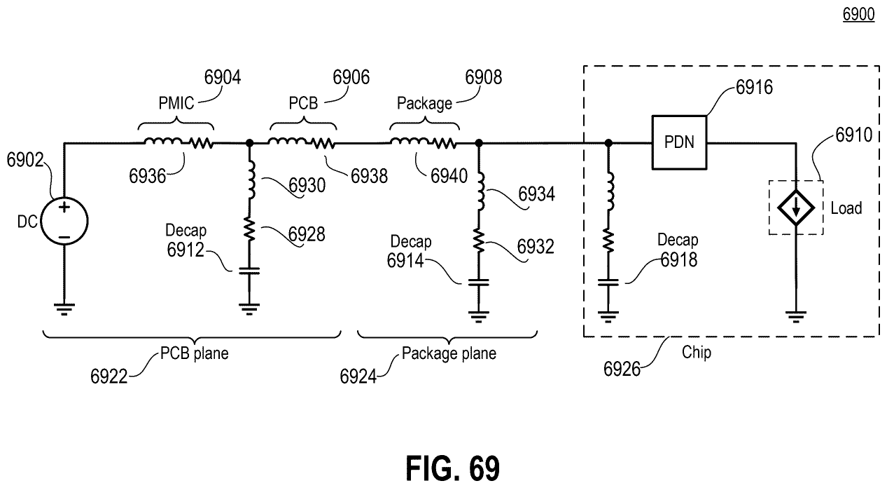

FIG. 69 is a schematic that illustrates a test bench circuit 6900 of the power distribution network 6500 of FIG. 65, in accordance with at least one example. The resistive and inductive losses because of the current flowing through components such as PCB 6922, package 6924, and chip 6926 can be computed by treating load as a series combination of resistance and inductance. In at least one example, the DC power from DC source 6902 is regulated by a PMIC 6904, wherein the parasitic losses of PMIC 6904 are modeled as a resistor-inductor 6936. The parasitic losses of PCB 6906 are modeled as a resistor-inductor 6938. Similarly, the parasitic losses of package 6908 are modeled as resistor-inductor 6940. The power of chip 6926 is managed by an on-chip power distribution network (PDN) 6916 which provides the on-chip load 6910. Load 6910 is modeled as a current source with a specified switching frequency, representing the switching of on-chip circuits like processors or memory, well known to the ones skilled in the art. To mitigate the parasitic losses of PMIC 6904, PCB 6906, package 6908, and PDN 6916, decoupling capacitors namely decaps 6912, 6914, and 6918 are placed at PCB plane 6922, package plane 6924, and chip 6926, respectively. In at least one example, each decoupling capacitor has an equivalent inductance and resistance. For instance, decap 6912 has a resistance 6928 and an inductance 6930 and decap 6914 has a resistance 6932 and an inductance 6934. This inductance and resistance are shown for decap 6918 as well. In at least one example, the parasitic losses due to PMIC 6904 are modeled as an inductance of 0.45 nanohenry and a resistance of 0.198 milliohms, respectively. The parasitic losses of PCB 6906 are modeled as inductance of 0.05 nanohenry and resistance of 10 mohms. The inductance of 0.48 nanohenry and resistance of 0.2 mohm model the parasitic losses by package 6908. Moreover, decap 6912 has a capacitance of 17.3 μF with an equivalent series resistance 6928 of 1 mohm and an equivalent series inductance 6930 of 1.66 picohenry. Similarly, decap 6914 has a capacitance of 185 nanofarad with an equivalent series resistance 6932 of 27 mohm and an equivalent series inductance 6934 of 200 picohenry.

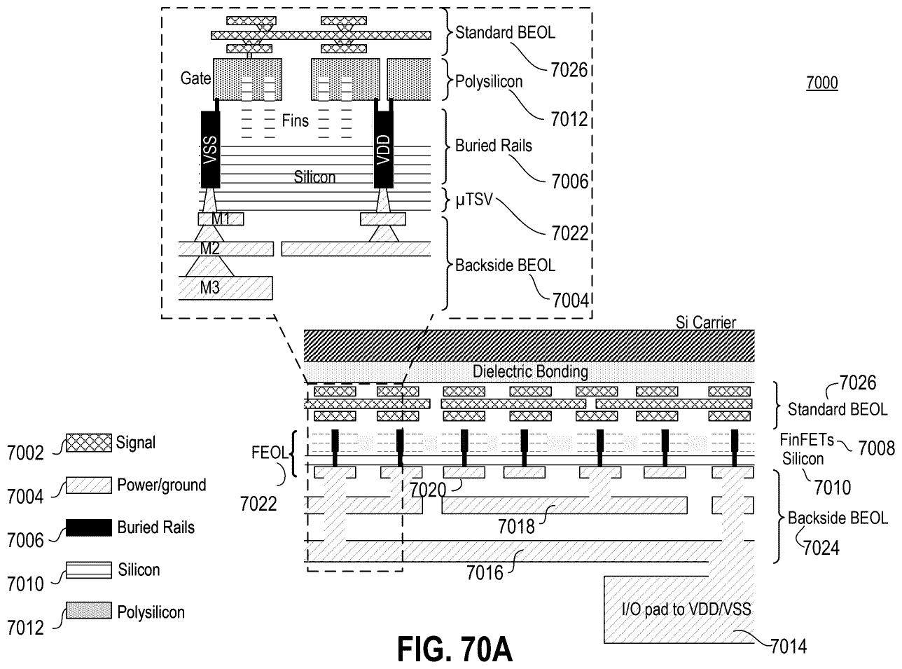

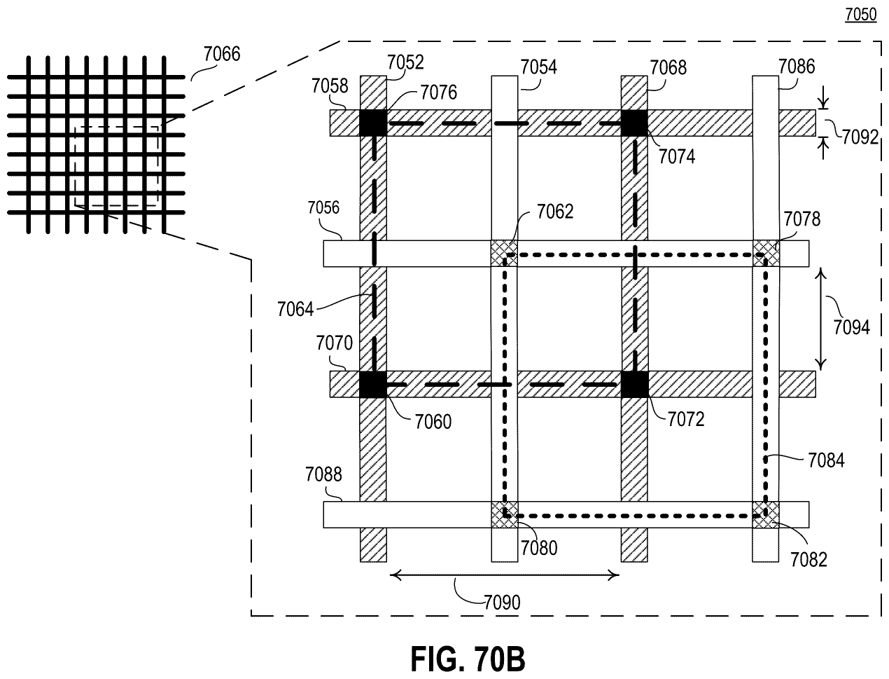

FIG. 70A is a schematic that illustrates a layout 7000 of on-chip PDN 6916 based on a backside power delivery method that utilizes the detailed die segmentation. The first metallization of signal layer 7002, referred to as standard back-end-of-the-line (BEOL) 7026, is positioned on the front side of the die, establishing a direct connection to front-end-of-the-line (FEOL) 7022. Standard BEOL 7026 network primarily serves a signaling network. In some examples, BEOL 7024 is implemented on the die specifically dedicated to the power distribution networks. Additionally, the configuration incorporates a buried power rail (BPR) network 7006, which is configured to supply power to active circuits. The active circuits, such as transistors like FinFETs 7008, are fabricated using materials like silicon 7010 and polysilicon 7012. In at least one example, BEOL 7024 connects I/O pad 7014 to BPR 7006 through conducting vias passing through metal layers 7016, 7018, and 7020. In at least one example, BPR 7006 may also connect to a backside power distribution network (PDN) using micro through silicon vias (uTSVs) 7022. This layout and configuration facilitates efficient power distribution and signal routing within a chip improving performance and functionality of the integrated circuits. Nevertheless, the conducting vias in BEOL 7004 or uTSVs 7022 introduce resistance in PDN 6916, and this resistance is responsible for power losses and heat generation.

FIG. 70B is a schematic that illustrates a layout 7050 of on-chip PDN 6916 of FIG. 69, in accordance with at least one example. Layout 7050 comprises the power and ground lines such as horizontal power lines 7058 and 7070, horizontal ground lines 7056 and 7088, vertical power lines 7052 and 7068, and vertical ground lines 7054 and 7086, in accordance with at least one example. The overlapping area of the power and ground wires are connected by conducting vias namely power via 7060 and ground via 7062, respectively. In one example, a power line unit cell 7064 is formed by connecting two vertical power lines 7052 and 7068 with two horizontal power lines 7058 and 7070 using the power vias 7060, 7072, 7074, and 7076. Similarly, a ground line unit cell 7084 is formed by connecting the two vertical ground lines 7054 and 7086 with the two horizontal ground lines 7056 and 7088, using the ground vias 7062, 7078, 7080, and 7082. This creates a meshed type power distribution network 7066 comprised of multiple power line unit cells such as a unit cell 7064, and the ground line unit cells such as unit cell 7084. This configuration can be repeated both horizontally and vertically. The power rails have a thickness of 1 micrometer and a width 7092 of 2 micrometers, with a separation 7090 of 8 micrometers between the contiguous power lines. The ground lines are placed similarly with a separation of 4 micrometers between the contiguous power and ground lines.

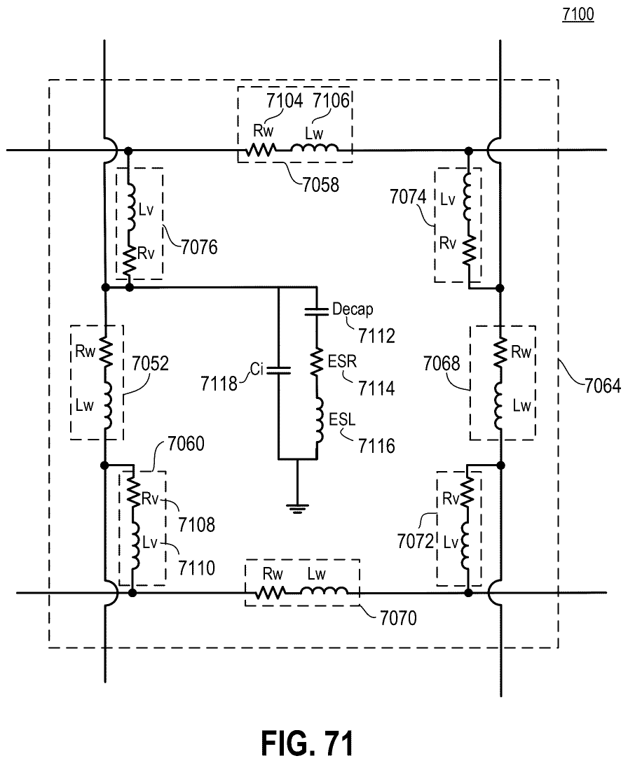

FIG. 71 is a schematic that illustrates an equivalent circuit 7100 of the power line unit cell 7064 of FIG. 70B, in accordance with at least one example. The series connection of resistor R_{W} 7104 and inductor L_{W} 7106 can represent one or more power lines such as 7052, 7058, 7068, or 7070 of FIG. 70B. Similarly, the series connection of resistor R_{V} 7108 and inductor L_{V} 7110 can represent one or more power vias such as the power vias 7060, 7072, 7074, or 7076, in accordance with at least one example. Consequently, unit cell 7064 is formed by connecting two horizontal power lines 7058 and 7070 and two vertical power lines 7052 and 7064 are connected using four power vias: 7060, 7076, 7072, 7074, wherein the resistor-inductor pair R_{W} 7104 and L_{W} 7106 represents the power line 7058 and resistor-inductor pair such as R_{V} 7108 and L_{V} 7110 represents power via 7060. In at least one example, the on-chip decoupling capacitor is distributed for each unit cell as decap 7112, having equivalent series resistance (ESR) 7114, and equivalent series inductance (ESL) 7116. Moreover, Ci 7118 represents the intrinsic capacitance of a node of a unit cell. In at least one example, R_{W} 7104 is 72.23 milliohms, L_{W} 7106 is 3.31 picohenry, R_{V} 7108 is 17.56 milliohms and L_{V} 7110 is 0.16 picohenry and Ci 7118 is 10 femtofarad, decap 7112 is 640 femtofarad, ESR 7114 is 0.1 milliohms and ESL 7116 is 0.2 picohenry.

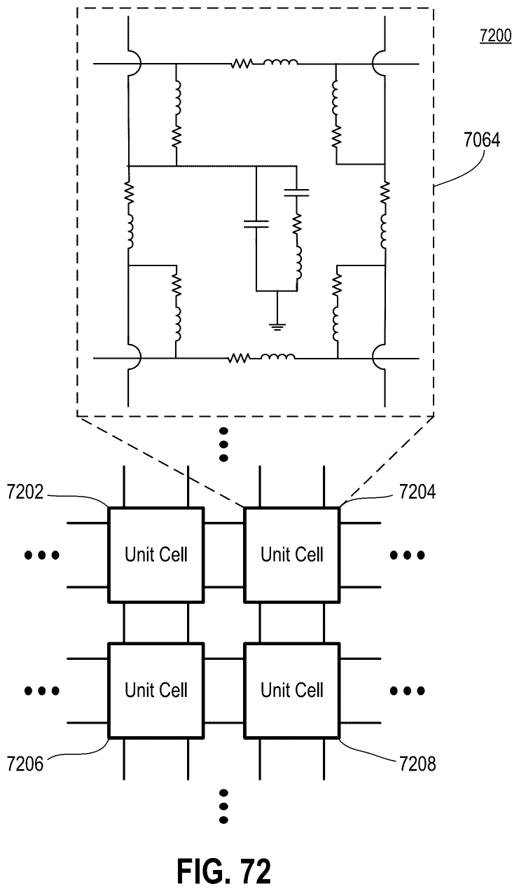

FIG. 72 is a schematic that illustrates a circuit 7200 of an on-chip power grid layout 7050 of FIG. 70B, wherein each unit cell in a set of unit cells 7202, 7204, 7206, or 7208 is modeled using the same method in which we modeled an equivalent circuit 7100 for unit cell 7064, in accordance with at least one example. A 2×2 PDN grid is formed by connecting four unit cells 7202, 7204, 7206, and 7208. A complete power grid of N×N unit cells can be formed in which every unit cell of the N×N unit cells grid of FIG. 70B is modelled as an equivalent circuit the way unit cell 7064 is modelled by the equivalent circuit.

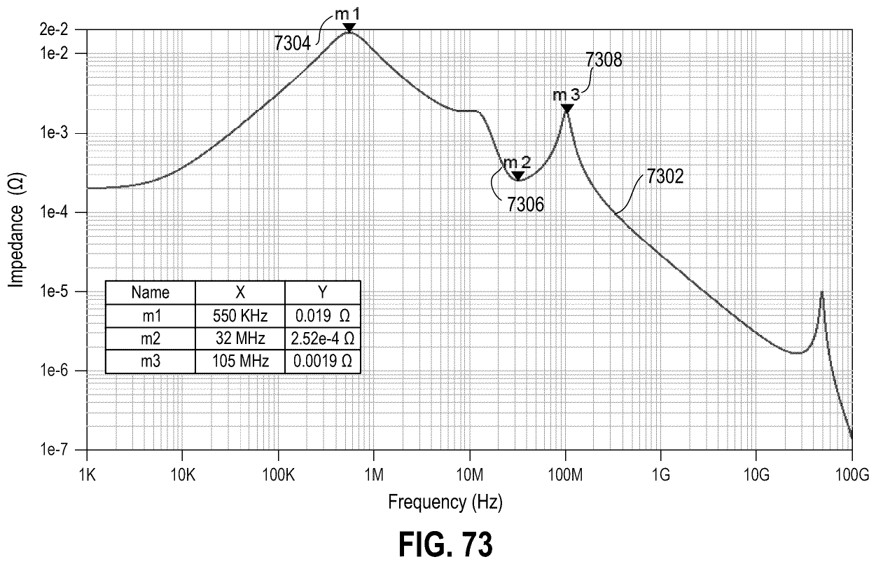

FIG. 73 is a plot 7300 that illustrates an impedance profile 7302 reflected at source 6902 of conventional PDN circuit 6900 of FIG. 69, in accordance with at least one example. Due to decoupling capacitors 6912, 6914, and 6918, a number of resonant peaks such as peaks 7304 and 7308 appear in impedance profile 7302 of PDN 6900. In the frequency region smaller than 550 KHz indicated by marker m1 7304, the inductive behavior due to PCB parasitic resistor-inductor 6938 dominates and the impedance reaches 0.019 ohms at 550 KHz, in accordance with at least one example. After 550 KHz, the capacitive behavior dominates with an impedance of 0.252 milliohms at 32 megahertz as indicated by marker m2 7306. After 32 megahertz, impedance profile 7302 rises due to the package inductances and reaches a local maxima of 0.002 ohms at 105 megahertz indicated by the marker m3 7308, in accordance with at least one example. Plot 7300 demonstrates the inefficient power distribution of a prior art PDN 6900 because a significant amount of impedance is reflected at source 6902 due to impedance mismatches.

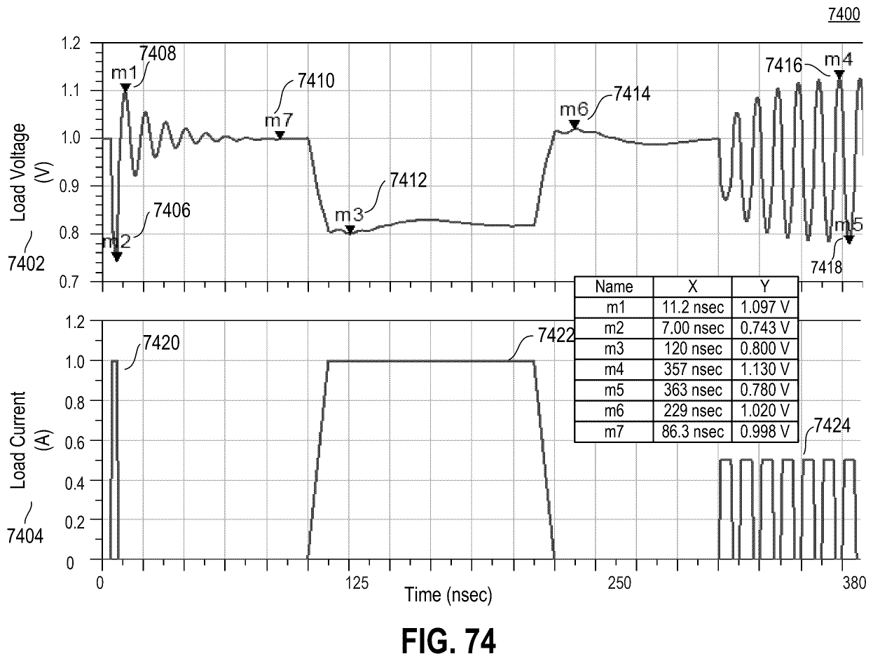

FIG. 74 is a plot 7400 that illustrates a transient voltage 7402 and a current 7404 of the circuit 6900 of FIG. 69, in accordance with at least one example. Plot 7400 shows that the voltage 7402, during switching of load 6910, results in a transient current 7404. Despite the fact that load voltage 7402 is desired to be kept constant at 1 volt, the variations in load voltage 7402 still occur, when load current 7404 experiences transient oscillations due to the mismatch of impedance profile 7302 of a conventional power distribution network 6900. The different phases of the load circuit are represented by impulse current 7420, step current 7422, and resonance current 7424. In at least one example, a voltage variation with a negative peak of −0.097 volts and a drop of 0.26 volts is observed when the impulse current 7420 is drawn, and is indicated by markers m1 7408 and m2 7406, respectively. The voltage fluctuations reach a steady state after a settling time of 75 nanoseconds indicated by marker m7 7410. The voltage variation is also observed at marker points m3 7412 and m6 7414 when a step current 7422 of 1 Ampere is drawn by the load 6910 for 100 nanoseconds. Other variations in voltage waveform 7402 are indicated by markers m4 7416 and m5 7418 and occur when resonance current 7424 of 0.5 amperes is drawn by load 6910 at 100 megahertz, in accordance with at least one example. The continuous fluctuations in load voltage 7402 during load 6910 switching can lead to an unstable PDN, thereby reducing its power distribution efficiency, which substantially impacts the performance and reliability of 3D IC, as the load voltage fluctuations can damage sensitive components, which can result in malfunctioning of the on-chip circuitry.

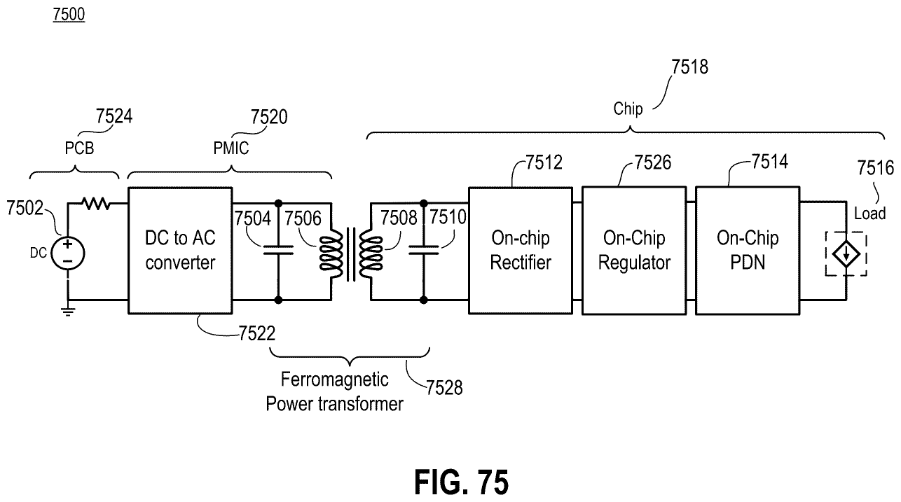

FIG. 75 is a schematic that illustrates a circuit 7500 of the ferromagnetic power transformer based PDN architecture, in accordance with at least one example. DC power 7502 from PCB 7524 is converted to the AC power at PMIC 7520 using the DC to AC converter 7522. This AC power is supplied to capacitor 7504 and inductive coil 7506 of PMIC 7520, which form a resonating tank configured to transfer the AC power wirelessly to chip 7518, in accordance with at least one example. The power is received by inductive coil 7508 and capacitor 7510, forming a resonating tank of chip 7518. In at least one example, on-chip rectifier 7512 rectifies the transferred AC power. On-chip regulator 7526 regulates the rectified signal. Load 7516 is modeled as a current source to represent the current drawn by a memory or processor. Load 7516 is powered by on-chip PDN 7514. Inductor 7506 can represent the inductive coil 6604, and inductor 7508 can represent inductive coil 6606 of ferromagnetic power transformer 6600 of FIG. 66. Ferromagnetic power transformer 6600 is configured to enhance the power transfer efficiency of the power distribution network of a 3D IC by reducing the parasitic losses, and avoiding the heat generation because of the interconnect resistivity of the vias.

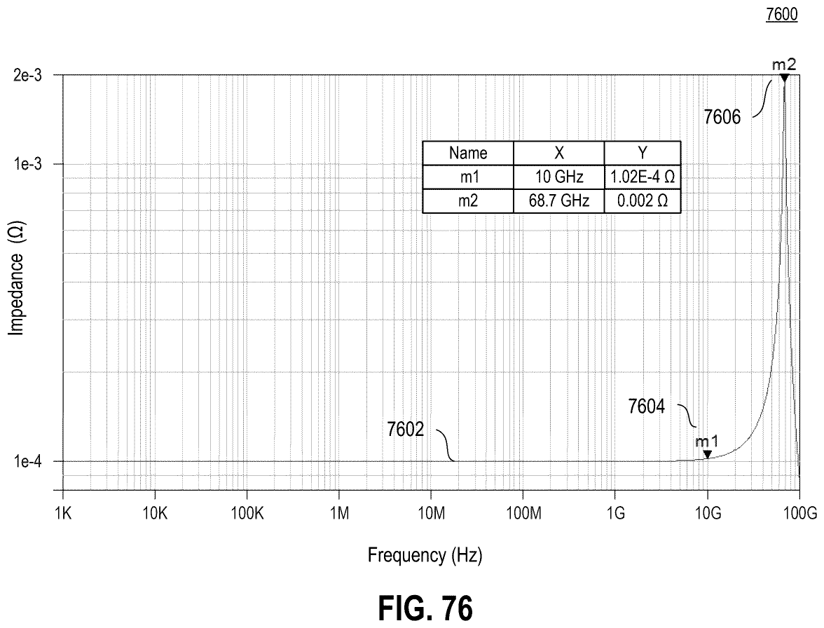

FIG. 76 is a plot 7600 that illustrates an impedance profile 7602 reflected at source 7502 of circuit 7500 of FIG. 75, in accordance with at least one example. The AC power is transferred to chip 7518 instead of the DC power, which results in a smooth impedance profile 7602 of 1.02e-4 ohms up to 10 GHz, as illustrated by marker m1 7604, in accordance with at least one example. After 10 GHZ, the inductive behavior of the on-chip circuit introduces a peak of 0.002 ohms at 68.7 GHz as shown by marker m2 7606. Plot 7600 represents the power transfer efficiency of power distribution network circuit 7500 based on ferromagnetic power transformer 6600. Impedance profile 7602 is generally constant at 0.102 milliohms with a peak of only 0.002 ohms which illustrates a significant improvement from impedance profile 7302 of FIG. 73.

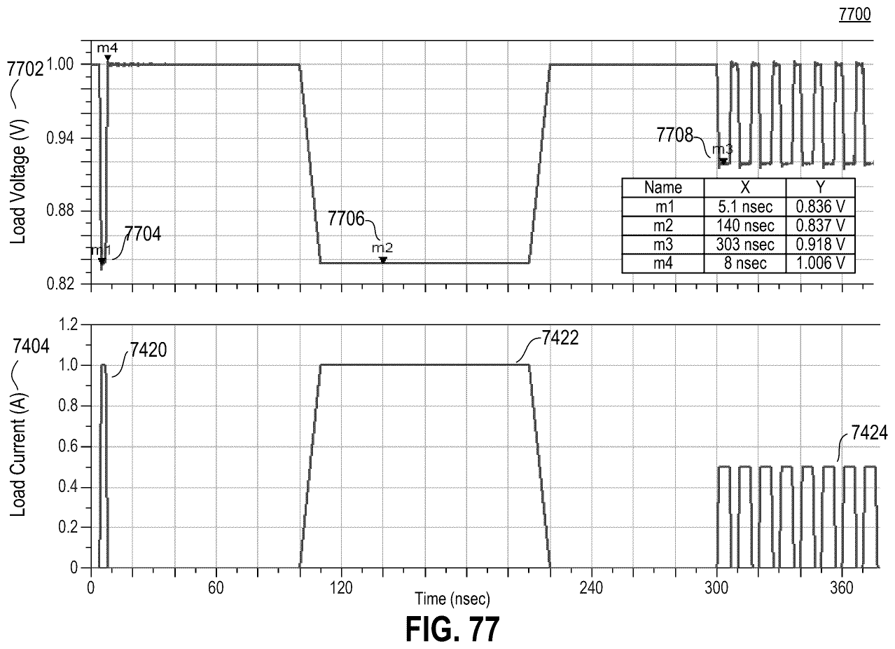

FIG. 77 is a plot 7700 that shows the behavior of load voltage 7702 and load current 7704 of circuit 7500 in FIG. 75, in accordance with at least one example. When load 7516 switches, it drives a transient current 7404 through load 7516, and associated load voltage 7702 is plotted. The different phases of load current 7404 are: impulse current 7420, step current 7422, and resonance current 7424. They model different switching behaviors of load 7516, in accordance with at least one example. For instance, when impulse current 7420 of 1 Ampere peak or step current 7422 of 1 Ampere is drawn by load 7516 for 100 nanoseconds, the voltage drop of 0.164 volts is observed and shown by markers m1 7704 and m2 7706, respectively. In a similar way, the voltage drop of 0.082 volts is also observed at marker m3 7708, when resonance current 7424 of 0.5 Amperes is drawn by load 7516 at 100 megahertz, in accordance with at least one example. The fluctuations in voltage 7702, because of the current transients 7420, 7422, and 7424 in the load current 7404, are minimized as shown in plot 7700 of FIG. 77. Consequently, the use of ferromagnetic power transformer 6600 in power distribution network 7500 reduces the fluctuations in load voltage 7702 as compared to load voltage 7402 of power distribution network 6900 that did not use a ferromagnetic power transformer.

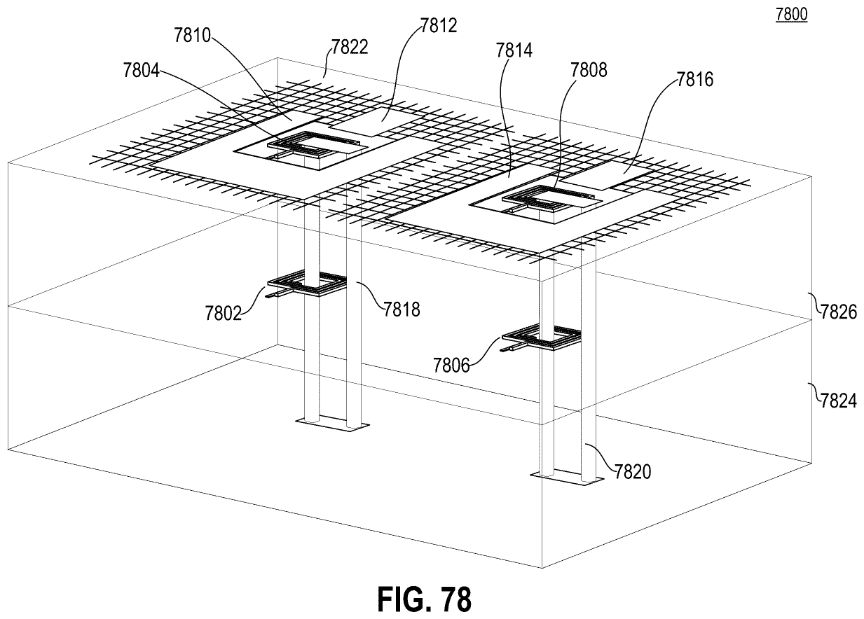

FIG. 78 is a schematic that illustrates a layout 7800 of a 3D integrated circuit (3D IC). In the layout, multiple ferromagnetic power transformers (FMPTs) supply power to different circuit blocks of chips 7824 and 7826 in a 3D IC, in accordance with at least one example. The AC power from PMIC 7824 is transferred through inductive coil 7802 to inductive coil 7804 on chip 7826 using ferromagnetic transformer core 7818. In at least one example, block 7812 is configured to rectify the AC power to the DC power and regulate it. In at least one example, on-chip PDN 7822 delivers the DC power to a circuitry, which is fabricated in block 7810. The other part of the on-chip circuitry is fabricated in block 7814, and is powered by inductive coils 7806 and 7808, and ferromagnetic core 7820. In this circuit part, block 7816 is configured to rectify the AC power to the DC power and regulate it.

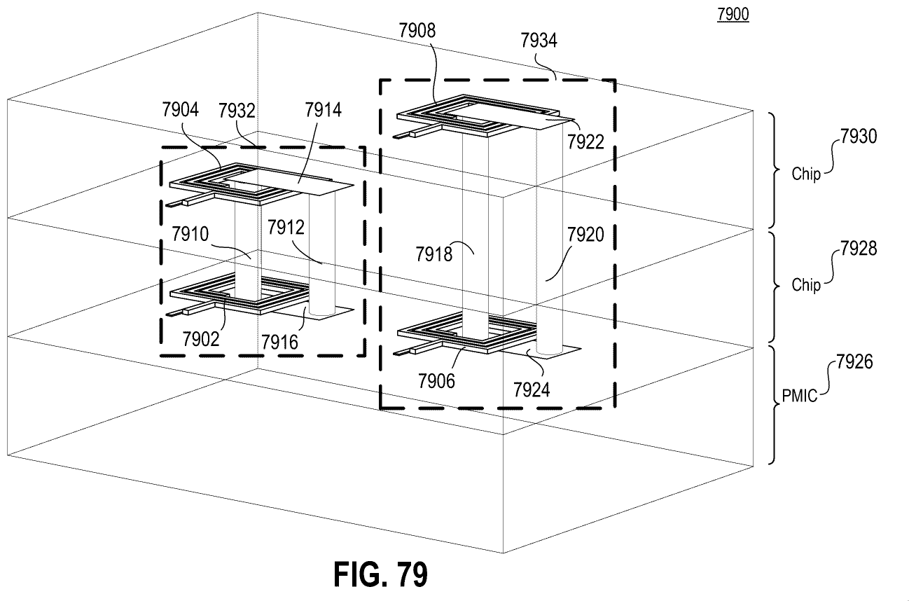

FIG. 79 is a schematic that illustrates an example structure 7900 of the power distribution network in the 3D integrated circuit, wherein PMIC 7926 is configured to supply the power to chips 7928 and 7930 using ferromagnetic power transformers (FMPTs) 7932 and 7934, in accordance with at least one example. In at least one example, ferromagnetic power transformer 7932 comprises inductive coils 7902 and 7904 around the ferromagnetic through silicon via 7910. Moreover, FTSVs 7910 and 7912 are connected by ferromagnetic lines 7914 and 7916. In at least one example, ferromagnetic power transformer 7934 comprises inductive coils 7906 and 7908 around FTSV 7918. Moreover, the ferromagnetic through silicon vias 7918 and 7920 are connected by ferromagnetic lines 7922 and 7924, respectively. In at least one example, inductive coil 7902 transfers the AC power from PMIC 7926 to inductive coil 7904 on chip 7928, and inductive coil 7906 transfers the AC power from PMIC 7926 to inductive coil 7908 of chip 7930.

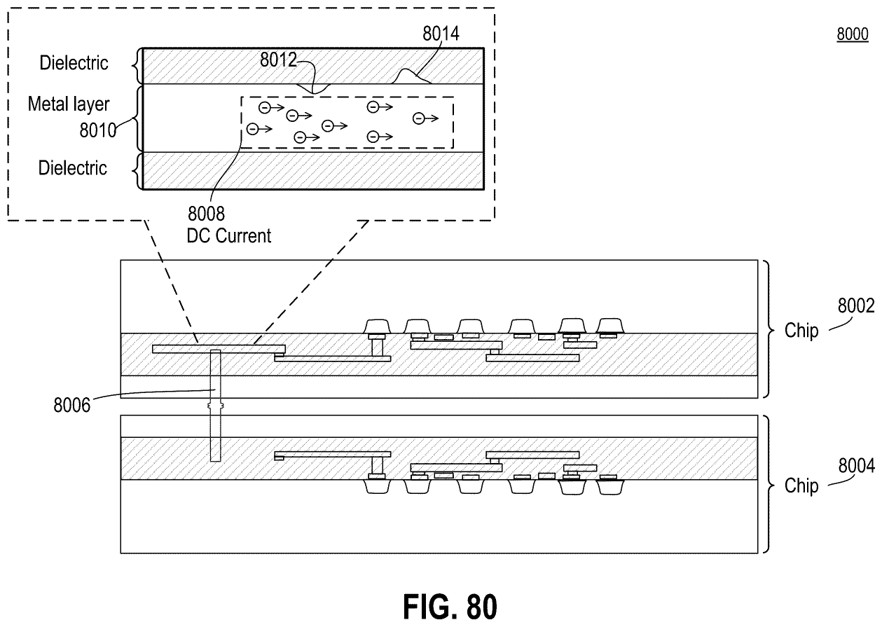

FIG. 80 is a schematic that illustrates a cross section 8000 of a conventional 3D integrated circuit, powered by a DC source, to model the effect of electromigration. In at least one example, stacked chips 8002 and 8004 are interconnected using through silicon via (TSV) 8006. Due to the continuous flow of electric charges in one direction, represented by DC current 8008, atoms in the metal layer 8010 are displaced, leading to the formation of voids 8012 and accumulate at different locations in metal layer 8010, leading to the formation of hillocks 8014. The same phenomenon occurs in the small conducting vias such as via 8006 as well. Consequently, interconnects and conducting vias may degrade over time, posing a risk of device failure or malfunction, which subsequently can lead to shortening the lifespan of the 3D IC. Since the power and ground rails carry most of the current in a circuit, therefore, their reliability can become a significant concern due to the electromigration. This phenomenon also poses a challenge in two-dimensional ICs, but the effects of electromigration are further exacerbated in 3D ICs due to a high integration density of interconnects.

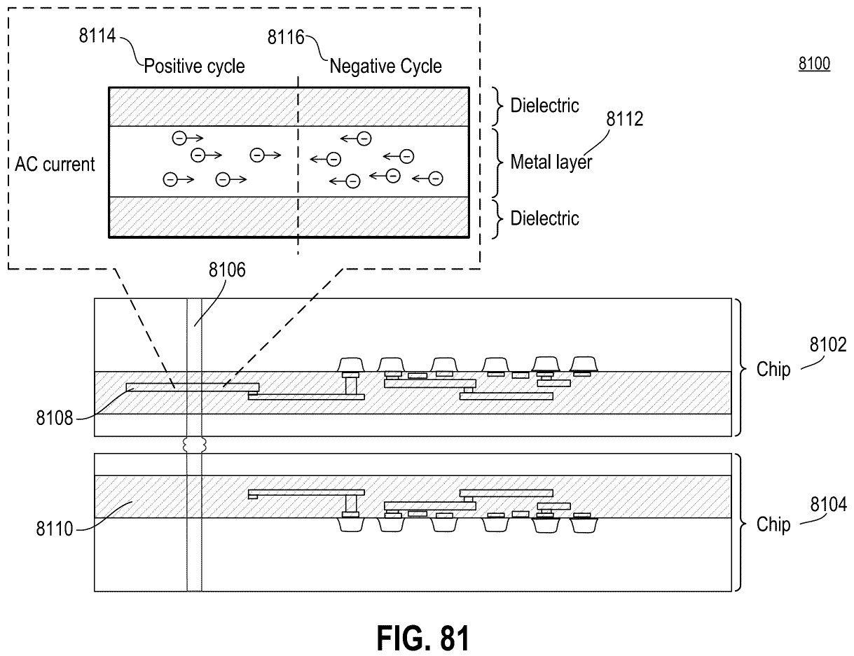

FIG. 81 is a schematic that illustrates a cross-section 8100 of a 3D integrated circuit, demonstrating the damped effect of electromigration in a ferromagnetic power transformer based power distribution network. The chips in the 3D IC such as chips 8102 and 8104 are interconnected through ferromagnetic through silicon via 8106, which passes through on-chip inductive coils 8108 and 8110 and transfers the AC power between the chips. As an AC signal propagates in metal layer 8112, the current flows in one direction during the positive cycle 8114 (when the AC voltage is positive) and reverses during negative cycle 8116 (when the AC voltage is negative). This alternating current flow cancels out the net force applied on the metal atoms, thereby significantly reducing the effect of electromigration. Since the AC power is transferred between the inductive coils, the AC signal propagates in the power and ground rail. This mitigates the formation of voids and hillocks in the metal interconnects. Please see that metal layer 8112 has no voids and hillocks, and now compare it with metal layer 8010 and conducting via 8006 of FIG. 80 that has voids 8012 and hillocks 8014. Consequently, the power transfer efficiency of the ferromagnetic power transformer based power distribution net is enhanced that consequently improves the reliability of a 3D IC.

Throughout specifications and claims, “chip” may generally refer to a discrete semiconductor component or module, typically designed for integration into a larger semiconductor package or system, and more specifically to a vertical stacking within a three-dimensional integrated circuit. The chips may encompass various functionalities such as processing units, memory elements, or specialized accelerators. Their modular nature allows for flexible assembly and integration strategies, enhancing scalability, performance, and customization within semiconductor architectures.

Here, “semiconductor chip” may generally refer to a small electronic device made from semiconductor materials, typically silicon, containing integrated circuits (ICs) capable of performing various functions such as processing, memory storage, or specialized acceleration.

Here, “substrate” may generally refer to the underlying material or base upon which semiconductor components and circuits are fabricated within a semiconductor chip. In at least one example, substrate provides the mechanical support and electrical connections for the integrated circuits and may be composed of materials like silicon, glass, or other semiconductor materials.

Here, “dielectric layer” may generally refer to an insulating material deposited or integrated into a semiconductor chip between conductive layers or components. In at least one example, dielectric layer serves to electrically isolate different parts of the chip, preventing unwanted electrical interactions and providing a stable environment for circuit operation.

Here, “metal layer” may generally refer to a conductive layer within a semiconductor chip, typically made of metals such as aluminum, copper, or gold. Deposited within the dielectric layers, it facilitates interconnections between components and circuits, ensuring signal flow, power distribution, and enhancing overall functionality and performance.

Here, “via” may generally refer to a hardware component of a three-dimensional integrated circuit that penetrates or connects two or more chips through silicon within a three-dimensional integrated circuit.

Here, “interposed” may generally refer to a component being placed or positioned between two or more entities or elements and more particularly to an FTSV situated or inserted between chips.

Here, “parasitic losses” may generally refer to unintended or undesired energy losses within an electrical or electronic system, resulting from the presence of parasitic elements or effects.

Here, “metallization” may generally refer to the process of depositing a thin layer of metal onto a substrate, typically to create conductive pathways or interconnects within an electronic device or integrated circuit.

Here, “voids” may generally refer to empty spaces or gaps within a material or structure, typically resulting from the absence of material and more particularly to the absence of metal ions in a metal interconnect due to the migration of those ions.

Here, “hillocks” may generally refer to protrusions or bumps that form on the surface of a material and more particularly to the metal ions that accumulate, wherein the metal ions arrive from the points where voids formed due to electromigration.

Here, “positive cycle” and “negative cycle” may generally refer to the alternating phases or periods of a periodic waveform, such as an alternating current (AC) current or voltage signal.

Here, “ferromagnetic through silicon via” may generally refer to a constituent hardware element within a three-dimensional integrated circuit that provides a low reluctance channel for magnetic fields to traverse. In at least one example, the ferromagnetic through silicon via may generally refer to a single ferromagnetic through silicon via, two ferromagnetic through silicon vias, a connected two ferromagnetic through silicon via with one or more ferromagnetic lines at the top or bottom, or a connected three ferromagnetic through silicon via with one or more ferromagnetic lines at the top or bottom.

Here, “magnetically coupled channel” may generally refer to a communication pathway within a semiconductor chip configured to facilitate data transmission via magnetic coupling between flux-inducing circuits and more particularly to magnetic coupling between inductive coils, eliminating the need for direct electrical connections.

Here, “magnetically coupled resonating channel” may generally refer to a specialized communication pathway within a semiconductor chip configured to facilitate data transmission using magnetic coupling between inductive coils and resonating circuits that resonate at a unique resonating frequency.

Here, “wireless power transfer channel” may generally refer to a communication pathway within a semiconductor chip configured to enable the transmission of power wirelessly between components using inductive coils.

Here, “resonant frequency” may generally refer to the natural frequency at which a system vibrates or oscillates most efficiently and more particularly to the frequency that allows maximum transmission through a resonating circuit or resonating tank.

Here, “micro wave, mm-wave, and THz communication bands” may generally refer to specific frequency ranges employed in wireless communication. “Microwave” spans frequencies from 1 gigahertz (GHz) to 30 gigahertz (GHz), “millimeter-wave (mm-wave)” ranges from 30 gigahertz (GHz) to 300 gigahertz (GHz), and “terahertz (THz)” communication bands extend beyond millimeter-wave frequencies, usually from 300 gigahertz (GHz) to several terahertz (THz).

Here, “ferromagnetic transformer” may generally refer to a hardware component of a three-dimensional integrated circuit configured to facilitate and enhance the wireless communication at one or more frequencies between two chips in the three-dimensional integrated circuits. In at least one example, ferromagnetic transformer allows wireless communication using two inductive coils and ferromagnetic through silicon via(s) between two or more chips at one or more frequencies.

Here, “ferromagnetic power transformer” may generally refer to a hardware component of a three-dimensional integrated circuit configured to facilitate and enhance the wireless power transfer at one or more frequencies between two or more chips in the three-dimensional integrated circuits. In at least one example, the ferromagnetic power transformer allows wireless power transfer between two or more inductive coils at one or more frequencies.

Here, “frequency selectivity” may generally refer to the ability of a system or component to selectively pass or reject signals based on their frequency.

Here, “thermal pathway” may generally refer to a route within a heat conductive material for transferring heat from hot regions to cooler regions.

Here, “heat dissipater” or “heat sink” may generally refer to a component of a three-dimensional integrated circuit designed to absorb and dissipate heat, generated during operations, and more particularly to absorb heat from the ferromagnetic through silicon vias and dissipate heat to an ambient environment or a cooling fluid/paste.

Here, “conducting via” may generally refer to a vertical interconnect within a circuit or semiconductor device, designed to establish electrical connections between different layers, regions, or components of the device.

Here, “ferromagnetic heat transformer” may generally refer to a hardware component of a three-dimensional integrated circuit configured to facilitate and enhance the heat dissipation in the three-dimensional integrated circuits. In at least one example, the ferromagnetic heat transformer allows heat transfer from hotspots on chips to heat conductive lines and from hotspots on chips to ferromagnetic through silicon via. In at least one example, the ferromagnetic heat transformer also allows heat transfer from the ferromagnetic through silicon via towards a heat dissipater or heat sink.

Here, “inductive coil” may generally refer to a constituent hardware element within a three-dimensional integrated circuit, configured to produce a magnetic field when the electric current passes through it, or alternatively, to permit the flow of electric current when exposed to a magnetic field.

Here, “inductive link” may generally refer to a magnetic coupling between two inductive coils and more specifically to an enhanced magnetic coupling between two or more inductive coils through a low reluctance magnetically coupled channel of one or more ferromagnetic through silicon vias.

Here, “resonating circuit” may generally refer to a constituent hardware element within a three-dimensional integrated circuit, configured to resonate at a unique resonating frequency. In at least one example, the resonating circuit is typically composed of one or more inductors and one or more capacitors, meticulously arranged to enable the passage of signals at this unique resonating frequency to facilitate seamless communication or efficient power transfer within the three-dimensional integrated circuit.

Here, “resonant link” may generally refer to a magnetic coupling between two resonating tanks comprising one or more inductive coils and one or more capacitors, and more specifically to an enhanced magnetic coupling between two or more resonating tanks through a low reluctance magnetically coupled resonating channel of one or more ferromagnetic through silicon vias.

Here, “coupling result” may generally refer to the outcome or effect of the coupling between two or more components within a system and more particularly to the results of the coupling of the inductive coils in the inductive links or the resonant links of the ferromagnetic transformers.

Here, “transceiver circuit” may generally refer to a constituent hardware or software element within a three-dimensional integrated circuit, configured to handle the signals transmitted to or received from inductive coils, facilitating communication or power transfer within a three-dimensional integrated circuit.

Here, “test circuit” may generally refer to a software simulation test bench configured to validate the performance, functionality, and reliability of various structures and examples of inductive and resonant links described herein.

Here, “heat pipe” may generally refer to a hardware component that assists the dissipation of heat, generated by the chips of the three-dimensional integrated circuit, by conducting the heat towards the ambience or a heat sink and more specifically to the ferromagnetic through silicon vias behaving as a heat conductor within the three-dimensional integrated circuit.

Here, a “DC to AC converter” may generally refer to a device that transforms electrical power from a DC source into an AC waveform.

Here, an “AC to DC converter” may generally refer to a device that converts electrical power from an AC source into a DC output.

Here, a “heat generating chip” may generally refer to any semiconductor chip or integrated circuit that produces heat during operations due to electrical resistance and power dissipation.

Here, “electromigration” may generally refer to a phenomenon where the gradual movement of metal atoms occurs due to the flow of electrical current which leads to the degradation and eventual failure of the device, often manifesting as a void formation, thinning, or even a complete disconnection of the conducting paths within the metallic interconnects of a device.

Here, “device” may generally refer to an apparatus according to context of usage of that term. In at least one example, a device may refer to a stack of layers or structures, a single structure or layer, a connection of various structures having active and/or passive elements, etc. Generally, a device is a three-dimensional structure with a plane along x-y direction and a height along z direction of an x-y-z Cartesian coordinate system. In at least one example, plane of device may also be plane of an apparatus, which comprises the device.

Here, “connected” may generally refer to a direct connection, such as electrical, mechanical, or magnetic connection between things that are connected, without any intermediary devices.

Here, “coupled” may generally refer to a direct or indirect connection, such as a direct electrical, mechanical, or magnetic connection between things that are connected or an indirect connection, through one or more passive or active intermediary devices.

Here, “adjacent” may generally refer to a position of a thing being next to (e.g., immediately next to or close to with one or more things between them) or adjoining another thing (e.g., abutting it).

Here, “circuit” or “module” may generally refer to one or more passive and/or active components that are arranged to cooperate with one another to provide a desired function.

Here, “signal” may generally refer to at least one current signal, voltage signal, magnetic signal, or data/clock signal. Here, meaning of “a,” “an,” and “the” include plural references. Here, meaning of “in” includes “in” and “on.”

Here, “analog signal” generally refers to any continuous signal for which time varying feature (variable) of signal is a representation of some other time varying quantity, e.g., analogous to another time varying signal.

Here, “scaling” may generally refer to converting a design (schematic and layout) from one process technology to another process technology and subsequently being reduced in layout area. Here, “scaling” may generally refer to downsizing layout and devices within same technology node. Here, “scaling” may also generally refer to adjusting (e.g., slowing down or speeding up—e.g., scaling down, or scaling up, respectively) of a signal frequency relative to another parameter, for example, power supply level.

Here, “overlap” or “overlapping” may generally refer to the situation where two or more entities, such as signals, or physical regions, share a common area or time period.

Here, terms “substantially,” “close,” “approximately,” “near,” “overlapping,” and “about,” generally refer to being within +/−10% of a target value. For example, unless otherwise specified in explicit context of their use, terms “substantially equal,” “about equal” and “approximately equal” mean that there is no more than incidental variation between among things so described. In at least one example, such variation is typically no more than +/−10% of a predetermined target value.

Unless otherwise specified use of ordinal adjectives “first,” “second,” and “third,” etc., to describe a common object, merely indicate that different instances of like objects are being referred to and are not intended to imply that objects so described must be in a given sequence, either temporally, spatially, in ranking or in any other manner.

For purposes of present disclosure, phrases “A and/or B” and “A or B” mean (A), (B), or (A and B). In at least one example, phrase “A, B, and/or C” means (A), (B), (C), (A and B), (A and C), (B and C), or (A, B and C).

Here, “left,” “right,” “front,” “back,” “top,” “bottom,” “over,” “under,” and like in description and in claims, if any, are used for descriptive purposes and not necessarily for describing permanent relative positions. In at least one example, “over,” “under,” “front side,” “back side,” “top,” “bottom,” “over,” “under,” and “on” as used herein refer to a relative position of one component, structure, or material with respect to other referenced components, structures or materials within a device, where such physical relationships are noteworthy. In at least one example, these terms are employed herein for descriptive purposes only and predominantly within context of a device z-axis and therefore may be relative to an orientation of a device. In at least one example, a first material “over” a second material in context of a figure provided herein may also be “under” second material if device is oriented upside-down relative to context of figure provided. In context of materials, one material disposed over or under another may be directly in contact or may have one or more intervening materials. Moreover, one material disposed between two materials may be directly in contact with two layers or may have one or more intervening layers. In at least one example, a first material “on” a second material is in direct contact with that second material. Similar distinctions are to be made in context of component assemblies.

Here, “between” may be employed in context of z-axis, x-axis, or y-axis of a device. In at least one example, a material that is between two other materials may be in contact with one or both of those materials, or may be separated from both of other two materials by one or more intervening materials. In at least one example, a material “between” two other materials may therefore be in contact with either of other two materials, or may be coupled to other two materials through an intervening material. In at least one example, a device that is between two other devices may be directly connected to one or both of those devices, or may be separated from both of other two devices by one or more intervening devices.

Reference in specification to “an example,” “one example,” “in at least one example,” “some examples,” or “other examples” means that a particular feature, structure, or characteristic described in connection with examples is included in at least some examples, but not necessarily all examples. Various appearances of “an example,” “one example,” “in at least one example,” or “some examples” are not necessarily all referring to same examples. If specification states a component, feature, structure, or characteristic “may,” “might,” or “could” be included, that particular component, feature, structure, or characteristic is not required to be included. If specification or claim refers to “a” or “an” element, that does not mean there is only one of elements. If specification or claims refer to “an additional” element, that does not preclude there being more than one of additional elements.

Furthermore, particular features, structures, functions, or characteristics may be combined in any suitable manner in one or more examples. For example, a first example may be combined with a second example anywhere particular features, structures, functions, or characteristics associated with two examples are not mutually exclusive.

While at least one example has been described in conjunction with specific examples thereof, many alternatives, modifications, and variations of such examples will be apparent to those of ordinary skill in the art considering description herein. At least one example is intended to embrace all such alternatives, modifications, and variations as to fall within broad scope of appended claims.

In addition, well-known power/ground connections to integrated circuit (IC) chips and other components may or may not be shown within presented figures, for simplicity of illustration and discussion, and so as not to obscure any example. Further, arrangements may be shown in a block diagram form to avoid obscuring any example, and in view of the fact that specifics with respect to the implementation of such block diagram arrangements are highly dependent on the platform within which an example is to be implemented (e.g., such specifics should be well within the purview of one skilled in art). Where specific details (e.g., circuits) are set forth to describe example examples of disclosure, it should be apparent to one skilled in art that disclosure can be practiced without, or with variation of, these specific details. Description of an example is thus to be regarded as illustrative instead of limiting.

In at least one example, structures described herein can also be described as method(s) of forming those structures or apparatuses, and method(s) of operation of these structures or apparatuses. Following examples are provided that illustrate at least one example. An example can be combined with any other example. As such, at least one example can be combined with at least another example without changing the scope of an example.

Example 1 is an apparatus of a ferromagnetic power transformer in a 3D integrated circuit, the apparatus comprising: a power transmission semiconductor chip stacked within the 3D integrated circuit, wherein the power transmission semiconductor chip comprises: a first substrate; a plurality of first dielectric layers; a plurality of first metal layers, wherein an individual first metal layer of the plurality of first metal layers is in an individual first dielectric layer of the plurality of first dielectric layers over the first substrate; a first inductive coil in the individual first metal layer of the plurality of first metal layers, wherein the first inductive coil is to wirelessly transmit AC power signals; and a power transmission circuit coupled to the first inductive coil, wherein the power transmission circuit includes a DC to AC converter to convert first DC power signals to the AC power signals; a plurality of power reception semiconductor chips overlapping the power transmission semiconductor chip, wherein an individual power reception semiconductor chip of the plurality of power reception semiconductor chips wirelessly receives the AC power signals from the power transmission semiconductor chip, wherein the individual power reception semiconductor chip comprises: a second substrate; a plurality of second dielectric layers; a plurality of second metal layers, wherein an individual second metal layer of the plurality of second metal layers is in an individual second dielectric layer of the plurality of second dielectric layers over the second substrate; a second inductive coil in the individual second metal layer of the plurality of second metal layers, wherein the second inductive coil is to wirelessly receive the AC power signals from the first inductive coil; and a power reception circuit coupled to the second inductive coil, wherein the power reception circuit includes an AC to DC converter to convert the AC power signals to second DC power signals; and a ferromagnetic through silicon via substantially in a center of the first inductive coil and the second inductive coil, wherein the ferromagnetic through silicon via provides a wireless power transfer channel to enable the wireless transfer of the AC power signals between the power transmission semiconductor chip and the plurality of power reception semiconductor chips at one or more frequencies.

Example 2 is an apparatus according to any examples herein, in particular example 1, wherein the 3D integrated circuit includes: a plurality of ferromagnetic power transformers, wherein an individual ferromagnetic power transformer of the plurality ferromagnetic power transformers includes: a plurality of power transmission semiconductor chips, wherein an individual power transmission semiconductor chip of the plurality of power transmission semiconductor chips overlaps with one or more power reception semiconductor chips of the plurality of power reception semiconductor chips, wherein the individual power transmission semiconductor chip wirelessly transmits the AC power signals to the one or more power reception semiconductor chips of the plurality of power reception semiconductor chips via the wireless power transfer channel at the one or more frequencies; and a plurality of ferromagnetic through silicon vias, wherein an individual ferromagnetic through silicon via of the plurality of ferromagnetic through silicon vias is substantially in a center of a plurality of inductive coils of the power transmission semiconductor chip and the one or more power reception semiconductor chips of the plurality of power reception semiconductor chips, wherein the individual ferromagnetic through silicon via provides a wireless power transfer channel to wirelessly transfer the AC power signals between the power transmission semiconductor chip and the one or more power reception semiconductor chips at the one or more frequencies.

Example 3 is an apparatus according to any examples herein, in particular example 1, wherein a shape of a cross-section of the individual ferromagnetic through silicon via comprises one of a rectangular shape, a square shape, a hexagonal shape, an octagonal shape, a circular shape, an elliptical shape, or any combination thereof.

Example 4 is an apparatus according to any examples herein, in particular example 1, wherein the first inductive coil of the power transmission semiconductor chip and the second inductive coil of the individual power reception semiconductor chip comprise one of a rectangular shape, a square shape, a circular shape, a hexagonal shape, or any combination thereof.

Example 5 is an apparatus according to any examples herein, in particular example 1, wherein transmission and reception of the AC power signals through the wireless power transfer channel protects the wireless power transfer channel against electromigration.

Example 6 is an apparatus according to any examples herein, in particular example 1, wherein the first inductive coil of the power transmission semiconductor chip and the second inductive coil of the individual power reception semiconductor chip communicate in microwave, mm-wave, and/or terra hertz (THz) communication bands through the wireless power transfer channel.

Example 7 is an apparatus of a ferromagnetic transformer in a 3D integrated circuit, the apparatus comprising: a plurality of semiconductor chips stacked within the 3D integrated circuit, wherein an individual semiconductor chip of the plurality of semiconductor chips comprises: a substrate; a plurality of dielectric layers; and a plurality of metal layers in the plurality of dielectric layers; and one or more ferromagnetic through silicon vias vertically positioned through the individual semiconductor chip.

Example 8 is an apparatus according to any examples herein, in particular example 7, wherein the apparatus includes: a plurality of inductive links, wherein an individual inductive link of the plurality of inductive links communicates through the individual ferromagnetic through silicon via at one or more frequencies, wherein the individual inductive link is configured to enable wireless transmission of AC power signals or wireless communication between two semiconductor chips of the plurality of semiconductor chips, wherein the individual inductive link comprises: a first inductive coil in a first metal layer of the plurality of metal layers of a first semiconductor chip of the plurality of semiconductor chips, wherein the first inductive coil surrounds a ferromagnetic through silicon via of the one or more ferromagnetic through silicon vias; and a second inductive coil in a second metal layer of the plurality of metal layers of a second semiconductor chip of the plurality of semiconductor chips, wherein the second inductive coil surrounds the individual ferromagnetic through silicon via, wherein the second inductive coil substantially overlaps the first inductive coil, wherein the second inductive coil is magnetically coupled with the first inductive coil at the one or more frequencies.

Example 9 is an apparatus according to any examples herein, in particular example 7, wherein a shape of a cross-section of individual ferromagnetic through silicon via comprises one of a rectangular shape, a square shape, a hexagonal shape, an octagonal shape, a circular shape, an elliptical shape, or any combination thereof.

Example 10 is an apparatus according to any examples herein, in particular example 7, wherein the apparatus includes: a plurality of resonant links, wherein an individual resonant link of the plurality of resonant links communicates through a wireless channel of the individual ferromagnetic through silicon via at a resonant frequency, wherein the individual resonant link is configured to enable wireless transmission of AC power signals or wireless communication between two semiconductor chips of the plurality of semiconductor chips, wherein the wireless transmission of the AC power signals protects the wireless channel against electromigration, wherein the individual resonant link comprises: a first inductive coil in a first metal layer of the plurality of metal layers of a first semiconductor chip of the plurality of semiconductor chips, wherein the first inductive coil surrounds the individual ferromagnetic through silicon via; a first resonating circuit coupled to the first inductive coil, wherein the first resonating circuit and the first inductive coil are configured to communicate at the resonant frequency; a second inductive coil in a second metal layer of the plurality of metal layers of a second semiconductor chip of the plurality of semiconductor chips, wherein the second inductive coil surrounds the individual ferromagnetic through silicon via of the one or more ferromagnetic through silicon vias, wherein the second inductive coil substantially overlaps the first inductive coil, wherein the second inductive coil is magnetically coupled with the first inductive coil; and a second resonating circuit coupled to the second inductive coil, wherein the second resonating circuit and the second inductive coil are configured to communicate at the resonant frequency.

Example 11 is an apparatus according to any examples herein, in particular example 7, wherein the 3D integrated circuit includes: one or more heat dissipation structures configured to dissipate heat away from the 3D integrated circuit during its operation, wherein the one or more heat dissipation structures comprise one or more heat sinks, thermal spreaders, or thermal interface materials, wherein the one or more heat dissipation structures overlap one or more semiconductor chips of the plurality of semiconductor chips, wherein the one or more heat dissipation structures are configured to dissipate heat away from the individual ferromagnetic through silicon via.

Example 12 is an apparatus according to any examples herein, in particular example 7, wherein the plurality of semiconductor chips include: one or more heat conductive lines which are configured to form a thermal pathway between the one or more semiconductor chips of the plurality of semiconductor chips and the one or more ferromagnetic through silicon vias to facilitate dissipation of heat generated by the individual semiconductor chip.

Example 13 is an apparatus according to any examples herein, in particular example 7, wherein the plurality of semiconductor chips include one or more of: central processing units (CPUs), graphics processing units (GPUs), field-programmable gate arrays (FPGAs), application-specific integrated circuits (ASICs), system-on-chip (SoC) architectures, digital signal processors (DSPs), microcontroller units (MCUs), artificial intelligence (AI) accelerators, neural processing units (NPUs), tensor processing units (TPUs), data processing units (DPUs), inference processing units (IPUs), vision processing units (VPUs), coprocessors, cryptographic accelerators, memory controllers, power management integrated circuits (PMICs), display controllers, audio processors, sensor hubs, or any combination thereof.

Example 14 is an apparatus according to any examples herein, in particular example 7, wherein the plurality of semiconductor chips include: a plurality of inductive links, wherein an individual inductive link of the plurality of inductive links communicates through the individual ferromagnetic through silicon via at one or more frequencies, wherein the individual inductive link is configured to enable wireless communication between two semiconductor chips of the plurality of semiconductor chips, wherein individual inductive link comprises: a first flux inducing circuit which is configured to generate a magnetic flux, wherein the first flux inducing circuit surrounds the individual ferromagnetic through silicon via; a second flux inducing circuit which is configured to receive the magnetic flux, wherein the second flux inducing circuit surrounds the individual ferromagnetic through silicon via, wherein the second flux inducing circuit substantially overlaps the first flux inducing circuit, wherein the second flux inducing circuit is magnetically coupled with the first flux inducing circuit at the one or more frequencies; and wherein the first flux inducing circuit and the second flux inducing circuit comprise one or more of oscillators, transistors, resistors, conductive loops, or any combination thereof.

Example 15 is an apparatus of a ferromagnetic transformer in a 3D integrated circuit, the apparatus comprising: a plurality of semiconductor chips stacked within the 3D integrated circuit, wherein one or more semiconductor chips of the plurality of semiconductor chips are configured to generate heat; and one or more ferromagnetic through silicon vias vertically positioned through the one or more semiconductor chips, wherein an individual ferromagnetic through silicon via of one or more ferromagnetic through silicon vias is configured to behave as a heat pipe that conducts heat from the one or more semiconductor chips to an ambient heat sink.

Example 16 is an apparatus according to any examples herein, in particular example 15, wherein the apparatus includes: a plurality of two or more overlapping inductive coils, wherein two or more overlapping inductive coils of the plurality of two or more overlapping inductive coils surround the individual ferromagnetic through silicon via, wherein the two or more overlapping inductive coils are magnetically coupled through the individual ferromagnetic through silicon via to enable wireless transmission of AC power signals or wireless communication between two or more semiconductor chips of the plurality of semiconductor chips.

Example 17 is an apparatus according to any examples herein, in particular example 15, wherein the apparatus includes: one or more pairs of overlapping inductive coils, wherein an individual pair of overlapping inductive coils of the one or more pairs of overlapping inductive coils surround the individual ferromagnetic through silicon via, wherein the individual pair of overlapping inductive coils is magnetically coupled through the individual ferromagnetic through silicon via to enable wireless transmission of AC power signals or wireless communication between two or more semiconductor chips of the plurality of semiconductor chips.

Example 18 is an apparatus according to any examples herein, in particular example 15, wherein a shape of a cross-section of the individual ferromagnetic through silicon via comprises one of a rectangular shape, a square shape, a hexagonal shape, an octagonal shape, a circular shape, or an elliptical shape.

Example 19 is an apparatus according to any examples herein, in particular example 15, wherein the plurality of semiconductor chips include one or more of: central processing units (CPUs), graphics processing units (GPUs), field-programmable gate arrays (FPGAs), application-specific integrated circuits (ASICs), system-on-chip (SoC) architectures, digital signal processors (DSPs), microcontroller units (MCUs), artificial intelligence (AI) accelerators, neural processing units (NPUs), tensor processing units (TPUs), data processing units (DPUs), inference processing units (IPUs), vision processing units (VPUs), coprocessors, cryptographic accelerators, memory controllers, power management integrated circuits (PMICs), display controllers, audio processors, sensor hubs, or any combination thereof.

Example 20 is an apparatus according to any examples herein, in particular example 15, wherein the plurality of semiconductor chips includes: a plurality of inductive links, wherein an individual inductive link of the plurality of inductive links communicates through the individual ferromagnetic through silicon via of the one or more ferromagnetic through silicon vias at one or more frequencies, wherein the individual inductive link is configured to enable wireless transmission of AC power signals or wireless communication between two semiconductor chips of the plurality of semiconductor chips.

Example 21 is an apparatus according to any examples herein, wherein the capacitors integrated within the first chip and the second chip employ various shapes and technologies. These capacitors may exhibit shapes such as rectangular, cylindrical, spherical, tapered, or hexagonal. Furthermore, the capacitors can be constructed using diverse technologies including electrolytic, ceramic, tantalum, polymer, or film capacitors, each tailored to suit specific performance requirements and constraints within the integrated circuit. Additionally, the capacitors may utilize diverse technologies including metal-insulator-metal (MIM) and metal-oxide-metal (MOM) configurations.

Example 22 is an apparatus according to any examples herein, wherein the ferromagnetic through silicon via structures constitute one of single ferromagnetic through silicon via, one or more ferromagnetic through silicon via with one or more ferromagnetic lines, one or more ferromagnetic through silicon via with one or more ferromagnetic sheets, or two or more silicon ferromagnetic through silicon vias connected at the top and bottom by ferromagnetic lines configurations.

Example 23 is an apparatus of a ferromagnetic transformer (FMT) comprising: a ferromagnetic through silicon via (FTSV), wherein the ferromagnetic through silicon via penetrates two or more chips of the three-dimensional integrated circuits (3D IC), wherein the ferromagnetic through silicon via provides a magnetically coupled channel in the ferromagnetic transformer (FMT); and one or more pair of chips, wherein the one or more pair of chips are vertically stacked into a single package in the three-dimensional integrated circuits (3D IC), the one or more pair of chips include: a first chip, wherein the first chip is embedded within the vertical stack of the one or more pair of chips, the first chip includes: a first flux inducing circuit, wherein the first flux inducing circuit is around the ferromagnetic through silicon via (FTSV), wherein the first flux inducing circuit sends or receives the signals via the magnetically coupled channel of the ferromagnetic through silicon via (FTSV), wherein the first flux inducing circuit induces a magnetic field in the magnetically coupled channel due to flow of current; and a first transceiver circuit, wherein the first transceiver circuit is connected with the first flux inducing circuit, wherein the first transceiver circuit processes the signals, at one or more frequencies, sent or received via the first flux inducing circuit; and a second chip, wherein the second chip is embedded within the vertical stack of the one or more pair of chips, the second chip includes: a second flux inducing circuit, wherein the second flux inducing circuit is around the ferromagnetic through silicon via (FTSV), wherein the second flux inducing circuit sends or receives the signals via the magnetically coupled channel of the ferromagnetic through silicon via (FTSV), wherein the second flux inducing circuit induces a magnetic field in the magnetically coupled channel due to flow of current; and a second transceiver circuit, wherein the second transceiver circuit is connected with the second flux inducing circuit, wherein the second transceiver circuit processes the signals, at one or more frequencies, sent or received via the second flux inducing circuit.

Example 24 is an apparatus according to any examples herein, in particular example 23, wherein the first flux inducing circuit or the second flux inducing circuit may correspond to one of inductive coils, oscillators, one or more resistors, one or more transistors, or a combination thereof around a ferromagnetic through silicon via structure configuration.

Example 25 is an apparatus according to any examples herein, wherein the magnetic coupling can ensure transfer of data modulated by any modulation technique via the magnetically coupled channel or the magnetically couple resonating channel at one or more frequencies.

Example 26 is an apparatus according to any examples herein, wherein the ferromagnetic through silicon via structures ensure galvanic isolation between two or more inductive coils and thereby between two or more chips to mitigate resistive losses.

Example 27 is an apparatus according to any examples herein, wherein each ferromagnetic through silicon via may support a multitude of resonant links operating at different frequencies, using frequency division duplexing or time division duplexing.

Example 28 is an apparatus according to any examples herein, wherein each transceiver circuit includes a serializer-deserializer to transmit or receive parallel data on the magnetically coupled channel or the magnetically coupled resonating channel.

What is claimed is:

1. An apparatus of a ferromagnetic power transformer in a 3D integrated circuit, the apparatus comprising:
a power transmission semiconductor chip stacked within the 3D integrated circuit, wherein the power transmission semiconductor chip comprises:
a first substrate;
a plurality of first dielectric layers;
a plurality of first metal layers, wherein an individual first metal layer of the plurality of first metal layers is in an individual first dielectric layer of the plurality of first dielectric layers over the first substrate;
a first inductive coil in the individual first metal layer of the plurality of first metal layers, wherein the first inductive coil is to wirelessly transmit AC power signals; and
a power transmission circuit coupled to the first inductive coil, wherein the power transmission circuit includes a DC to AC converter to convert first DC power signals to the AC power signals;
a plurality of power reception semiconductor chips overlapping the power transmission semiconductor chip, wherein an individual power reception semiconductor chip of the plurality of power reception semiconductor chips wirelessly receives the AC power signals from the power transmission semiconductor chip, wherein the individual power reception semiconductor chip comprises:
a second substrate;
a plurality of second dielectric layers;
a plurality of second metal layers, wherein an individual second metal layer of the plurality of second metal layers is in an individual second dielectric layer of the plurality of second dielectric layers over the second substrate;
a second inductive coil in the individual second metal layer of the plurality of second metal layers, wherein the second inductive coil is to wirelessly receive the AC power signals from the first inductive coil; and
a power reception circuit coupled to the second inductive coil, wherein the power reception circuit includes an AC to DC converter to convert the AC power signals to second DC power signals; and
a ferromagnetic through silicon via substantially in a center of the first inductive coil and the second inductive coil, wherein the ferromagnetic through silicon via provides a wireless power transfer channel to enable the wireless transfer of the AC power signals between the power transmission semiconductor chip and the plurality of power reception semiconductor chips at one or more frequencies.

2. The apparatus of claim 1, wherein the 3D integrated circuit includes:
a plurality of ferromagnetic power transformers, wherein an individual ferromagnetic power transformer of the plurality ferromagnetic power transformers includes:
a plurality of power transmission semiconductor chips, wherein an individual power transmission semiconductor chip of the plurality of power transmission semiconductor chips overlaps with one or more power reception semiconductor chips of the plurality of power reception semiconductor chips, wherein the individual power transmission semiconductor chip wirelessly transmits the AC power signals to the one or more power reception semiconductor chips of the plurality of power reception semiconductor chips via the wireless power transfer channel at the one or more frequencies; and
a plurality of ferromagnetic through silicon vias, wherein an individual ferromagnetic through silicon via of the plurality of ferromagnetic through silicon vias is substantially in a center of a plurality of inductive coils of the power transmission semiconductor chip and the one or more power reception semiconductor chips of the plurality of power reception semiconductor chips, wherein the individual ferromagnetic through silicon via provides a wireless power transfer channel to wirelessly transfer the AC power signals between the power transmission semiconductor chip and the one or more power reception semiconductor chips at the one or more frequencies.

3. The apparatus of claim 1, wherein a shape of a cross-section of the individual ferromagnetic through silicon via comprises one of a rectangular shape, a square shape, a hexagonal shape, an octagonal shape, a circular shape, an elliptical shape, or any combination thereof.

4. The apparatus of claim 1, wherein the first inductive coil of the power transmission semiconductor chip and the second inductive coil of the individual power reception semiconductor chip comprise one of a rectangular shape, a square shape, a circular shape, a hexagonal shape, or any combination thereof.

5. The apparatus of claim 1, wherein transmission and reception of the AC power signals through the wireless power transfer channel protects the wireless power transfer channel against electromigration.

6. The apparatus of claim 1, wherein the first inductive coil of the power transmission semiconductor chip and the second inductive coil of the individual power reception semiconductor chip communicate in microwave, mm-wave, and/or terra hertz (THz) communication bands through the wireless power transfer channel.

7. An apparatus of a ferromagnetic transformer in a 3D integrated circuit, the apparatus comprising:
a plurality of semiconductor chips stacked within the 3D integrated circuit, wherein an individual semiconductor chip of the plurality of semiconductor chips comprises:
a substrate;
a plurality of dielectric layers; and
a plurality of metal layers in the plurality of dielectric layers; and
one or more ferromagnetic through silicon vias vertically positioned through the individual semiconductor chip.

8. The apparatus of claim 7 includes:
a plurality of inductive links, wherein an individual inductive link of the plurality of inductive links communicates through the individual ferromagnetic through silicon via at one or more frequencies, wherein the individual inductive link is configured to enable wireless transmission of AC power signals or wireless communication between two semiconductor chips of the plurality of semiconductor chips, wherein the individual inductive link comprises:
a first inductive coil in a first metal layer of the plurality of metal layers of a first semiconductor chip of the plurality of semiconductor chips, wherein the first inductive coil surrounds a ferromagnetic through silicon via of the one or more ferromagnetic through silicon vias; and
a second inductive coil in a second metal layer of the plurality of metal layers of a second semiconductor chip of the plurality of semiconductor chips, wherein the second inductive coil surrounds the individual ferromagnetic through silicon via, wherein the second inductive coil substantially overlaps the first inductive coil, wherein the second inductive coil is magnetically coupled with the first inductive coil at the one or more frequencies.

9. The apparatus of claim 7, wherein a shape of a cross-section of individual ferromagnetic through silicon via comprises one of a rectangular shape, a square shape, a hexagonal shape, an octagonal shape, a circular shape, an elliptical shape, or any combination thereof.

10. The apparatus of claim 7 includes:
a plurality of resonant links, wherein an individual resonant link of the plurality of resonant links communicates through a wireless channel of the individual ferromagnetic through silicon via at a resonant frequency, wherein the individual resonant link is configured to enable wireless transmission of AC power signals or wireless communication between two semiconductor chips of the plurality of semiconductor chips, wherein the wireless transmission of the AC power signals protects the wireless channel against electromigration, wherein the individual resonant link comprises:
a first inductive coil in a first metal layer of the plurality of metal layers of a first semiconductor chip of the plurality of semiconductor chips, wherein the first inductive coil surrounds the individual ferromagnetic through silicon via;
a first resonating circuit coupled to the first inductive coil, wherein the first resonating circuit and the first inductive coil are configured to communicate at the resonant frequency;
a second inductive coil in a second metal layer of the plurality of metal layers of a second semiconductor chip of the plurality of semiconductor chips, wherein the second inductive coil surrounds the individual ferromagnetic through silicon via of the one or more ferromagnetic through silicon vias, wherein the second inductive coil substantially overlaps the first inductive coil, wherein the second inductive coil is magnetically coupled with the first inductive coil; and
a second resonating circuit coupled to the second inductive coil, wherein the second resonating circuit and the second inductive coil are configured to communicate at the resonant frequency.

11. The apparatus of claim 7, wherein the 3D integrated circuit includes:
one or more heat dissipation structures configured to dissipate heat away from the 3D integrated circuit during its operation, wherein the one or more heat dissipation structures comprise one or more heat sinks, thermal spreaders, or thermal interface materials, wherein the one or more heat dissipation structures overlap one or more semiconductor chips of the plurality of semiconductor chips, wherein the one or more heat dissipation structures are configured to dissipate heat away from the individual ferromagnetic through silicon via.

12. The apparatus of claim 7, wherein the plurality of semiconductor chips include:
one or more heat conductive lines which are configured to form a thermal pathway between the one or more semiconductor chips of the plurality of semiconductor chips and the one or more ferromagnetic through silicon vias to facilitate dissipation of heat generated by the individual semiconductor chip.

13. The apparatus of claim 7, wherein the plurality of semiconductor chips include one or more of: central processing units (CPUs), graphics processing units (GPUs), field-programmable gate arrays (FPGAs), application-specific integrated circuits (ASICs), system-on-chip (SoC) architectures, digital signal processors (DSPs), microcontroller units (MCUs), artificial intelligence (AI) accelerators, neural processing units (NPUs), tensor processing units (TPUs), data processing units (DPUs), inference processing units (IPUs), vision processing units (VPUs), coprocessors, cryptographic accelerators, memory controllers, power management integrated circuits (PMICs), display controllers, audio processors, sensor hubs, or any combination thereof.

14. The apparatus of claim 7, wherein the plurality of semiconductor chips include:
a plurality of inductive links, wherein an individual inductive link of the plurality of inductive links communicates through the individual ferromagnetic through silicon via at one or more frequencies, wherein the individual inductive link is configured to enable wireless communication between two semiconductor chips of the plurality of semiconductor chips, wherein individual inductive link comprises:
a first flux inducing circuit which is configured to generate a magnetic flux, wherein the first flux inducing circuit surrounds the individual ferromagnetic through silicon via;
a second flux inducing circuit which is configured to receive the magnetic flux, wherein the second flux inducing circuit surrounds the individual ferromagnetic through silicon via, wherein the second flux inducing circuit substantially overlaps the first flux inducing circuit, wherein the second flux inducing circuit is magnetically coupled with the first flux inducing circuit at the one or more frequencies; and
wherein the first flux inducing circuit and the second flux inducing circuit comprise one or more of oscillators, transistors, resistors, conductive loops, or any combination thereof.

15. An apparatus of a ferromagnetic transformer in a 3D integrated circuit, the apparatus comprising:
a plurality of semiconductor chips stacked within the 3D integrated circuit, wherein one or more semiconductor chips of the plurality of semiconductor chips are configured to generate heat; and
one or more ferromagnetic through silicon vias vertically positioned through the one or more semiconductor chips, wherein an individual ferromagnetic through silicon via of one or more ferromagnetic through silicon vias is configured to behave as a heat pipe that conducts heat from the one or more semiconductor chips to an ambient heat sink.

16. The apparatus of claim 15 includes:
a plurality of two or more overlapping inductive coils, wherein two or more overlapping inductive coils of the plurality of two or more overlapping inductive coils surround the individual ferromagnetic through silicon via, wherein the two or more overlapping inductive coils are magnetically coupled through the individual ferromagnetic through silicon via to enable wireless transmission of AC power signals or wireless communication between two or more semiconductor chips of the plurality of semiconductor chips.

17. The apparatus of claim 15 includes:
one or more pairs of overlapping inductive coils, wherein an individual pair of overlapping inductive coils of the one or more pairs of overlapping inductive coils surround the individual ferromagnetic through silicon via, wherein the individual pair of overlapping inductive coils is magnetically coupled through the individual ferromagnetic through silicon via to enable wireless transmission of AC power signals or wireless communication between two or more semiconductor chips of the plurality of semiconductor chips.

18. The apparatus of claim 15, wherein a shape of a cross-section of the individual ferromagnetic through silicon via comprises one of a rectangular shape, a square shape, a hexagonal shape, an octagonal shape, a circular shape, or an elliptical shape.

19. The apparatus of claim 15, wherein the plurality of semiconductor chips include one or more of: central processing units (CPUs), graphics processing units (GPUs), field-programmable gate arrays (FPGAs), application-specific integrated circuits (ASICs), system-on-chip (SoC) architectures, digital signal processors (DSPs), microcontroller units (MCUs), artificial intelligence (AI) accelerators, neural processing units (NPUs), tensor processing units (TPUs), data processing units (DPUs), inference processing units (IPUs), vision processing units (VPUs), coprocessors, cryptographic accelerators, memory controllers, power management integrated circuits (PMICs), display controllers, audio processors, sensor hubs, or any combination thereof.

20. The apparatus of claim 15, wherein the plurality of semiconductor chips includes:
a plurality of inductive links, wherein an individual inductive link of the plurality of inductive links communicates through the individual ferromagnetic through silicon via of the one or more ferromagnetic through silicon vias at one or more frequencies, wherein the individual inductive link is configured to enable wireless transmission of AC power signals or wireless communication between two semiconductor chips of the plurality of semiconductor chips.
